(19) United States
(12) Patent Application Publication
(10) Pub. No.: US 2021/0242086 A1
(43) Pub. Date: Aug. 5, 2021

(54) METHOD OF REMOVING SEMICONDUCTING LAYERS FROM A SEMICONDUCTING SUBSTRATE

(71) Applicant: The Regents of the University of California, Oakland, CA (US)

(72) Inventors: Srinivas Gandrothula, Santa Barbara, CA (US); Takeshi Kamikawa, Santa Barbara, CA (US)

(73) Assignee: The Regents of the University of California, Oakland, CA (US)

(21) Appl. No.: 17/049,156

(22) PCT Filed: May 30, 2019
(86) PCT No.: PCT/US19/34686

§ 371 Date: Oct. 20, 2020

Related U.S. Application Data
(60) Provisional application No. 62/677,833, filed on May 30, 2018.

(51) Int. Cl. H01L 21/78; H01L 21/02; C30B 25/04; C30B 25/20; C30B 29/40; C30B 33/02

(52) U.S. Cl. CPC H01L 21/7813; H01L 21/02389; H01L 21/02458; H01L 21/0254; H01L 21/02639; H01S 5/34333; C30B 25/04; C30B 25/20; C30B 29/403; C30B 33/02; H01L 21/02647

(57) ABSTRACT

A method of removing semiconducting layers from a substrate, in particular, III-nitride-based semiconductor layers from a III-nitride-based substrate, with an attached film, using a peeling technique. The method comprises forming the semiconductor layers into island-like patterns on the substrate via an epitaxial lateral overgrowth method, with a horizontal trench extending inwards from the sides of the layers. Stress is induced in the layers by raising or lowering the temperature, and applying pressure to the attached film, such that the film firmly fits a shape of the layers. Differences in thermal expansion between the substrate and the film attached to the layers initiates a crack at an interface between the layers and the substrate, so that the layers can be removed from the substrate. Once the layers are removed, the substrate can be recycled, resulting in cost savings for device fabrication.

### CROSS REFERENCE TO RELATED APPLICATIONS

This application claims the benefit under 35 U.S.C. Section 119(e) of the following and commonly-assigned application:

U.S. Provisional Application Ser. No. 62/677,833, filed on May 30, 2018, by Srinivas Gandrothula and Takeshi Kamikawa, entitled “METHOD OF REMOVING SEMICONDUCTING LAYERS FROM A SEMICONDUCTING SUBSTRATE,” attorneys' docket number G&C 30794.0682USP1 (UC 2018-614-1);

which application is incorporated by reference herein.

This application is related to the following and commonly-assigned applications:

PCT International Patent Application No. PCT/US19/32936, filed on May 17, 2019, by Takeshi Kamikawa and Srinivas Gandrothula, entitled “METHOD FOR DIVIDING A BAR OF ONE OR MORE DEVICES,” attorney's docket no. 30794.0681WOU1 (UC 2018-605-2), which application claims the benefit under 35 U.S.C. Section 119(e) of and commonly-assigned U.S. Provisional Application Ser. No. 62/672,913, filed on May 17, 2018, by Takeshi Kamikawa and Srinivas Gandrothula, entitled “METHOD FOR DIVIDING A BAR OF ONE OR MORE DEVICES,” attorneys' docket number G&C 30794.0682USP1 (UC 2018-605-1);

PCT International Patent Application No. PCT/US18/31393, filed on May 7, 2018, by Takeshi Kamikawa, Srinivas Gandrothula, Hongjian Li and Daniel A. Cohen, entitled “METHOD OF REMOVING A SUBSTRATE,” attorney's docket no. 30794.0653WOU1 (UC 2017-621-2), which application claims the benefit under 35 U.S.C. Section 119(e) of and commonly-assigned U.S. Provisional Patent Application No. 62/502,205, filed on May 5, 2017, by Takeshi Kamikawa, Srinivas Gandrothula, Hongjian Li and Daniel A. Cohen, entitled “METHOD OF REMOVING A SUBSTRATE,” attorney's docket no. 30794.0653USP1 (UC 2017-621-1); and

PCT International Patent Application No, PCT/US18/51375, filed on Sep. 17, 2018, by Takeshi Kamikawa, Srinivas Gandrothula and Hongjian Li, entitled “METHOD OF REMOVING A SUBSTRATE WITH A CLEAVING TECHNIQUE,” attorney's docket no. 30794.0659WOU1 (UC 2018-086-2), which application claims the benefit under 35 U.S.C. Section 119(e) of and commonly-assigned U.S. Provisional Patent Application No. 62/559,378, filed on Sep. 15, 2017, by Takeshi Kamikawa, Srinivas Gandrothula and Hongjian Li, entitled “METHOD OF REMOVING A SUBSTRATE WITH A CLEAVING TECHNIQUE,” attorney's docket no. 30794.0659USP1 (UC 2018-086-1);

all of which applications are incorporated by reference herein.

### BACKGROUND OF THE INVENTION

### 1. Field of the Invention

This invention relates to a method of removing semiconducting epitaxial layers from a semiconductor substrate with a peeling technique

### 2. Description of the Related Art

In the current invention we focus on removing III-nitride epitaxial layers from III-nitride base substrate, however, in general this invention can be applied to all semi-conducting substrates.

Many device manufacturers have used free-standing bulk GaN substrates to produce laser diodes (LDs) and light-emitting diodes (LEDs) for lighting, optical storage, and other purposes. GaN substrates are attractive in that it is easy to obtain high-quality III-nitride-based semiconductor layers having low defect densities by homo-epitaxial growth on GaN substrates.

However, GaN substrates, which are typically produced using HVPE (hydride vapor phase epitaxy), are very expensive. Moreover, nonpolar and semipolar GaN substrates are more expensive than polar (c-plane) GaN substrates. For example, 2-inch polar GaN substrates cost about $1,000/wafer, while 2-inch nonpolar or semipolar GaN substrates cost about $10,000/wafer.

As a result, researchers have investigated removing III-nitride-based semiconductor layers from GaN substrates after the device is manufactured. Such a technique would result in a GaN substrate that can be recycled, which would ultimately provide very cheap and high quality GaN devices for customers.

It is easy to remove epitaxial layers from a foreign substrate, such as sapphire/GaN, Si/GaN, etc., at a hetero-interface using laser ablation or other techniques. However, GaN substrates and III-nitride-based semiconductor layers lack a hetero-interface, which makes it difficult to remove the III-nitride-based semiconductor layers from GaN substrates.

Consequently, there is a need for a technique that removes III-nitride-based semiconductor layers from III-nitride-based substrates or layers in an easy manner.

In one previous technique, a GaN layer is spalled by a stressor layer of metal under tensile strain. See, e.g., Applied Physics Express 6 (2013) 112301, U.S. Pat. Nos. 8,450,184, 9,748,353, 9,245,747, and 9,058,990, which are incorporated by reference herein. Specifically, this technique uses spalling in the middle of the GaN layer.

However, surface morphology on a spalling plane is rough and the spalling position cannot be controlled. Moreover, this removal method may damage the semiconductor layers due to excess bending in the layer that is being removed, which may result in cracks in unintended directions. Thus, it is necessary to reduce any such damage and surface roughness.

Another conventional technique is the use of photoelectrochemical (PEC) etching of sacrificial layers to remove device structures from GaN substrates, but this takes a long time and involves several complicated processes. Moreover, the yield from these processes have not reached industry expectations.

Thus, there is a need in the art for improved methods of removing III-nitride-based substrates from III-nitride-based semiconductor layers, especially where GaN thin films are grown on GaN substrates. The present invention satisfies this need.

### SUMMARY OF THE INVENTION

To overcome the limitations in the prior art described above, and to overcome other limitations that will become apparent upon reading and understanding this specification, the present invention discloses a method of removing island-like semiconductor layers from a semiconducting substrate, in particular, island-like III-nitride semiconductor layers from a III-nitride-based substrate or hetero-substrate, using a polymer/adhesive film and a controlled temperature and pressure ambient.

The method forms the III-nitride-based semiconductor layers into an island-like structure that includes a horizontal trench at a lower portion of each island-like structure extending inwards to its center using an epitaxial lateral overgrowth (ELO) mechanism. The application of stress to the island-like structure is due to differences in thermal expansion between the island-like structure and the polymer/adhesive film bonded to the island-like structure. The polymer/adhesive film is chosen to have a different, e.g., larger, thermal expansion coefficient than at least the substrate.

Once removed, the substrate, in particular, the III-nitride-based substrate or hetero-substrate, can be recycled, resulting in cost savings for device fabrication. Additionally, this method ensures a 100% yield as it can be applied several times on the same substrate until all island-like structures are removed without elongated lead-times.

The method provides advantages in the fabrication of both laser diodes and light-emitting diodes, namely, easy removal of the III-nitride-based substrate or hetero-substrate, little damage to the III-nitride-based semiconductor layers, smooth cleaving surfaces, and short processing times at a lower cost.

### BRIEF DESCRIPTION OF THE DRAWINGS

Referring now to the drawings in which like reference numbers represent corresponding parts throughout:

FIGS. 1(a) and 1(b) illustrate a device structure fabricated according to the present invention's Type 1 design, wherein FIG. 1(a) is a cross-sectional view and FIG. 1(b) is a top view.

FIG. 2(a) is a typical structure of laser diode device and FIG. 2(b) is light emitting diode device.

FIG. 3(a) and FIG. 3(b) represent Type 2 and Type 3 designs, respectively; FIG. 3(c) illustrates a dry-etched Type 3 design; FIG. 3(d) shows a magnified top view of one of the sub-masks patch of Type 2 design, which also illustrates a resulting sub-mask patch pattern after dry etching a Type 3 design; FIG. 3(e) shows a cross section view; and FIGS. 3(f) and 3(g) illustrate typical structures of laser diode and light emitting diode devices on Type 2 and Type 3 designs, respectively.

FIG. 4(a) illustrates a typical mask for a Type 4 design of the present invention; FIG. 4(b) shows epitaxial lateral overgrowth layers from the top view on a Type 4 design and its cross-section view is shown in FIG. 4(c), FIG. 4(d) is a typical structure of a device on a Type 4 design; and FIGS. 4(e), 4(f), 4(g) and 4(h) show schematic views of possible design patterns using Type 4 designs.

FIGS. 5(a) and 5(b) are schematics illustrating of the steps for growing III-nitride layers and dissolving a growth restrict mask, respectively.

FIGS. 6(a) and 6(b) are schematic illustrations of the steps for placing a polymer/adhesive film on top of Type 1 and Type 4 designs as shown in FIG. 6(a), and on top of Type 2 and Type 3 designs as shown in FIG. 6(b).

FIGS. 7(a), 7(b), 7(c) and 7(d) are schematic illustrations of the steps for applying pressure on Type 1 and Type 4 designs as shown in FIG. 7(a), and on Type 2 and Type 3 designs as shown in FIG. 7(b); and for applying a polymer/adhesive film on epitaxial lateral overgrowth layers of the designs using a compressible material as shown in FIGS. 7(c) and 7(d).

FIGS. 8(a) and 8(b) are images of a proof-of-concept for one of the techniques mentioned in this invention, where it is not necessary for a polymer/adhesive film to reach the III-nitride-based substrate when removing at least two epitaxial lateral overgrowth layers at a time.

FIGS. 9(a), 9(b) and 9(c) are a schematic and photographic images showing the original equipment used in this invention.

FIG. 10 is a schematic view of the step for lowering or raising the structure's temperature according to the present invention.

FIG. 11(a) is a schematic of the epitaxial lateral overgrowth layers grown over an opening area in the growth restrict mask, and FIG. 11(b) is a cross-sectional transmission electron microscope (TEM) image at the interface between the epitaxial lateral overgrowth layers and the substrate near the edge of the opening area.

FIG. 12(a) is a schematic representation of a commercialized automated chamber having required functions and elements to realize this invention; and FIG. 12(b) is a flowchart that illustrates the process flow.

FIG. 13(a) is a schematic representation of a substrate after placing a polymer/adhesive film; FIG. 13(b) represents the peeling direction of the polymer/adhesive film from a top view; and FIG. 13(c) represents the peeling direction of the polymer/adhesive film from a cross-section view.

FIGS. 14(a), 14(b) and 14(c) are schematics depicting one way to form a horizontal trench in the island-like III-nitride semiconductor layers.

FIGS. 15(a) and 15(b) are schematic views of alternative films used in realizing this invention.

FIG. 16 is a schematic representation of the typical layers involved in designing a laser diode device and its schematic over a wing region of the epitaxial lateral overgrowth.

FIGS. 17(a) and 17(b) illustrate how chip scribing is performed.

FIGS. 18(a), 18(b), 18(c), 18(d) and 18(e) are scanning electron microscope (SEM) images of (0001) surfaces of III-nitride-based substrates before and after removing island-like III-nitride semiconductor layers; FIGS. 18(f), 18(g) and 18(h) are optical microscope images of the removed island-like III-nitride semiconductor layers on a polymer/adhesive film; and FIGS. 18(i) and 18(j) are SEM images of the back surface of the removed island-like III-nitride semiconductor layers.

FIGS. 19(a) and 19(b) are reference images following removal of epitaxial lateral overgrowth layers from a c-plane substrate when no temperature is applied while practicing the invention.

FIGS. 20(a), 20(b), 20(c) and 20(d) are optical microscope images before and after removing island-like III-nitride semiconductor layers from a (10-10) surface of the III-nitride-based substrate; FIG. 20(e) shows optical microscope images of the removed epitaxial lateral overgrowth layers on polymer/adhesive films indicating the range of opening areas that can be removed using this invention; and FIG. 20(f) is an optical microscope image of an irregular shape on a polymer/adhesive film removed using this invention.

FIGS. 21(a), 21(b), 21(c), 21(d) and 21(e) are optical microscope images illustrating a proof-of-concept demonstration for Type 2 designs mentioned in the invention, wherein FIGS. 21(b), 21(c) and 21(d) are optical microscope images of removed epitaxial lateral overgrowth layers on a polymer/adhesive film, and FIGS. 21(a) and 21(e) are substrate images after removing the epitaxial lateral overgrowth layers.

FIGS. 22(a), 22(b), 22(c) and 22(d) are optical microscope images illustrating a proof-of-concept demonstration for Type 4 designs mentioned in the invention, wherein FIGS. 22(a), 22(c) and 22(d) are substrate images after removing the epitaxial lateral overgrowth layers, and FIG. 22(b) shows the epitaxial lateral overgrowth layers on a polymer/adhesive film.

FIG. 23(a) shows optical microscope images of substrates with (10-10), (20-21), (20-2-1) orientations after removing island-like III-nitride semiconductor layers having opening areas with a width of 2 μm, 4 μm and 6 μm; and FIG. 23(b) shows images of removed epitaxial lateral overgrowth layers on a polymer/adhesive film from the substrates with the (10-10), (20-21), (20-2-1) orientations.

FIG. 24 is an image of a surface of an m-plane substrate after the epitaxial lateral overgrowth layers have been removed.

FIGS. 25(a), 25(b), 25(c), 25(d) and 25(e) are optical microscope images of epitaxial lateral overgrowth layers comprised of AlGaN before and after being removed from a III-nitride-based substrate.

FIG. 26 includes both schematics and SEM images illustrating the effects of SiO₂ and Silk on an interface with epitaxial lateral overgrowth layers grown on a III-nitride-based substrate, wherein the images show the interface effects on a backside portion of the layers.

FIGS. 27(a), 7(b), 27(c) and 27(d) are schematic illustrations of alternative attachment methods for a polymer/adhesive film to realize the invention, wherein these techniques modify the applied stress while lowering or raising temperature.

FIGS. 28(a), 28(b), 28(c), 28(d), 28(e) and 28(f) are optical microscopic images of the island-like III-nitride semiconductor layers grown using MOCVD on substrates with orientations of (10-10), (10-11), (20-21), (30-31), (11-22), (10-1-1), (20-2-1), (30-3-1), (11-2-2), after the island-like III-nitride semiconductor layers have been removed from the substrates using a polymer/adhesive film.

FIGS. 29(a), 29(b), 29(c) and 29(d) are schematic illustrations of an alternative attachment method for polymer/adhesive films, which modifies the applied stress while lowering or raising temperature.

FIGS. 30(a), 30(b), 30(c) and 30(d) are schematic views showing how to peel off epitaxial layers from large-scale wafers using a polymer/adhesive film and applying local thermal stress.

FIGS. 31(a), 31(b), 31(c) and 31(d) are schematic views showing how to peel off at least two epitaxial lateral overgrowth layers at a selective region after growing them on a substrate.

FIGS. 32(a), 32(b) and 32(c) are schematic views showing how to mass produce displays using laser diode devices of this invention, while FIGS. 32(d) and 32(e) are schematic views showing how to mass produce displays using light emitting diode devices of this invention.

FIG. 33 is a schematic view and flowchart showing how to peel off at least one epitaxial lateral overgrowth layer at a selective region from the grown substrate.

FIG. 34(a) is an image of epitaxial lateral overgrowth layers grown on an m-plane substrate using on a growth restrict mask having opening areas of 50 μm and mask stripes of 50 μm; and FIG. 34(b) is an image of epitaxial lateral overgrowth layers transferred onto a polymer/adhesive film using this invention.

35(a) is an image of epitaxial lateral overgrowth layers grown on an m-plane substrate using a growth restrict mask having opening areas of 100 μm and mask stripes of 50 μm; and FIG. 35(b) is an image of epitaxial lateral overgrowth layers transferred onto a polymer/adhesive film using this invention.

FIG. 36(a) is an image of epitaxial lateral overgrowth layers grown on an to-plane substrate using a growth restrict mask having opening areas of 200 μm and mask stripes of 50 μm; and FIG. 36(b) is an image of epitaxial lateral overgrowth layers transferred onto a polymer/adhesive film using this invention.

FIG. 37 includes images of the surface of the substrate following removal of the island-like III-nitride semiconductor layers at an opening area.

FIGS. 38(a) and 38(b) are schematics illustrating the surface of the substrate following removal of the island-like III-nitride semiconductor layers at an opening area.

FIG. 39 is a flowchart that illustrates a method of removing semiconductor layers from a substrate.

### DETAILED DESCRIPTION OF THE INVENTION

In the following description of the preferred embodiment, reference is made to a specific embodiment in which the invention may be practiced. It is to be understood that other embodiments may be utilized and structural changes may be made without departing from the scope of the present invention.

### Overview

The present invention discloses a method for removing epitaxial semiconducting layers from a semiconducting substrate by separating the epitaxial semiconducting layers as island-like structures having a horizontal trench at a lower portion of the structure extending inwards towards its center. A combination of dry etching and chemical etching, or epitaxial lateral overgrowth (ELO), are two options to form the horizontal trench; however, the invention is not limited to these options. The ELO method is particularly useful for obtaining horizontal trenches on III-nitride-based semiconductor layers.

The epitaxially-grown III-nitride-based semiconductor layers are removed from the III-nitride-based substrate or hetero-substrate using a polymer/adhesive film, with a combination of controlled parameters, such as raising or lowering the temperature after bonding the film to the III-nitride-based semiconductor layers, and lowering or raising the temperature while a certain amount of pressure is applied to the film and the III-nitride-based semiconductor layers, followed by cleaving or cracking the III-nitride-based semiconductor layers to remove them from the substrate, and then recycling the substrate.

As long as it enables growth of a III-nitride layer through a growth restrict mask, any III-nitride-based substrate, such as GaN, may be used. Moreover, this technique can be applied to remove III-nitride semiconductor layers from any plane of the III-nitride-based substrate independent of crystal orientation.

In alternative embodiments, a foreign or hetero-substrate, such as sapphire (Al₂O₃), SiC, LiAlO₂, Si, etc., may be substituted for the III-nitride-based substrate. In addition, this invention can also be extended to removing semiconducting layers containing other materials, such as InP, GaAs, GaAsInP, etc.

The III-nitride-based semiconductor layers and the III-nitride-based substrate refer to any composition or material related to (B, Al, Ga, In) N semiconductors having the formula B_{w}AlₓGa_{y}In_{z}N where 0≤w≤1, 0≤x≤1, 0≤y≤1, 0≤z≤1, and w+x+y+z=1. Further, compositions and materials within the scope of the invention may further include quantities of dopants and/or other impurity materials and/or other inclusional materials such as Mg, Si, O, C, H, etc.

The island-like III-nitride semiconductor layers are epitaxially grown on or above the III-nitride-based substrate and/or an intermediate layer, The quality of the island-like III-nitride semiconductor layers is extremely high, and a device comprised of the III-nitride-based semiconductor layers is of extremely high quality. However, it is hard to separate III-nitride-based semiconductor layers from a III-nitride-based substrate. It has been discovered that ELO III-nitride layers can be easily removed from a III-nitride-based substrate using the polymer/adhesive film under a controlled temperature and pressure.

One technique is to use a growth restrict mask, which may be a dielectric film or metals, such as SiO₂, SiN, HfO₂, Al₂O₃, TiN, Ti, etc., in this substrate removal technique. The interface between the growth restrict mask and any subsequent III-nitride-based semiconductor layers grown by ELO on the mask has a weak bonding strength. The bonding area is controlled so that it is less than the device size, Thus, it is easy to remove III-nitride device layers from the substrate using ELO III-nitride layers.

The growth restrict mask is patterned and the island-like III-nitride semiconductor layers are grown on the patterned mask, beginning with the ELO III-nitride layers. Adjacent island-like III-nitride semiconductor layers do not coalesce, which leaves a space between them that is a recess region, and later this space will be used to crack or cleave the III-nitride-based semiconductor layers from the substrate. Also, the non-coalescence pattern of ELO III-nitride layers helps in releasing internal strain of the layers, avoiding any occurrences of cracks, resulting an improved performance from the devices made using this technique. Additionally, the space between islands enhances the contact portion between the polymer/adhesive film and the III-nitride-based semiconductor layers through providing access to reach deeper sides.

Particularly, the ultra-violet (UV) optical device field is experiencing similar problems as the III-nitride semiconductor field. Higher Aluminum composition epitaxial layers of AlGaN, AlN, etc., must be grown on substrates which support growth of these layers, in order to achieve functional UV optical devices. And, at the end, it is preferred to remove the desired operational wavelength absorbing substrate for proper device operation. This invention would satisfy both of these needs, by facilitating a higher Al composition in the epitaxial layers via the island-like pattern growth without significant stress in the epi-layers, and by removing an unnecessary substrate from the device, by practicing the technique mentioned in the following.

A breaking point in this method is around the interface between device layer and the substrate surface. The breaking point is different depending on the substrate planes, substrate materials and growth restrict mask thickness and materials.

This method dissolves the mask using a hydrofluoric acid (HF), buffered HF (BHF), or another etchant, before removing the substrate. Thereafter, the III-nitride-based semiconductor layers are bonded to a polymer/adhesive film, by slightly applying a pressure on top of epi-layers, wherein the film is later chemically dissolved in a solvent.

After dissolving the growth restrict mask, the polymer/adhesive film is attached to the III-nitride semiconducting layers. In another embodiment, it is observed that when the film is wrapped effectively, such that to attain a maximum contact region between ELO-grown III-nitride semiconducting layers and the polymer/adhesive film, a better yield is obtained. To achieve this, the space between adjacent island-like layers is used.

Preferably, the polymer/adhesive film comprises two layers or more. For example, in two layers, a top layer which is harder than a bottom layer contacts the epilayers. By such a structure, the bottom layer can easily be placed into the recess portion between the adjacent island-like III-nitride-based semiconductor layers before applying the pressure to the layers. By doing this, the polymer/adhesive film can apply pressure from the side facets of the island-like III-nitride-based semiconductor layers efficiently. Moreover, changing the temperature, for example, lowering the temperature while applying the polymer/adhesive film avoids forming cracks when shrinking the polymer/adhesive film.

After attaching the polymer/adhesive film to the island-like III-nitride-based semiconductor layers, pressure is applied on the combination and the structure is inserted into a liquid nitrogen bath to alter the temperature of the combination. The combination is then pulled out of the temperature bath and brought back to room temperature by blowing a dry nitrogen gas.

One key technique of this invention is to decrease the temperature of the polymer/adhesive film and the substrate, which results in two mechanisms occurring at the same time. One is to apply the pressure to the island-like III-nitride-based semiconductor layers (in a concavity and convexity region) using the difference between the polymer/adhesive films and the island-like III-nitride-based semiconductor layers. Another is to harden the polymer/adhesive film by lowering the temperature. These two mechanisms make it easy to apply pressure to the island-like III-nitride-based semiconductor layers efficiently and uniformly. Moreover, it is much preferable that a bottom surface of the polymer/adhesive film at least reaches below the surface of the convexity region. By doing this, the pressure is efficiently applied to the island-like III-nitride-based semiconductor layers.

The rapid contraction and expansion shock experienced by polymer/adhesive film during this temperature cycle, and the difference in thermal expansion and contraction behavior between the polymer/adhesive film and the island-like III-based semiconductor layers initiates a crack or cleave at an interface between the layers and the substrate.

This technique can also be practiced by raising and lowering the temperature. Also, it is possible to use non-flexible support substrates which have a thermal expansion different from the III-nitride-based substrate. The combination is then heated after bonding the polymer/adhesive film. Stress is applied to the island-like III-nitride-based semiconductor layers, which are bonded to the support substrate, due to the differences in thermal expansion between the substrates.

This stress is applied at the weakest point between the island-like III-nitride-based semiconductor layers and the III-nitride-based substrate, namely the ELO III-nitride layers at the opening areas of the growth restrict mask. The breaking starts from one side of the opening areas, which is at an edge of the growth restrict mask, and proceeds to the opposite side of the edge.

The device or chip size, which is the width of the island-like III-nitride semiconductor layers, generally is wider than the peeled length along the peeled surface. As a result, less force or pressure can be used to remove the island-like semiconductor layers. This avoids degradation of the device and reduction in yields.

The peeling or cleaving technique uses a trigger to start the (breaking) cleaving. The trigger may be the stress resulting from the differences in thermal expansion, but other triggers may be used as well. For example, mechanical force, such as ultra-sonic waves, can be used as the trigger for the cleaving technique.

Also, crack or cleave trigging could occur at a fragile region at the sides of the opening areas that is particularly present in the case of the ELO growth mechanism. The ELO III-nitride layers bend over the growth restrict mask at the sides of the opening areas near the interface between the substrate and the growth restrict mask. During the process of bending, defects that originate from the opening areas of the substrate also bend towards the growth restrict mask, resulting in a higher defect density region at the sides of the opening areas at the interface, as compared to other portions of the epitaxial layer, resulting a fragile region near the sides of the opening region.

If mechanical forces are used, removal of the III-nitride-based substrate is achieved quickly and with very weak stress. Furthermore, the cleaving point may be a wedge shape, which simplifies the cleaving. The shape of the cleaving point is important to achieve a high yield.

Using these methods, device layers can be easily removed from the III-nitride-based substrates and wafers, including wafers of large size, over 2 inches. For devices needing AlGaN layers, this is very useful, especially in the case of high Al content layers.

### Technical Description

Generally, the present invention describes a method for manufacturing a semiconductor device comprising the steps of: forming a growth restrict mask with a plurality of opening areas directly or indirectly upon a substrate, wherein the substrate is a III-nitride-based semiconductor; and growing a plurality of island-like III-nitride semiconductor layers upon the substrate using the growth restrict mask, such that the growth extends in a direction parallel to the striped opening areas of the growth restrict mask, and the island-like III-nitride semiconductor layers are prevented from coalescing.

However, the present invention is not limited to layers that do not coalesce. For example, epitaxial lateral overgrowth may bury the growth restrict mask at certain regions. In that case, the growth restrict mask is first exposed by a dry etching process and then dissolve it using a chemical etchant resulting convex concave shape regions will be identified.

The III-nitride-based semiconductor layers can be removed from the III-nitride-based substrate by at least partially dissolving the growth restrict mask using a wet etching technique. Then, a peeling (cleaving) technique is used to separate the III-nitride-based semiconductor layers from the III-nitride-based substrate.

An n-electrode and bonding pad are deposited on the opposite side of the device. The opposite side is the facet removed from substrate. Off course, the electrode can be disposed on the top surface. The device may be a light-emitting diode, laser diode, Schottky barrier diode, or metal-oxide-semiconductor field-effect-transistor, micro-light emitting diode, Vertical Cavity Surface Emitting Laser device.

Finally, the removed III-nitride-based substrate then can be recycled by polishing the surface of the substrate. The steps are repeated, and III-nitride-based semiconductor layers are again deposited on the III-nitride-based substrate.

Specifically, the method includes the following steps:

1. Semiconductor Layers

The present invention applied to the following variations in growth restrict mask designs, however, it is not limited to these designs. Epitaxial GaN layers are grown on III-nitride-based substrate patterned with growth restrict mask containing any of the following materials, for example, SiO₂, SiN, or a combination of SiO₂ and SiN, or HfO₂, Al₂O₃, MgF, TiN, Ti etc.

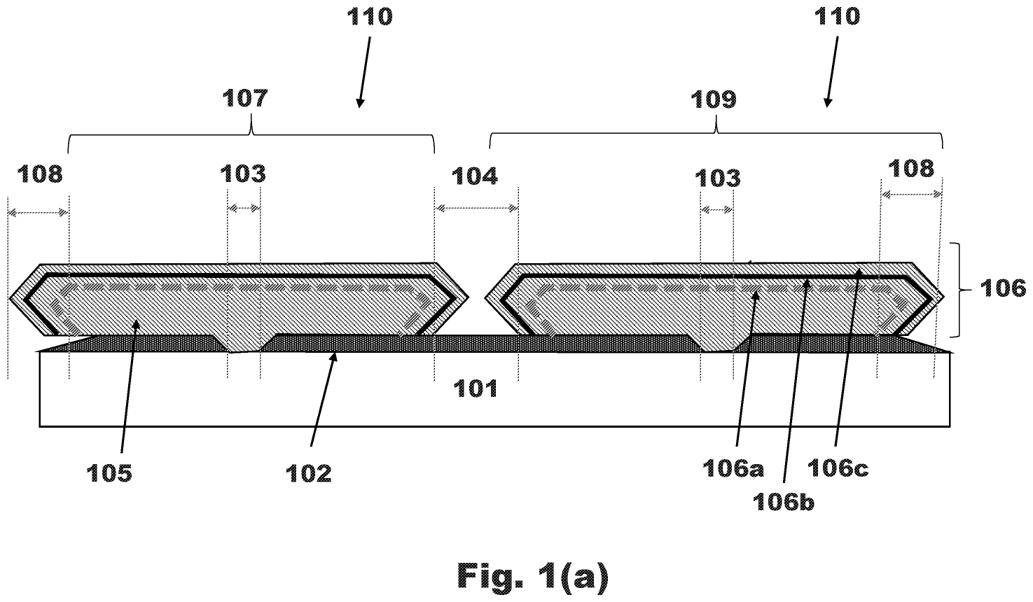

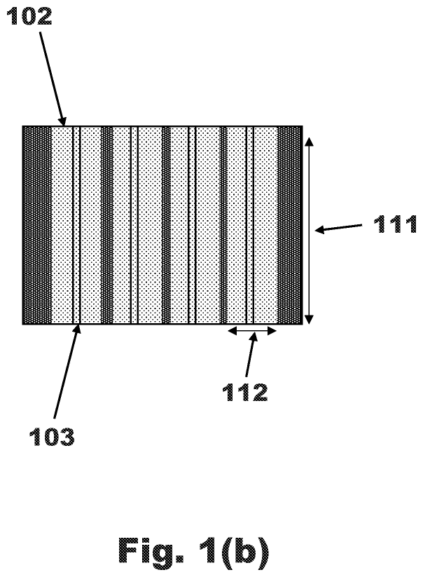

FIGS. 1(a) and 1(b) illustrate a device structure fabricated according to a Type 1 design, wherein FIG. 1(a) is a cross-sectional view and FIG. 1(b) is a top view.

In this example, a III-nitride-based substrate 101 is provided, such as a bulk GaN substrate 101, and a growth restrict mask 102 is formed on or above the substrate 101. Opening areas 103 are defined in the growth restrict mask 102, resulting in the growth restrict mask 102 having stripes.

The growth restrict mask 102 has a width ranging from 50 μm to 100 μm and an interval of 2 μm to 200 μm, wherein a length of the opening areas 103 extends in a first direction 111 and a width of the opening areas 103 extends in a second direction 112, as shown in FIG. 1(b), The growth restrict mask 102 stripes are vertical to <11-20> axis for semi-polar and non-polar III-nitride-based substrates 101 and along a non-polar direction for C-plane III-nitride-based substrates 101.

No-growth regions 104 result when ELO III-nitride layers 105, grown from the adjacent opening areas 103 in the growth restrict mask 102, are made not to coalesce on top of the growth restrict mask 102. Growth conditions are optimized such that the ELO III-nitride layers 105 have a lateral width of 20 μm on a wing region thereof.

Additional III-nitride semiconductor device layers 106 are deposited on or above the ELO III-nitride layers 105, and may include an active region 106a, an electron blocking layer (EBL) 106b, and a cladding layer 106c, as well as other layers.

The thickness of the ELO III-nitride layers 105 is important, because it determines the width of one or more flat surface regions 107 and layer bending regions 108 at the edges thereof adjacent the no-growth regions 104. The width of the flat surface region 107 is preferably at least 5 μm, and more preferably is 10 μm or more, and most preferably is 20 μm or more.

The ELO III-nitride layers 105 and the additional III-nitride semiconductor device layers 106 are referred to as island-like III-nitride semiconductor layers 109, wherein adjacent island-like III-nitride semiconductor layers 109 are separated by no-growth regions 104. The distance between the island-like III-nitride semiconductor layers 109 is the width of the no-growth region 104. The distance between the island-like III-nitride semiconductor layers 109 adjacent to each other is generally 20 μm or less, and preferably 5 μm or less, but is not limited to these values.

Each of the island-like III-nitride semiconductor layers 109 may be processed into a separate device 110. The device 110, which may be a light-emitting diode (LED), laser diode (LD), Schottky barrier diode (SBD), or metal-oxide-semiconductor field-effect-transistor (MOSFET), is processed on the flat surface region 107 and/or the opening areas 103. Moreover, the shape of the device 110 generally comprises a bar.

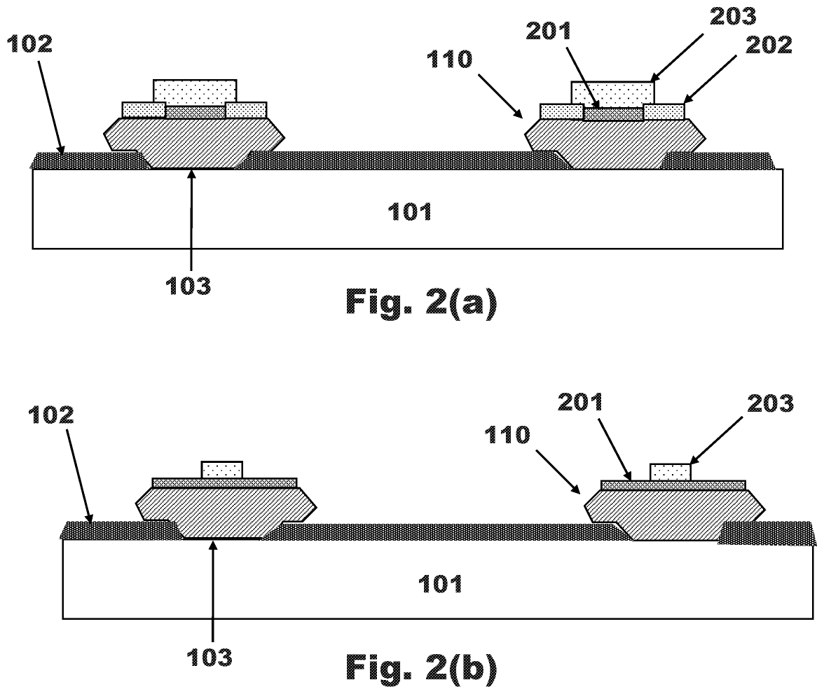

FIG. 2(a) shows a laser diode device 110 processed to include a ridge stripe comprising of a transparent conducting oxide (TCO) layer 201, a zirconium dioxide (ZrO₂) current limiting layer 202 and a p-type pad 203. FIG. 2(b) shows a light emitting diode device 110 that includes a TCO layer 201 and p-type pad 203.

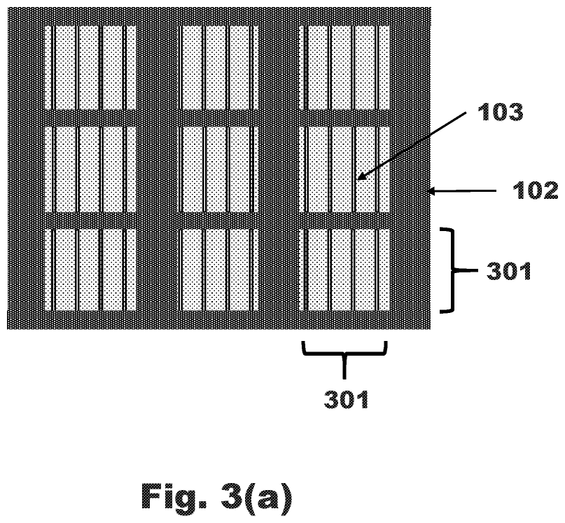

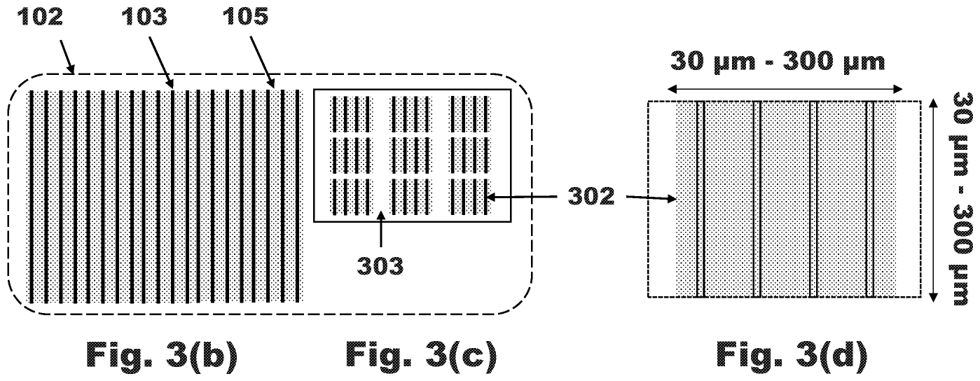

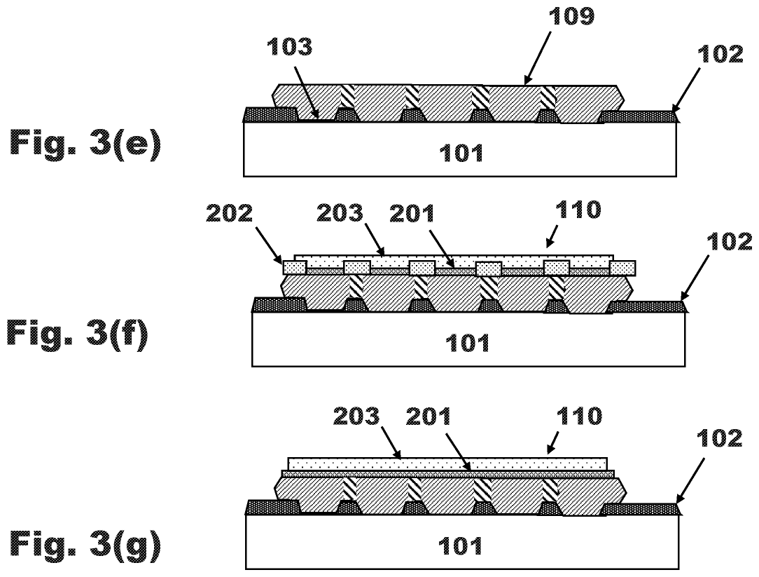

In a Type 2 design, as shown in FIG. 3(a), the growth restrict mask 102 has several sub masks 301. Each sub mask 301 has length and breadth dimensions varied from 30 μm to 300 μm. In each sub mask 301, the growth restrict mask 102 has open areas 103 with a width of 3 μm to 7 μm, and at an interval of 7 μm to 3 μm. The ELO III-nitride layers 105 grown in every sub mask 301 are made to coalesce and care is taken to stop the coalescence between adjacent sub masks 301.

In a Type 3 design, as shown in FIG. 3(b), the growth restrict mask 102 has opening areas 103 width of 3 μm to 7 μm at an interval of 7 μm to 3 μm, which are patterned throughout the entire growth restrict mask 102, wherein the growth restrict mask 102 stripes are vertical to a <11-20> axis for semi-polar and non-polar III-nitride-based substrates 101 and along a non-polar direction for C-plane III-nitride-based substrates 101.

The ELO III-nitride layers 105 grown from opening areas 103 in the growth restrict mask 102 are made to coalesce on top of the growth restrict mask 102 covering the entire surface, as shown in FIG. 3(b). The ELO III-nitride layers 105 are then divided into sub mask 301 patches 302 via etching in regions 303, as shown in FIG. 3(c). The sub mask 301 patches 302 are enlarged in FIG. 3(d).

A cross-sectional side view of the resulting structure, including the substrate 101, growth restrict mask 102, opening areas 103, and island-like III-nitride semiconductor layers 109, is shown in FIG. 3(e). As shown in FIG. 3(f), a ridge process may be performed to form an LD device 110, which may include TCO layer 201, ZrO₂ current limiting layer 202 and p-type pad 203. Otherwise, as shown in FIG. 3(g), a ridge process is not necessary to form an LED device 110, and a TCO layer 201 and p-type pad 203 are deposited.

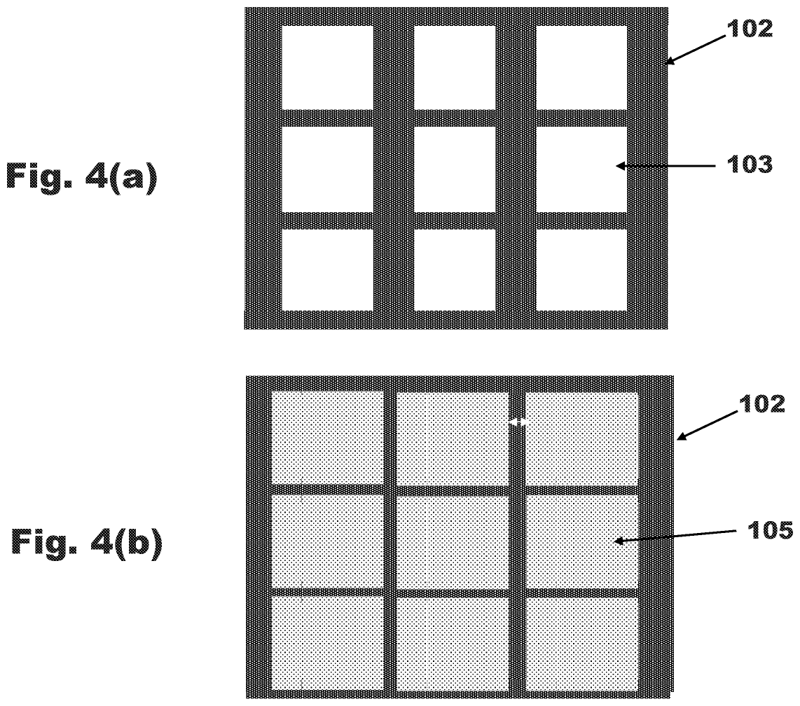

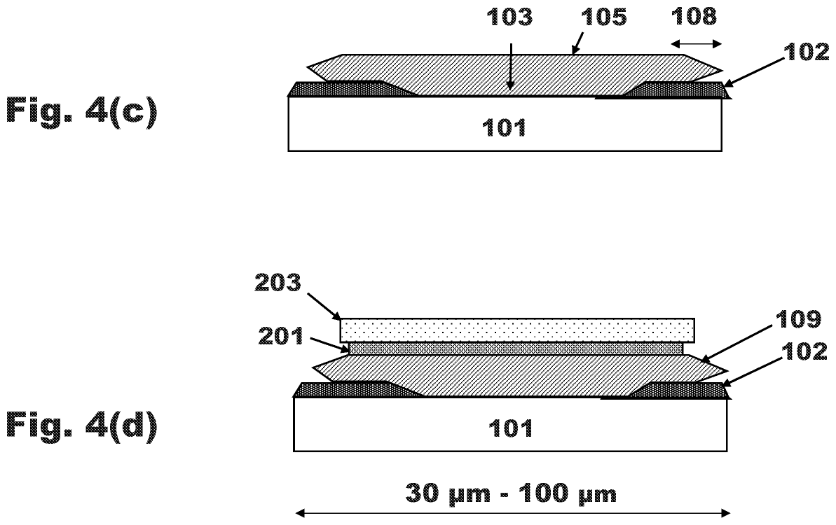

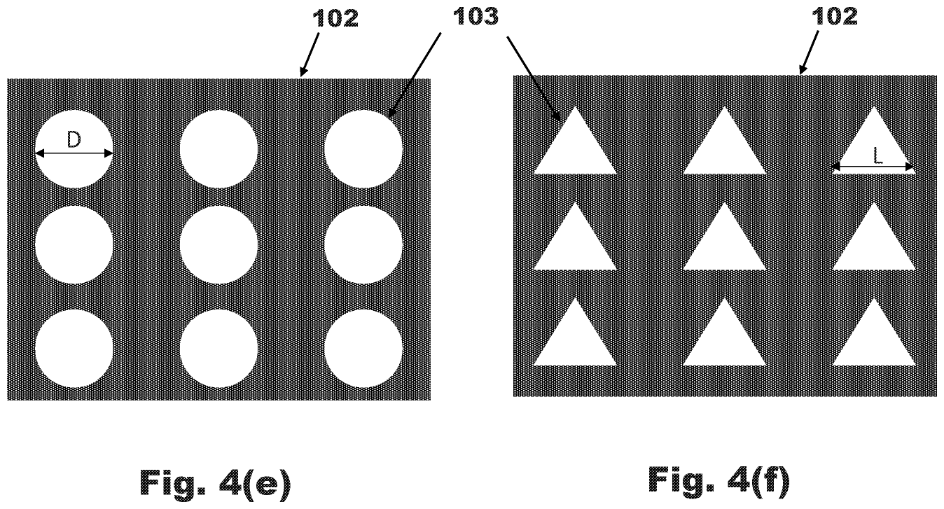

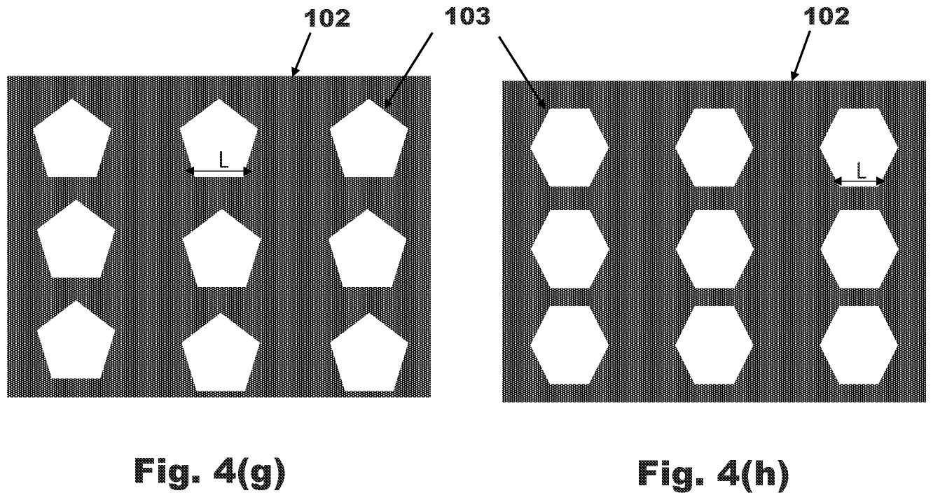

A Type 4 design is illustrated in FIG. 4(a), wherein the growth restrict mask 102 has opening areas 103, with a width of 30 μm to 100 μm at an interval of 20 μm to 30 μm, patterned over the entire substrate 101. The III-nitride layers 105 are grown on the opening areas 103, as shown in FIG. 4(b). FIG. 4(c) shows a cross sectional view of the ELO III-nitride layers 105 as grown. FIG. 4(d) shows a TCO layer 201 and p-type pad 203 deposited on the island-like III-nitride semiconductor layers 109.

Alternatively, growth restrict masks 102 having opening area 103 shapes different than square or rectangle may provide the pattern for a Type 4 design, as shown in FIGS. 4(e)-4(h), by maintaining the opening areas 103 of the mask 102 at least larger than 1 μm².

2. Removing the Growth Restrict Mask

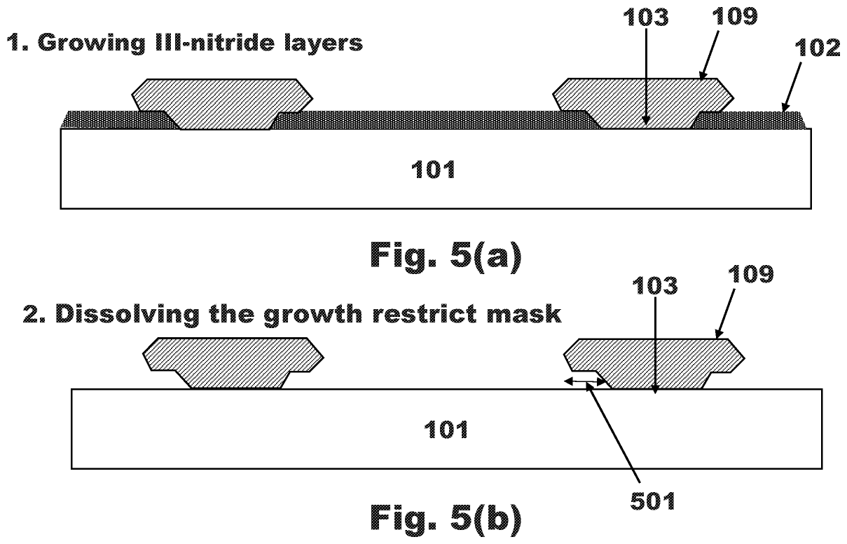

FIG. 5(a) shows the substrate 101, growth restrict mask 102, opening areas 103 and island-like III-nitride semiconductor layers 109, following the growth. As illustrated in FIG. 5(b), the growth restrict mask 102 is then removed using a chemical solution, such as hydrofluoric acid (HF) or buffered HF, resulting in a horizontal trench 501 under the island-like III-nitride semiconductor layers 109. Alternatively, dry etching can also be implemented to remove growth restrict mask 102.

3. Attaching the Film

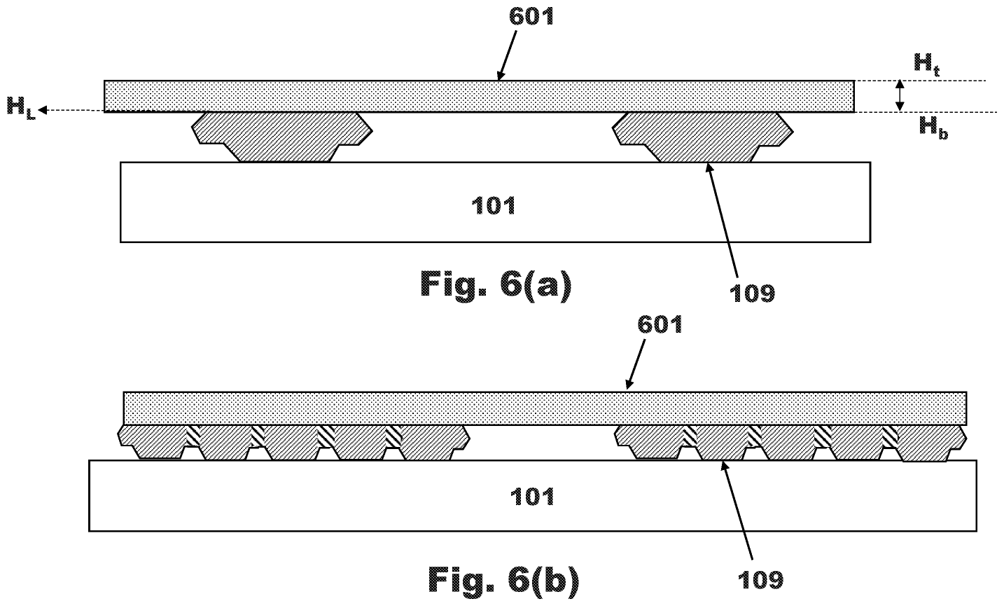

As shown in FIGS. 6(a) and 6(b), after dissolving the growth restrict mask 102, a polymer/adhesive film 601 is applied to the island-like III-nitride semiconductor layers 109. The polymer/adhesive film 601 preferably has a thickness of Hₜ-H_{b} and extends beyond the island-like III-nitride semiconductor layers 109 by a length of H_{L}.

It is observed that leaving a no-growth region 104 between neighboring island-like III-nitride semiconductor layers 109 helps the polymer/adhesive film 601 to comfortably fit to the shape of the island-like III-nitride semiconductor layers 109, resulting in an improved quality and yield for the removed devices 110. In this design, the no-growth regions 104 are between neighboring island-like III-nitride semiconductor layers 109 in the Type 1 and Type 4 designs, and are between neighboring patches 302 in the Type 2 design, and in the Type 3 design, are the etched portions, which divide the adjacent patches 302.

4. Applying Pressure

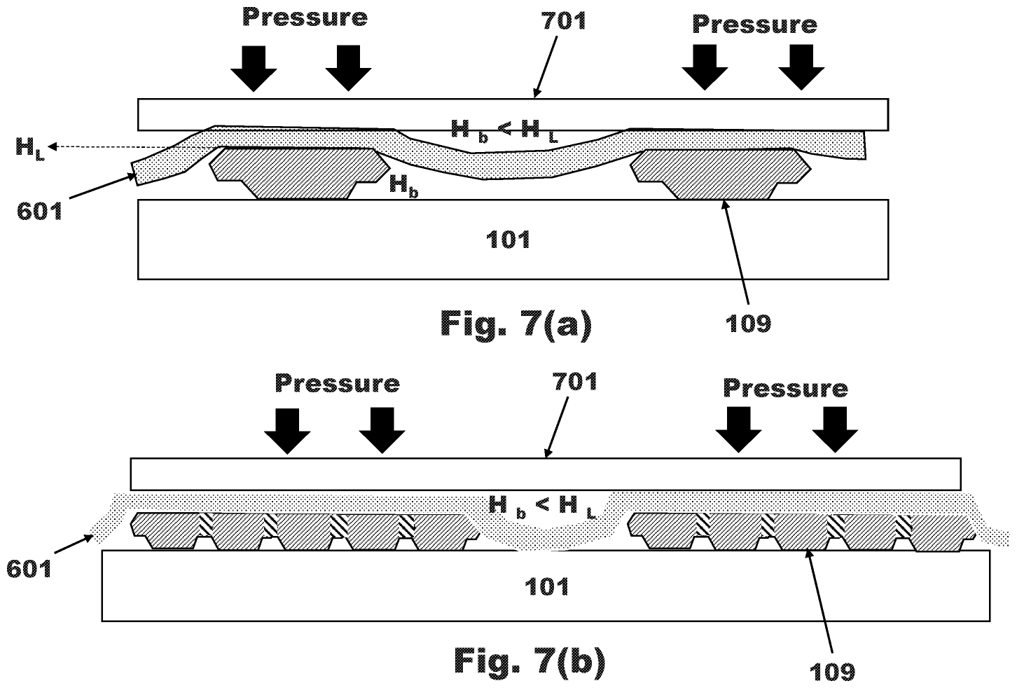

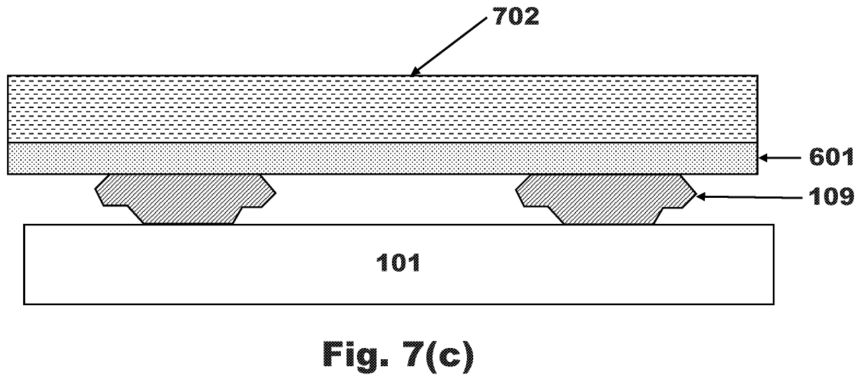

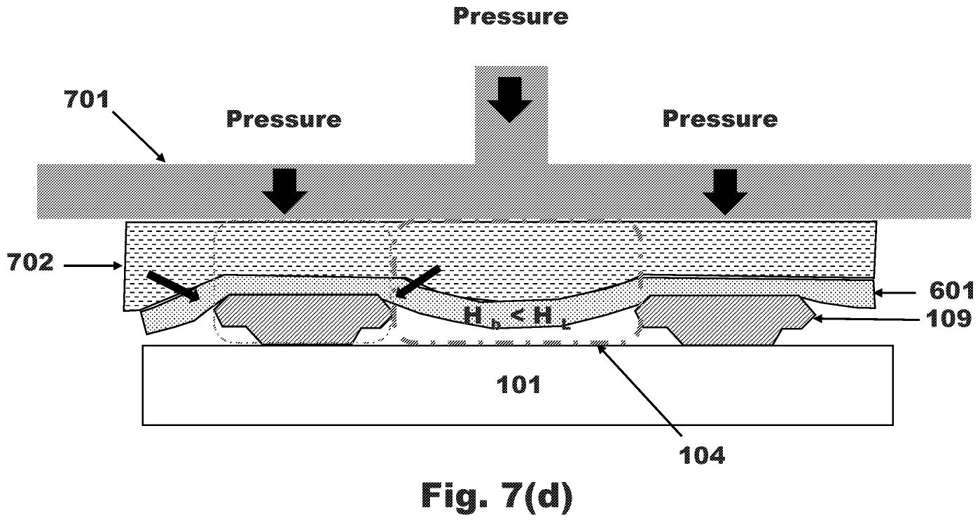

FIGS. 7(a) and 7(b) illustrate how, after attaching the polymer/adhesive film 601, the polymer/adhesive film 601 is slightly pressed against one or more sides of the island-like III-nitride semiconductor layers 109 using a suitable tool 701 without exceeding the cracking limit of the island-like III-nitride semiconductor layers 109, such that the bottom surface of the polymer/adhesive film 601, H_{b} should at least reach below the top surface of the island-like III-nitride semiconductor layers 109, H_{L}.

Alternatively, after placing the polymer/adhesive film 601 upon the island-like III-nitride semiconductor layers 109, a compressible material 702 can be placed over the polymer/adhesive film 601 to apply a pressure around the shape of the island-like III-nitride semiconductor layers 109, as illustrated in FIGS. 7(c) and 7(d). In such a case, as there is no material lying in between the polymer/adhesive film 601 and the substrate 101 at the no-growth region 104, the applied pressure on the compressible material 702 will be distributed effectively around the edges of the island-like III-nitride semiconductor layers 109, resulting in a frame of the polymer/adhesive film 601 around the island-like III-nitride semiconductor layers 109.

A more effective way can be realized, if the ambient temperature s raised or lowered in a controlled fashion while applying pressure, such that the polymer/adhesive film 601 fits around the island-like III-nitride semiconductor layers 109.

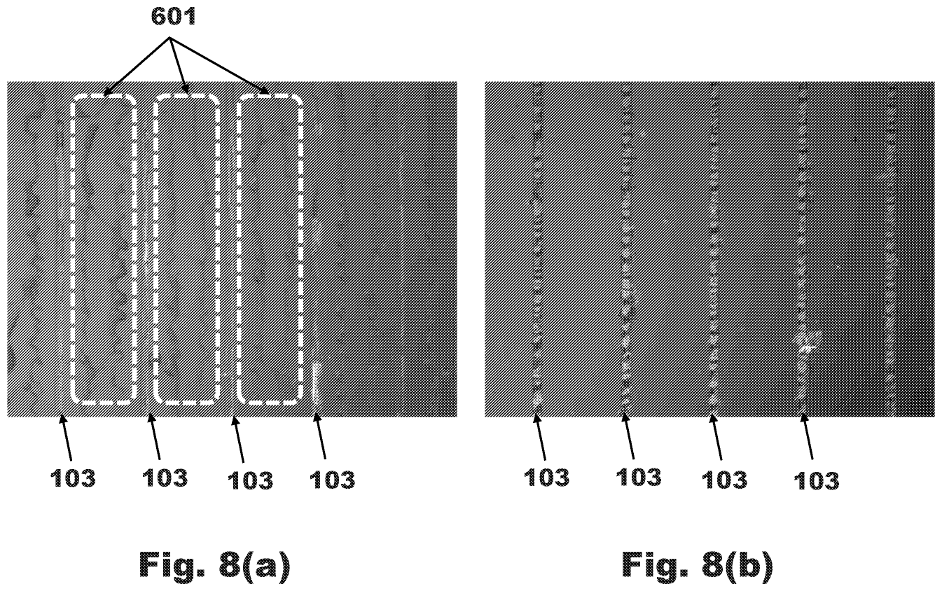

FIGS. 8(a) and 8(b), respectively, are images illustrating the cases of contacting the film 601 to the substrate 101 and not contacting the film 601 to the substrate 101. FIG. 8(a) shows residue remaining from the film 601, while FIG. 8(b) shows no residue. In both cases, the island-like III-nitride semiconductor layers 109 were removed. It is not necessary for the polymer/adhesive film 601 to contact the substrate 101 to remove the island-like III-nitride semiconductor layers 109.

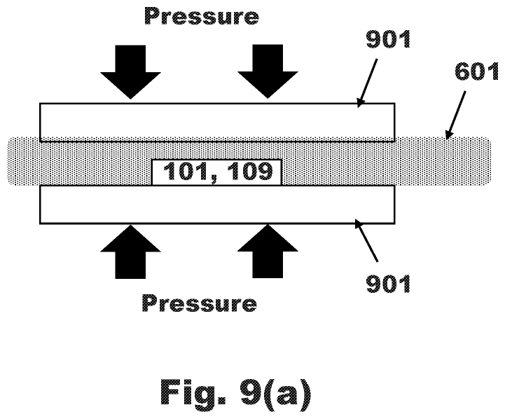

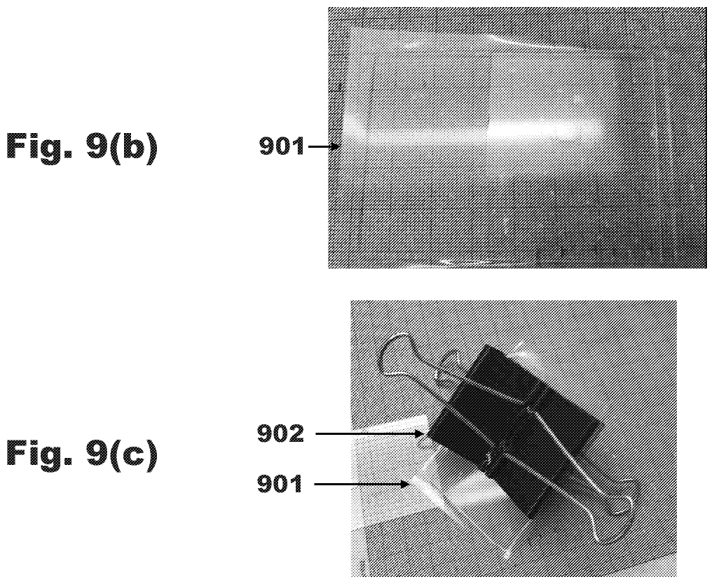

FIG. 9(a) is a schematic diagram and FIGS. 9(b) and 9(c) are images of the actual instrumentation used in realizing an alternative embodiment, wherein the polymer/adhesive film 601 is applied to a sample comprising the substrate 101 and the island-like III-nitride semiconductor layers 109, quartz plates 901 are applied to both sides of the sample 101, 109, and the polymer/adhesive film 601 and the quartz plates 901 are securely clamped by a metal clip 902, thereby applying pressure to the film 601.

5. Changing the Temperature

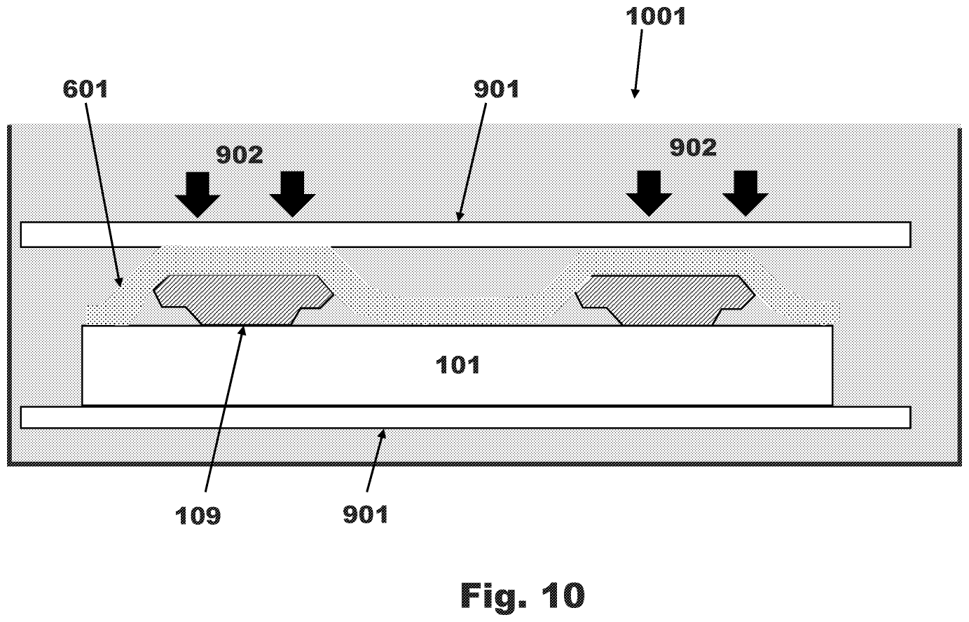

FIG. 10 illustrates an apparatus 1001 for changing the temperature of the sample 101, 109 with the polymer/adhesive film 601 sandwiched between two quartz plates 901 with a metal clamp 902. The temperature is lowered/raised from room temperature while applying pressure. The apparatus 1001 is then brought back to handling temperatures, such as room temperature, by constantly blowing dry nitrogen gas over the apparatus 1001, and pressure on the sample 101, 109 with the polymer/adhesive film 601 is released.

Bringing the sample 101, 109 with the polymer/adhesive film 601 back to a handling temperature can be accomplished by several alternatives, such as rising/lowering the temperature by placing the structure on a hot plate, heatsink, etc.

Alternatively, pressure on the sample 101, 109 with the polymer/adhesive film 601 can be released before lowering or raising temperature once the polymer/adhesive film 601 forms a nice layout around the island-like III-nitride semiconductor layers 109.

Rapid contraction and expansion shock experienced by the polymer/adhesive film 601 during this temperature cycle and the difference in thermal expansions between the polymer/adhesive film 601 and the island-like III-nitride semiconductor layers 109 may initiate a crack or cleave at the interface between the island-like III-nitride semiconductor layers 109 and the substrate 101.

Also, the crack or cleave could be at a fragile region at one or more sides of the opening areas 103 that is particularly present in the case of the ELO growth mechanism. The ELO III-nitride layers 105 bend over the growth restrict mask 102 at the sides of the opening areas 103 near the interface between the substrate 101 and the growth restrict mask 102. There is a higher defect density region at the sides of the opening areas 103 at the interface, as compared to other portions of the ELO III-nitride layers 105, resulting a fragile region near the sides of the opening areas 103.

FIGS. 11(a) and 11(b) are a schematic and transmission electron microscopy (TEM) image taken at one of the sides of the opening area 103 near the interface between the substrate 101 and the ELO III-nitride layer 105. The TEM image suggests that defects in the ELO III-nitride layer 105 are grouped at the sides of the opening area 103, as compared to other regions of the ELO III-nitride layer 105. The presence of these defects may be one of the reasons to initiate a crack due to the stress associated with the defects on the ELO III-nitride layer 105.

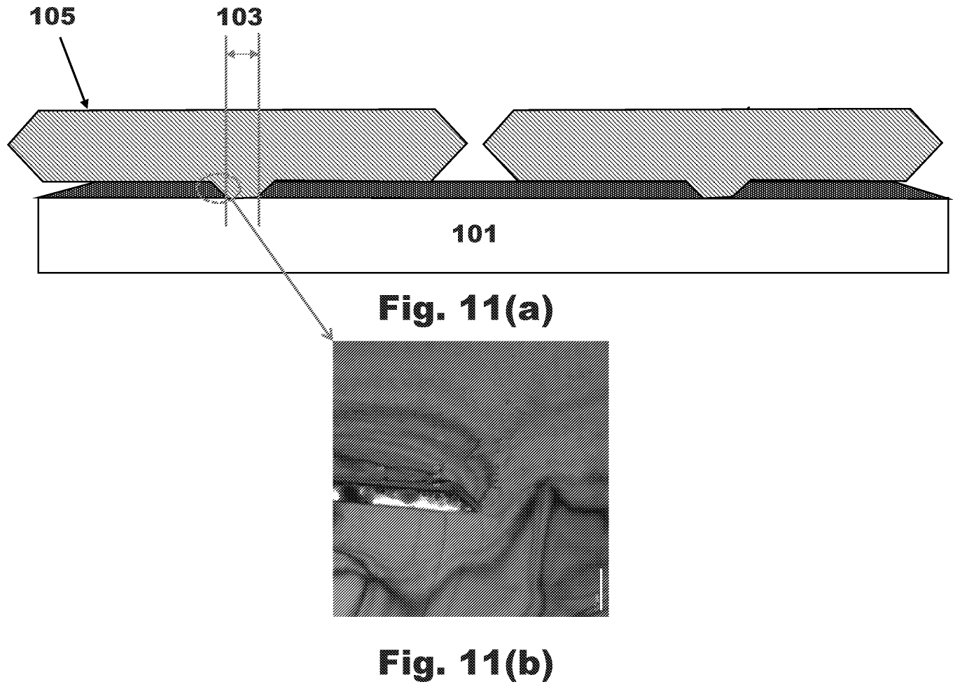

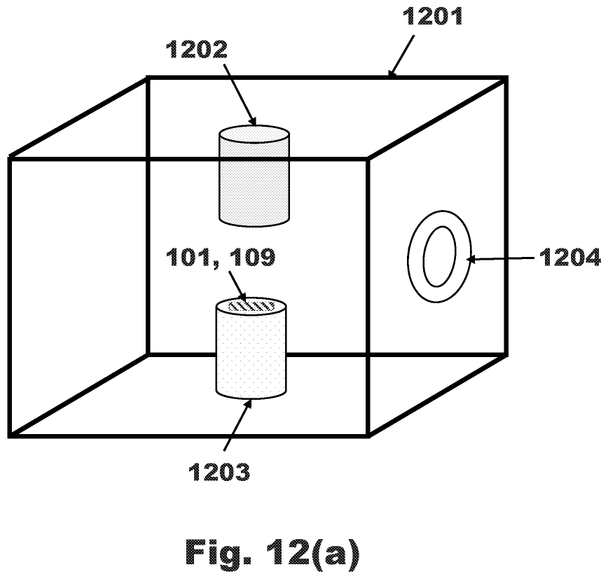

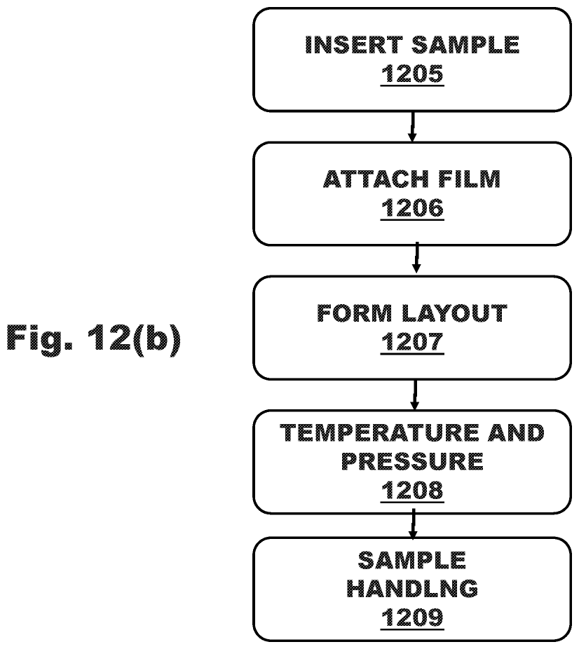

At an industrial level, the technique can be practiced with an automated chamber, which may include sample handling, gas valves for controlled environment, a hot plate to place samples, and which can also be capable of inducing sonification and a pressure application arm, etc. FIG. 12(a) is a schematic representation of an automated chamber having the required functions and elements to realize this invention, including a controlled ambient box 1201, robotic arms 1202, temperature controlled base with sonification function 1203, and sample handling port 1204; and FIG. 12(b) is a flowchart illustrating the process flow, which includes the steps of inserting the sample 101, 109 (1205), attaching the polymer film 601 (1206), forming a layout according to patterns on the substrate 101 (1207), programmed temperature and/or pressure changes (1208), and sample 101, 109 handling when the temperature is achieved (1209).

It is much preferred that changing the temperature is conducted in dry air or dry nitrogen atmosphere.

6. Peeling Epitaxial Layers From the Substrate

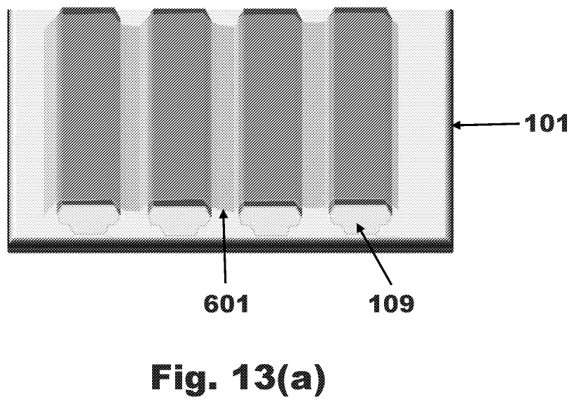

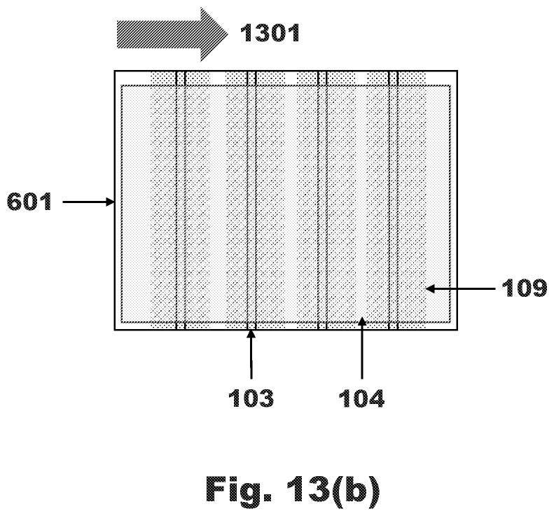

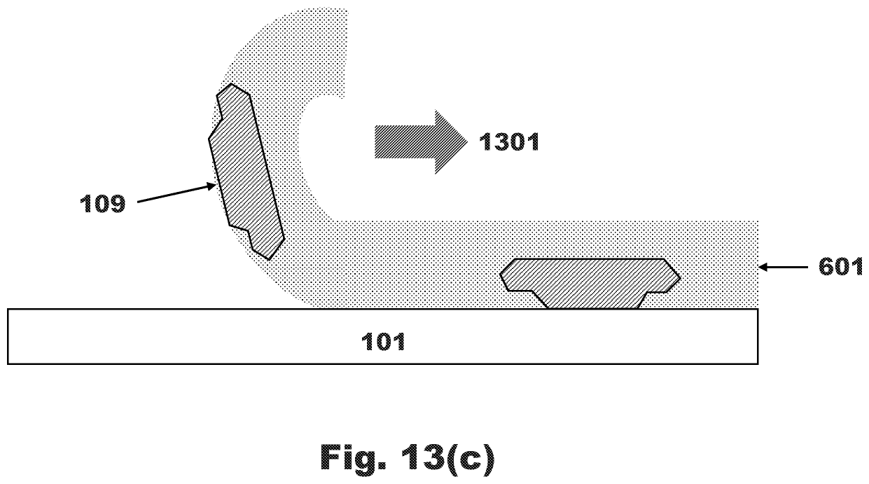

FIG. 13(a) is a schematic representation of a substrate 101 after placing a polymer/adhesive film 601 on the island-like III-nitride semiconductor layers 109; FIG. 13(b) represents the peeling direction 1301 of the film 601 from a top view; and FIG. 13(c) represents the peeling direction 1301 of the film 601 from a cross-section view.

Typically, the polymer/adhesive film 601 is slowly peeled from the sample 101, 109, after the handling temperature is attained.

If the polymer/adhesive film 601 has an adhesive interface where it contacts the island-like III-nitride semiconductor layers 109, the island-like III-nitride semiconductor layers 109 will be attached to the polymer/adhesive film 601.

If the polymer/adhesive film 601 has an interface that is not adhesive, then the island-like III-nitride semiconductor layers 109 may remain on the substrate 101 and further device handling may be carried out on the substrate 101, either by picking individual island-like III-nitride semiconductor layers 109 or picking a batch of the island-like III-nitride semiconductor layers 109, and placing them onto a support substrate.

Individual or batch island-like III-nitride semiconductor layers 109 that are attached to the polymer/adhesive film 601 are handled for processing as the devices 110 after removing the polymer/adhesive film 601 by treating the polymer/adhesive film 601 under ultraviolet (UV) or infrared (IR) irradiation or using an appropriate solvent. After that, with the help of a support substrate, further device 110 processing steps are carried out.

In this invention, the island-like III-nitride semiconductor layers 109 can be removed from the substrate 101 using the polymer/adhesive film 601 in an easy manner as set forth. This method can be used in mass production, and is both cheap and easy to implement with a short lead-time. Moreover, the island-like III-nitride semiconductor layers 109, after being removed, are automatically aligned on the polymer/adhesive film 601. This is useful for mass-production, especially, for micro-LEDs, laser diode arrays, and so on.

### DEFINITIONS OF TERMS

III-Nitride-Based Substrate

As long as a III-nitride-based substrate 101 enables growth of III-nitride-based semiconductor layers 105, 106, 109 through a growth restrict mask 102, any III-nitride-based substrate 101 that is sliced on a (0001), (1-100), (20-21), or (20-2-1) plane, or other plane, from a bulk III-nitride-based crystal can be used, such as a GaN substrate 101 sliced from a bulk GaN crystal. When the island-like III-nitride semiconductor layers 109 are removed from the III-nitride-based substrate 101 by peeling, the peeled surface may include an m-plane facet in the case of non-polar and semi-polar substrates 101, and a polar surface for polar substrates 101,

III-Nitride-Based Semiconductor Layers

The III-nitride-based semiconductor layers include ELO III-nitride layers 105, III-nitride semiconductor device layers 106 and island-like III-nitride semiconductor layers 109. In the semiconductor device 110, the sides of the island-like III-nitride semiconductor layers 109 are typically formed with the (1-10a) plane (where a is an arbitrary integer), the (11-2b) plane (where b is an arbitrary integer), or planes crystallo-graphically equivalent to these, or the sides of the island-like III-nitride semiconductor layers 109 include the (1-10a) plane (where a is an arbitrary integer).

The III-nitride-based semiconductor device layers 106 generally comprise more than two layers, including at least one layer among an n-type layer, an undoped layer and a p-type layer. The III-nitride-based semiconductor device layers 106 may comprise a GaN layer, an AlGaN layer, an AlGaNInN layer, an InGaN layer, etc.

In cases where the device 110 has a plurality of III-nitride-based semiconductor layers 105, 106, 109, the distance between the island-like III-nitride semiconductor layers 109 adjacent to each other in Type 1 and Type 4 designs is generally 30 μm or less, and preferably 10 μm or less, but is not limited to these values. For Type 2 designs, this is the preferred value between adjacent patches and this value is the dry etch region space for Type 3 designs. The distance between the island-like III-nitride semiconductor layers 109 is preferably the width of the no-growth region 104.

In the semiconductor device 110, a number of electrodes according to the types of the semiconductor device 110 are disposed at predetermined portions. The semiconductor device 110 may comprise, for example, a Schottky diode, a light-emitting diode, a semiconductor laser, a photodiode, a transistor, etc., but is not limited to these devices. This disclosure is particularly useful for micro-LEDs and laser diodes, such as edge-emitting lasers and vertical cavity surface-emitting lasers (VCSELs).

Growth Restrict Mask

The growth restrict mask 102 comprises a dielectric layer, such as SiO₂, SiN, SiON, Al₂O₃, AlN, AlON, MgF, TiN, Ti or a refractory metal, such as W, Mo, Ta, Nb, Pt, etc. The growth restrict mask 102 may be a laminate structure selected from the above materials. The growth restrict mask 102 also may be a stacking layer structure chosen from the above materials.

In one embodiment, the thickness of the growth restrict mask 102 is about 0.05-1.05 μm.

The striped opening areas 103 for non-polar and semi-polar III-nitride-based substrates 101 are arranged in a first direction vertical to the <11-20> direction of the III-nitride-based semiconductor layers 105, 106, 109, and a second direction parallel to the <11-20> direction of the III-nitride-based semiconductor layers 105, 106, 109, periodically at a first interval and a second interval, respectively, and extend in the second direction. The width of the striped opening areas 103 is typically constant in the second direction, but may be changed in the second direction as necessary.

The striped opening areas 103 for polar III-nitride-based substrates 101 are arranged in a first direction parallel to the <11-20> direction of the III-nitride-based semiconductor layers 105, 106, 109, and a second direction parallel to the <1-100> direction of the III-nitride-based semiconductor layers 105, 106, 109, periodically at a first interval and a second interval, respectively, and extend in the second direction. The width of the striped opening areas 103 is typically constant in the second direction, but may be changed in the second direction as necessary.

Flat Surface Region

The flat surface region 107 is between layer bending regions 108. Furthermore, the flat surface region 107 lies on both the growth restrict mask 102 and the opening area 103.

Fabrication of the semiconductor device 110 is mainly performed on the flat surface area 107. That means the device 110 can be on the growth restrict mask 102, the opening area 103, or both the growth restrict mask 102 and the opening area 103. It is not a problem if the fabrication of the semiconductor device 110 is partly performed in the layer bending region 108. More preferably, the layer bending layer 108 may be removed by etching.

The width of the flat surface region 107 is preferably at least 5 μm, and more preferably is 10 μm or more. The flat surface region 107 has a high uniformity of the thickness of each semiconductor layer 105, 106, 109 in the fiat surface region 107.

Layer Bending Region

If the layer bending region 108 that includes an active layer 106a remains in an LED device 110, a portion of the emitted light from the active layer 106a is reabsorbed. As a result, it may be preferable to remove the layer bending region 108 in such devices 110.

If the layer bending region 108 that includes an active layer 106a remains in an LD device 110, the laser mode may be affected by the layer bending region 108 due to a low refractive index (e.g., an InGaN layer). As a result, it may be preferable to remove the layer bending region 108 in such devices 110.

If the layer bending region 108 remains in the LD device 110, the edge of the ridge stripe structure should be at least 1 μm or more from the edge of the layer bending region 108.

From another point of view, an epitaxial layer of the flat surface region 107, except for the opening area 103, has a lesser detect density than ELO III-nitride layer 105 of the opening area 103. Therefore, the ridge stripe structure should be in the flat surface region 107, except for the opening area 103.

Horizontal Trench

The horizontal trench 501 is a structure created at a lower portion of the island-like III-nitride semiconductor layers 109 extending inwards to the center of the structure.

The following are various method for obtaining the horizontal trench 501:

Method 1:

The island-like III-nitride semiconductor layers 109 are grown on the substrate 101, and then the island-like III-nitride semiconductor layers 109 are divided using dry etching having a separation width particularly useful for practicing this invention and, with the help of chemical etching, the horizontal trench 501 that extends inwards of the structure's center can be realized.

In particular, for example, the island-like III-nitride semiconductor layers 109 include at least one lowermost layer just above the substrate 101 containing at least an element from group III (In, Ga, Al) is formed (InₓAl_{y}Ga_{1-(x+y)}N), which is sensitive for chemical etching, like PEC, followed by the island-like III-nitride semiconductor layers 109 mentioned elsewhere in this disclosure, such as n-type GaN, InGaN/GaN MQWs as active region, p-type GaN, is performed. Metal-organic chemical vapor deposition (MOCVD) is used for the materials growth. Trimethylgallium (TMGa), trimethylindium (TMIn) and triethylaluminium (TMAl) are used as the group-III elements source. Ammonia (NH₃) is used as the raw gas to supply Nitrogen, Hydrogen (H₂) and nitrogen (N₂) are used as carrier gases. Saline and Bis(cyclopentadienyl)magnesium (Cp₂Mg) are used as the n-type and p-type dopants. The pressure is set to be 50 to 760 Torr. The GaN growth temperature ranges from 900 to 1250° C. and the chemically sensitive layer growth temperature is from 800 to 1150° C. The thickness of the InₓAl_{y}Ga_{1-(x+y)}N chemically sensitive layer is from 1 to 100 nm. The composition of x and y is from 0 to 1 and x+y also ranges from 0 to 1.

Dry etching is performed to expose the island-like III-nitride semiconductor layers 109 including the chemical sensitive layer laying at the lowermost and just above the substrate 101. The depth of the dry etch should at least expose a partial portion of the lowermost layer sensitive to chemical etching.

Angled dry etching may be performed to ease the peeling mentioned in this disclosure, such as reactive-ion etching (RIE), etc. For example, SiCl₄ may be used as the etching gas. The etching angle is from 0 to 90 degrees.

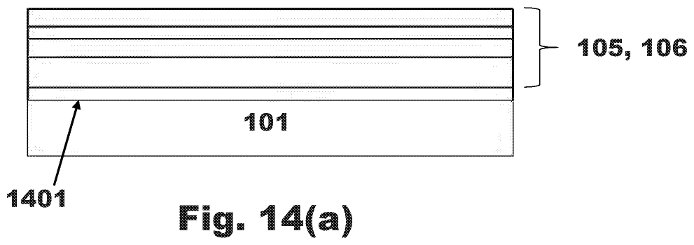

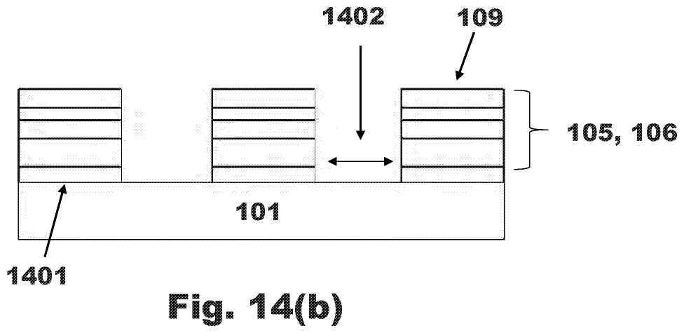

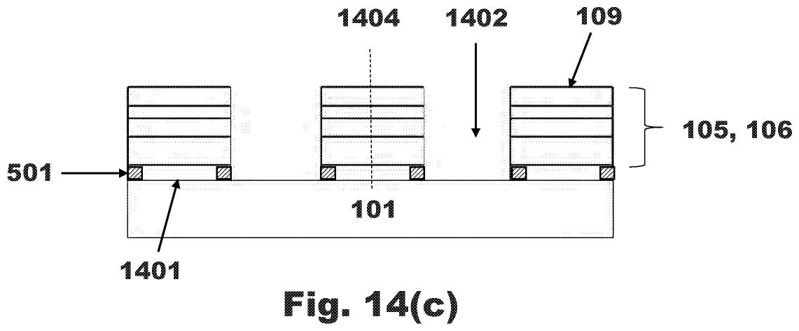

FIGS. 14(a), 14(b) and 14(c) are schematics depicting one way to form a horizontal trench 501 in the island-like III-nitride semiconductor layers 109. FIG. 14(a) shows the growth of the III-nitride semiconductor layers 105, 106, which includes a chemically sensitive layer 1401, such as InAlGaN, as the lowermost layer. FIG. 14(b) shows the etching of the III-nitride semiconductor layers 105, 106, resulting in etched regions 1402, which forms the island-like III-nitride semiconductor layers 109. FIG. 14(c) shows the forming of the horizontal trench 501, on either or both sides of the island-like III-nitride semiconductor layers 109, by partially etching the chemically sensitive layer 1401. The chemically sensitive layer 1401 preferably is chemically etched, for example, to realize the horizontal trench 501.

Method 2:

Epitaxial later overgrowth (ELO) is a second method to obtain a horizontal trench 501. The substrate 101 is masked with the growth restrict mask 102 which can hold at the MOCVD temperatures without decomposing and is the least reactive with growing semiconducting epitaxial layers thereafter. The mask 102 on the substrate 101 has several opening areas 103 periodically or non-periodically to assist in the growth of the island-like III-nitride semiconductor layers 109. The width of the ELO III-nitride layers 105 that grow from the opening areas 103 over the mask 102 laterally will be defined as the trench 501 length. Preferably, the trench 501 length would be 0.1 μm or more.

For example, for the III-nitride semiconductor case, a growth restrict mask 102, defined below in detail, having several design types discussed in this disclosure, is placed to realize horizontal trenches 501 to remove the island-like III-nitride semiconductor layers 109.

Polymer/Adhesive Film

Generally, the polymer/adhesive film 601 may be rolled over and onto the island-like III-nitride semiconductor layers 109. In addition, the polymer/adhesive film 601 can also be rolled over and onto complete device 110 structures, for example, containing ridge snipes, p-electrodes, etc.

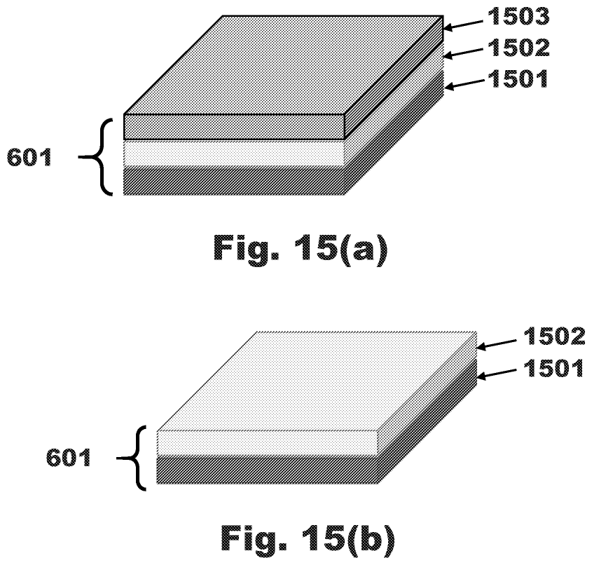

As shown in FIGS. 15(a) and 15(b), the structure of the polymer/adhesive film 601 may comprise three or two layers 1501, 1502, 1503, as shown in FIGS. 15(a) and 15(b), respectively, but is not limited to those layers. In one embodiment, the base film 1501 material has a thickness of about 80 μm and is made of polyvinyl chloride (PVC), the backing film 1502 material has a thickness of about 38 μm and is made of polyethylene terephthalate (PET); and an adhesive layer 1503 has a thickness of about 15 μm and is made of an acrylic.

Moreover, the polymer/adhesive film 601 may be a UV-sensitive or IR-sensitive tape. After removing the island-like III-nitride semiconductor layers 109 from the substrate 101, the film 601 may be exposed to UV or IR irradiation, which drastically reduces the adhesiveness of the film 601, making it easy to remove.

Moreover, there may be regions of convexity and/or concavity between island-like III-nitride semiconductor layers 109, with a height or depth of 1 μm or more. In these cases, it is important to place the polymer/adhesive film 601 into the concavity and/or concavity portions, and that the film 601 conform to such regions.

In this regard, the polymer/adhesive film 601 may be a multi-layer film comprised of at least a soft layer and a hard layer. For example, a PVC layer is harder than a PET layer, where the PET can easily be placed into and conform to such regions. The PVC also helps the PET avoid cracking and breaking during temperature changes.

Support Substrate

The method for manufacturing the semiconductor device, as necessary, may further comprise a step of bonding/attaching exposed surface side of the III-nitride-based epi-structures after peeling process is completed. If a polymer/adhesive film 601 is used, epi-layers that are attached onto the polymer/adhesive film 601 are bonded to a support substrate for further processing.

Or, if the polymer/adhesive film 601 is used for a peeling process, the treated epi-layers on the III-nitride-based substrates 101 are handled by bonding a support substrate onto III-nitride-based substrate 101.

The support substrate may be comprised of elemental semiconductor, compound semiconductor, metal, alloy, nitride-based ceramics, oxide-based ceramics, diamond, carbon, plastic, etc., and may comprise a single layer structure, or a multilayer structure made of these materials. A metal, such as solder, etc., or an organic adhesive, may be used for the bonding of the support substrate, and is selected as necessary.

Fabrication Method

The method of manufacturing the semiconductor device may further comprise a step of bonding a support substrate to exposed portion of the III-nitride-based semiconductor layers. The exposed portions of the III-nitride epilayers can be the lower surface, interface between the III-nitride-based substrate and III-nitride epilayers when a polymer/adhesive film 601 is used for peeling process. Alternatively, the exposed portion of the III-nitride epi-layer can be top portion of the grown III-nitride epi structure on III-nitride-based substrate.

In addition, the method may further comprise a step of forming one or more electrodes on the surface of the III-nitride-based semiconductor layer that is exposed after peeling the III-nitride-based semiconductor layers from the substrate.

As necessary, the method of manufacturing the semiconductor device may further comprise a step of forming one or more electrodes on the upper surface of the III-nitride-based semiconductor layers after growing the III-nitride-based semiconductor layers upon the substrate. The electrodes may be formed after III-nitrides based semiconductor layers have been removed using a peeling technique.

The method may further comprise a step of removing, by wet etchant, at least a portion of, or preferably almost all of, or most preferably all of, the growth restrict mask. However, this process is not always necessary to remove the substrate. Also, as necessary, a conductor thin film or a conductor line may be formed on support substrate on the side bonded with the III-nitride-based semiconductor layers.

According to the present invention, the crystallinity of the island-like III-nitride semiconductor layers laterally growing upon the growth restrict mask from a striped opening of the growth restrict mask is very high, and III-nitride-based semiconductor layers made of high quality semiconductor crystal can be obtained.

Furthermore, two advantages may be obtained using a III-nitride-based substrate. One advantage is that a high-quality island-like III-nitride semiconductor layer can be obtained, such as with a very low defects density. Another advantage, by using a similar or same material for both the epilayer and the substrate, is that it can reduce the strain in the epitaxial layer. Also, thanks to a similar or same thermal expansion, the method can reduce the amount of bending of the substrate during epitaxial growth. The effect, as above, is that the production yield can be high in order to improve the uniformity of temperature.

On the other hand, a foreign or hetero-substrate, such as sapphire, LiAlO₂, SiC, Si, etc., can be used to grow the III-nitride-based semiconductor layers. A foreign or hetero-substrate is easy to remove due to weak bonding strength at the interface region.

Consequently, the present invention discloses: a substrate comprised of a III-nitride-based semiconductor; a growth restrict mask with one or more striped openings disposed directly or indirectly upon the substrate; and one or more island-like III-nitride semiconductor layers grown upon the substrate using the growth restrict mask.

In one embodiment, the growth restrict mask is deposited by sputter or electron beam evaporation or PECVD (plasma-enhanced chemical vaper deposition), but is not limited to those methods. Also, when a plurality of island-like III-nitride semiconductor layers are grown, these layers are separated from each other, that is, formed in isolation, so tensile stress or compressive stress generated in each III-nitride-based semiconductor layer is limited within the III-nitride-based semiconductor layer, and the effect of the tensile stress or compressive stress does not fall upon the other III-nitride-based semiconductor layers. However, it is not necessary that the island-like III-nitride semiconductor layers be separated.

Also, as the growth restrict mask and the III-nitride-based semiconductor layer are not bonded chemically, the stress in the III-nitride-based semiconductor layer can be relaxed by a slide caused at the interface between the growth restrict mask and the III-nitride-based semiconductor layer.

Also, the existence of gaps between each of the island-like III-nitride semiconductor layers, known as no-growth regions 104, results in the substrate 101 having rows of a plurality of island-like III-nitride semiconductor layers 109, which has flexibility, and therefore, it is easily deformed when external force is applied and can be bent.

Therefore, even if there occurs a slight warpage, curvature, or deformation in the substrate 101, this can be easily corrected by a small external force, to avoid the occurrence of cracks. As a result, the handling of substrates 101 by vacuum chucking is possible, which makes the manufacturing process of the semiconductor devices 110 more easily carried out.

As explained, island-like III-nitride semiconductor layers 109 made of high quality semiconductor crystal can be grown by suppressing the curvature of the substrate 101, and further, even when a III-nitride-based semiconductor layer 105, 106, 109 is very thick, the occurrences of cracks, etc., can be suppressed, and thereby a large area semiconductor device 110 can be easily realized.

### ALTERNATIVE EMBODIMENTS

### First Embodiment

A III-nitride-based semiconductor device and a method for manufacturing thereof according to the first embodiment are explained.

In the first embodiment, a base substrate 101 is first provided, and a growth restrict mask 102 that has a plurality of striped opening areas 103 is formed on the substrate 101. In this embodiment, the base substrate 101 is made of III-nitride-based semiconductor.

The thickness of the III-nitride-based semiconductor layers, such as a GaN layer, etc., to be grown upon the GaN substrate is 1 to 60 μm, for example, but is not limited to these values. As described herein, the thickness of the III-nitride-based semiconductor layers are measured from the surface of growth restrict mask 102 to the upper surface of the island-like III-nitride-based semiconductor layers 109.

The growth restrict mask 102 can be formed from an insulator film, for example, an SiO₂ film deposited upon the base substrate 101, for example, by a plasma chemical vapor deposition (CVD) method, sputter, ion beam deposition (IBD), etc., wherein the SiO₂ film is then patterned by photolithography using a predetermined photo mask and etching. The thickness of the SiO₂ film in this embodiment is 0.02 μm to 0.3 μm, for example, but is not limited to that value.

Using the growth restrict mask 102, one or more ELO III-nitride layers 105 are grown by a vapor-phase deposition method, for example, a metalorganic chemical vapor deposition (MOCVD) method. In this case, the surface of the base substrate 101 is exposed in the opening areas 103, and the ELO III-nitride layers 105 are selectively grown thereon, and are continuously laterally grown upon the growth restrict mask 102,

In Type 1 designs, the growth is stopped before adjacent ones of the ELO III-nitride layers 105 coalesce.

Type 3 design is similar as the Type 1 design except that the opening areas 103 and growth restrict mask 102 stripes are smaller as compared to Type 1, so that the ELO III-nitride layers 105 are made to coalesce and later the ELO III-nitride layers 105 are divided into desired shapes.

The thickness of the ELO III-nitride layers 105 is important in Type 1 designs, because it determines the width of the flat surface region 107. Preferably, the width of the flat surface region 107 is 20 μm or more. The thickness of the ELO III-nitride layers 105 is preferably as thin as possible. This is to reduce the process time and to etch the opening area 103 easily. The ELO growth ratio is the ratio of the growth rate of the lateral direction to the growth rate of the vertical direction perpendicular to the substrate 101. Optimizing the growth conditions, the ELO growth ratio can be controlled from 0.4 to 4.

Next, the III-nitride semiconductor device layers 106 are grown on the ELO III-nitride layers 105. The III-nitride semiconductor device layers 106 are comprised of a plurality of III-nitride-based layers.

Growth Restrict Mask:

Various examples of the growth restrict mask 102 have been shown. For all the designs, the first direction of the growth restrict mask 102 stripes are vertical to <11-20> axis and the second direction along <11-20> for semi-polar and non-polar III-nitride-based substrates 101, like (10-1-1), (10-1 1), (20-2-1), (20-2-1), (30-3-1), (30-31), (1.-100), etc. and are respectively along <11-20> and <1-100> for C-plane (0001) III-nitride-based substrates 101.

The direction of growth restrict mask 102 is determined to obtain a smooth surface morphology for the epi-layer. With respect to removing the epi-layer, the direction does not matter. The invention adopts any direction.

In a Type 1 design, the first direction, which is the length of the opening area 103 is, for example, 200 to 5000 μm; and the second direction, which is the width of the opening area 103, is, for example, 5 to 200 μm.

In a Type 3 design, a growth restrict mask 102 comprises a plurality of opening areas 103 having an open window 301 width of 3 μm to 7 μm and at an interval of 7 μm to 3 μm, such that to have a period of 10 μm patterns are formed upon the substrate 101. After obtaining a coalesced ELO III-nitride layer 105 upon these patterns, the ELO III-nitride layer 105 is then etched at 303 using regular intervals in x and y directions to create a desired shape 302.

Typically, the growth restrict mask 102 used in the present invention has dimensions indicated as follows. In first embodiment, a C-plane GaN substrate 101 is used. The growth restrict mask 102 is formed with a 0.2-μm-thick SiO₂ film, wherein the length of the opening areas 103 in a <11-20> direction is 5000 μm; and the distance between the opening areas 103 in the <1-100> direction is 5 μm.

The growth conditions of the island-like III-nitride semiconductor layers 109 can use the same MOCVD conditions as the ELO technique. For example, the growth of GaN layers is at the temperature of 950-1150° C. and the pressure of 30 kPa. For the growth of GaN layers, trimethylgallium (TMGa) and ammonia (NH₃) are used as the raw gas, and hydrogen (H₂) and nitrogen (N₂) are used as the carrier gas; for the growth of AlGaN layers, triethylaluminium (TMAl) is used as the raw gas; and for the growth of InGaN layers, trimethylindium (TMIn) is used as the raw gas. Using these conditions, the following layers have been grown on a GaN substrate 101 with the growth restrict mask 102.

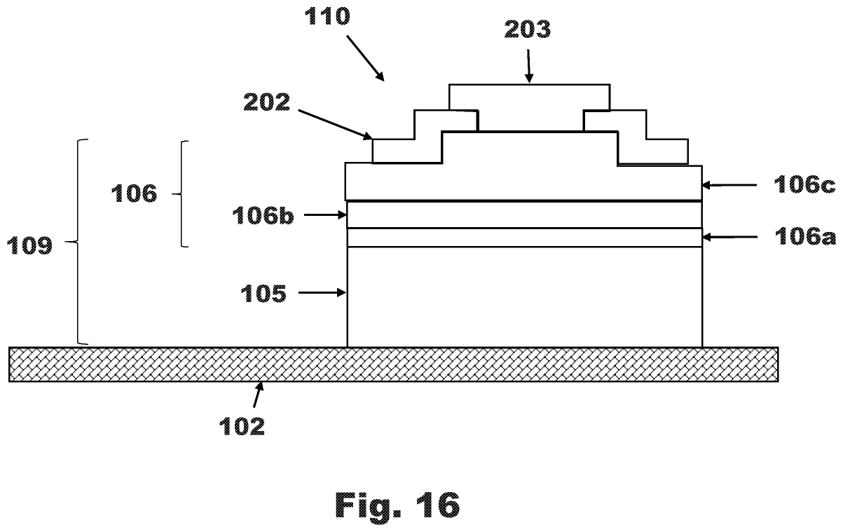

FIG. 16 is a sectional view of a laser diode device 110 along the direction perpendicular to an optical resonator, wherein the laser diode device 110 comprises an ELO III-nitride layer 105 and III-nitride semiconductor device layers 106, including a 5× InGaN/GaN multiple quantum well (MQW) active layer 106a, an AlGaN electron blocking layer (EBL) 106b, and a p-type GaN cladding layer 106c. The optical resonator is comprised of a ridge stripe structure, which is comprised of the p-GaN cladding layer 106c, ZrO₂ current limiting layer 202, and p-electrode 203, which provides optical confinement in a horizontal direction. The width of the ridge stripe structure is of the order of 1.0 to 40 μm, and typically is 10 μm.

In one embodiment, the p-electrode 203 may be comprised of one or more of the following materials: Pd, Ni, Ti, Pt, Mo, W, Ag, Au, etc. For example, the p-electrode 203 may comprise Pd—Ag—Ni—Au (with thicknesses of 3-50-30-300 nm). These materials may be deposited by electron beam evaporation, sputter, thermal heat evaporation, etc. In addition, a TCO cladding layer (comprised, for example, of ITO) may be added between p-GaN cladding layer 106b and p-electrode 203, as illustrated by TCO cladding layer 201 between ZrO₂ layer 202 and p-pad 203 in FIGS. 2(a) and 2(b).

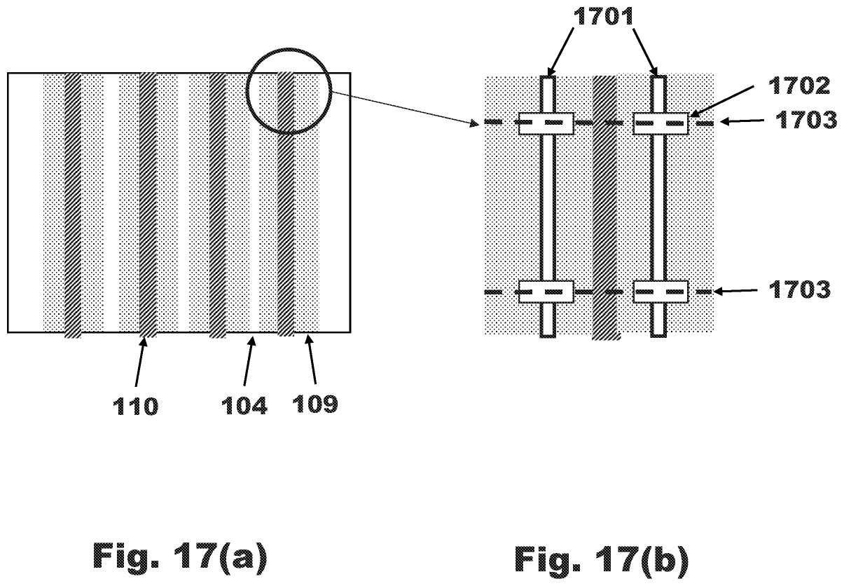

Using conventional common methods such as photolithography and dry etching has fabricated the ridge strip structure, as shown by 1701 in FIGS. 17(a) and 17(b), after MOCVD growth. The ridge depth is pre-determined before dry etching is performed, based on simulation or previous experimental data. The ridge structure may perform on entire flat surface region 107 of the III-nitride island based semiconductor layers 109 including opening areas 103, or only on the growth restrict mask 102.

Making a Facet:

As shown in FIGS. 17(a) and 17(b), the etched mirror facets 1702 is located based on optical resonance length. The etching process for GaN etching uses an Ar ion beam and Cl₂ ambient gas. The etching depth is from about 1 μm to about 4 μm. The etched mirror facets 1702 may be coated by a dielectric film selected from the group of the following: SiO₂, Al₂O₃, AlN, AlON, SiN, SiON, TiO₂, Ta₂O₅, Nb₂O₅, Zr₂O, etc.

Alternatively, the facet 1702 may be cleaved mechanically after transferring the island-like III-nitride-based semiconductor layers 109 from the III-nitride-based substrate 101.

Removing the Growth Restrict Mask:

The growth restrict mask 102 is removed using etching. Dry etching or a wet etching or a combination of both the processes can be used to at least partially dissolve the growth restrict mask 102. The invention can also be practiced without dissolving the growth restrict mask 102; however, for better yield and quality at least a partial dissolution is recommended.

Attaching the Film:

Then, a polymer/adhesive film 601 is placed over the island-like III-nitride semiconductor layers 109 and slightly pressed without reaching the breaking point of the island-like III-nitride semiconductor layers 109. This step is to ensure the polymer/adhesive film 601 is framed nicely around the layout of the island-like III-nitride semiconductor layers 109.

Alternatively, better results may obtain, if the temperature of the polymer/adhesive film 601 is slightly raised, for example, to about 100° C.; however, it is not limited to this value, and a value slightly below the melting point of the polymer/adhesive film 601 may work. Then application of slight pressure and/or rotating the sample with the attached heated polymer/adhesive film 601 using a spinner may help the film 601 to bend accordingly to the layout of the island-like III-nitride semiconductor layers 109.

Applying Pressure:

The above combination, the island-like III-nitride semiconductor layers 109 with the polymer/adhesive film 601 attached, is pressed from the top and bottom sides using a suitable tool and clamped together. For example, one quartz plate each on bottom and top sides of this combination and clamping the quartz plates together may ensure a good fixture for the polymer/adhesive film 601 on the island-like III-nitride semiconductor layers 109.

The invention can also be practiced without application pressure at this stage, if the polymer/adhesive film 601 is made to fit perfectly to the layout of the island-like III-nitride semiconductor layers 109 using any alternative methods, like the one mentioned above using a compressible material.

The invention can also be practiced with electrode(s) patterned on a conductive polymer/adhesive film 601 and made the film 601 made to overlap with pre-fabricated electrodes on the device 110.

Changing the Temperature:

Now, this new combination's (clamped structure) temperature is either raised or lowered while maintaining pressure on the structure. Then, the structure temperature is lowered/raised back to the handling temperature. Alternatively, a Peltier device can be used to change the temperature, so that the ramping rates for raising and lowering can be controlled as desired.

Alternatively, this invention may performed with several alternatives, for example, the pressure on the structure may either controlled or removed during the temperature varying process. Like the one shown in FIG. 12(a), several robotic functioning arms 1202 perform the operations of clamping, controllable heating base, controllable pressure, gas ports to vary ambient conditions of sample etc.

Peeling the Film

Rapid contraction and expansion shock experienced by the polymer/adhesive film 601 during this temperature cycle and the difference in thermal expansions between the polymer/adhesive film 601 and the III-nitride semiconductor layers 105, 106, 109 initiate a crack or cleave at the interface between the ELO III-nitride layers 105 and the substrate 101.

After handling temperatures attained, the polymer/adhesive film 601 from the sample is slowly peeled off as indicated in FIGS. 13(a), 13(b) and 13(c). The island-like III-nitride semiconductor layers 109 are attached to polymer/adhesive film 601, if the polymer/adhesive film 601 is an polymer/adhesive film.

The attached island-like III-nitride semiconductor layers 109 on the polymer/adhesive film 601 can be handled individually or in a batch using a vacuum chuck or some industrially mature processes after dissolving the interface between polymer/adhesive film 601 and the island-like III-nitride semiconductor layers 109 chemically, or by UV or IR irradiation.

Alternatively, if the polymer/adhesive film 601 is not an adhesive type, the island-like III-nitride semiconductor layers 109 may remain on the substrate 101 after removing the polymer/adhesive film 601. The island-like III-nitride semiconductor layers 109 then can be handled from the substrate 101 using the any of the above-mentioned methods.

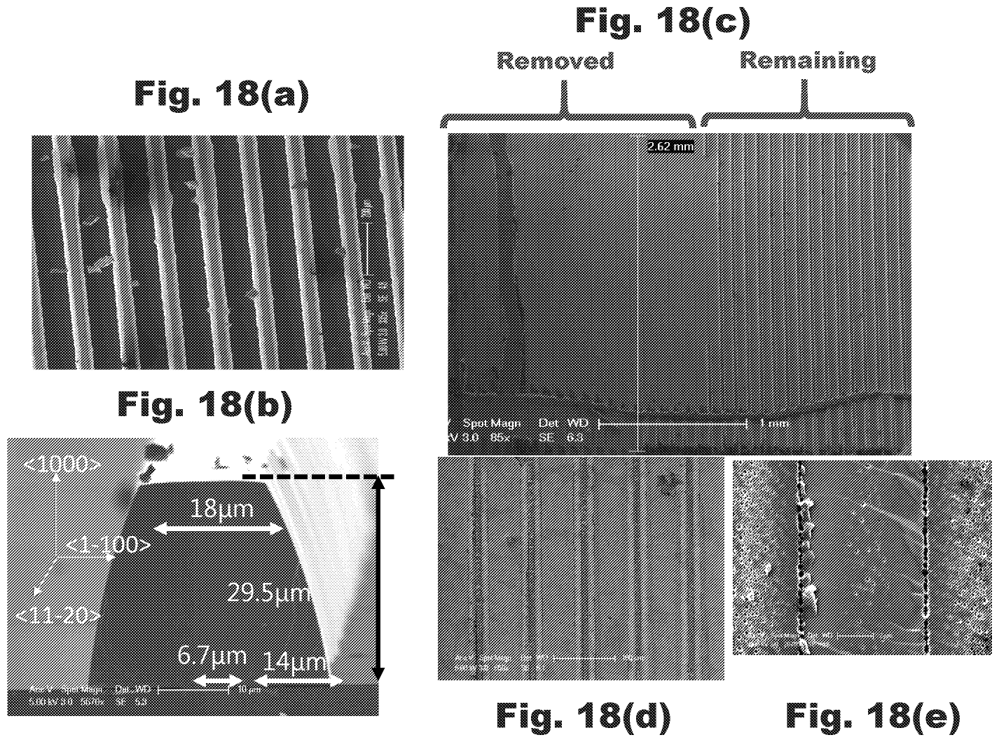

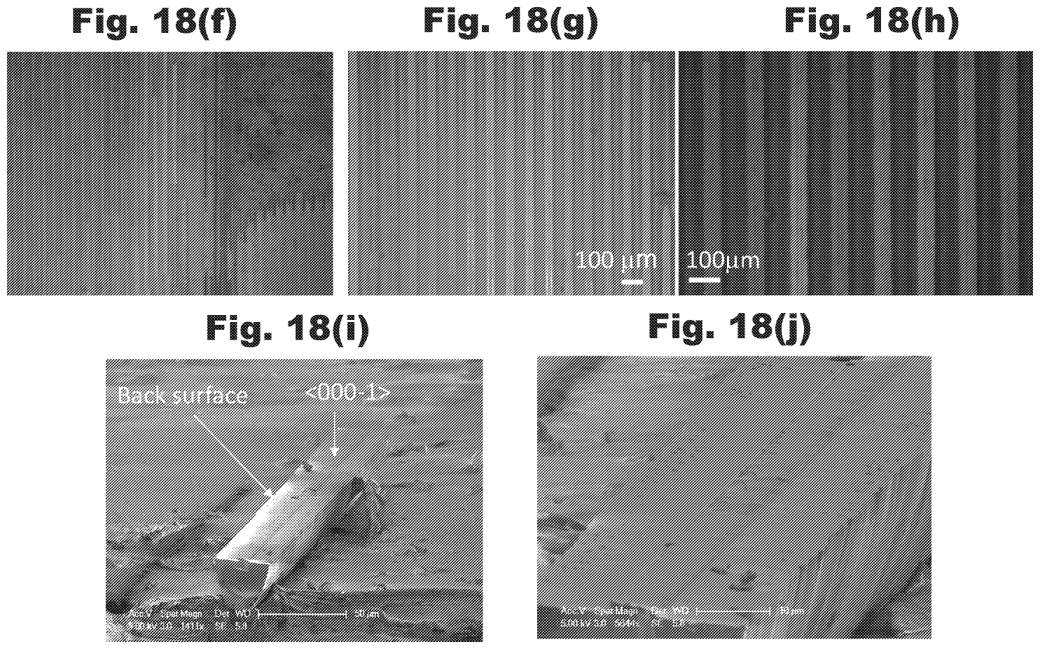

FIGS. 18(a)-18(j) are SEM images and microscopic images of the ELO III-nitride layers 105 peeled from a III-nitride-based C-plane semiconductor substrate 101. FIGS. 18(a) and 18(b) show the ELO III-nitride layers 105 on C-plane (0001) surface of the III-nitride-based substrate 101. FIGS. 18(c), 18(d) and 18(e) are the images of the C-plane III-nitride-based substrate 101 after removing the ELO III-nitride layers 105, where the maximum removed length of the ELO III-nitride layers 105 along the first direction is 2.6 mm, which can be seen in the image of FIG. 18(c). FIGS. 18(d) and 18(e) are magnified versions of the removed regions on the C-plane III-nitride substrate 101.

Peeled ELO III-nitride layers 105 on the polymer/adhesive film 601 are shown in the images of FIGS. 18(f), 18(g) and 18(h). SEM images of the peeled ELO III-nitride layers 105 from the C-plane III-nitride-based substrate 101 are shown in FIGS. 18(i) and 18(j). The back surface, which is an interface between the III-nitride-based substrate 101 and the ELO III-nitride layers 105, is shown in the images of FIGS. 18(i) and 18(j).

Once the III-nitride semiconductor layers 105, 106, 109 are removed from the III-nitride-based substrate 101, the substrate 101 can be recycled. Prior to recycling, the surface of the substrate 101 may be re-polished by a polisher. The recycling process can be done repeatedly, which lowers the cost of fabricating III-nitride-based semiconductor devices.

Depositing an n-Electrode:

An n-electrode may be placed on the back side of the III-nitride semiconductor layers 109. Typically, the n-electrode is comprised of one or more of the following materials: Ti, Hf, Cr, Al, Mo, W, Au, but is not limited these materials.

For example, the n-electrode may be comprised of Ti—Al—Pt—Au (with a thickness of 30-100-30-500 nm), but is limited to those materials. The deposition of these materials may be performed by electron beam evaporation, sputter, thermal heat evaporation, etc. Preferably, the p-electrode is deposited on the ITO,

Another option is to use ITO and ZnO for the n-electrode, but the n-electrode is not limited those materials.

Dividing the Chips:

The chip or device 110 division method has two steps. The first step is to scribe the island-like III-nitride semiconductor layers. The second step is to divide the support substrate using a laser scribe, etc.

As shown in FIGS. 17(a)-17(b), the chip scribe line 1703 is fabricated by a diamond scribing machine or laser scribe machine. The chip scribe line 1703 is fabricated on the back side of the island-like III-nitride semiconductor layers 109. The chip scribe line 1703 may be a solid line or a dashed line.

Next, the polymer/adhesive film 601 is divided by laser scribing as well to obtain an laser diode device 110. It is better to avoid the ridge strip structure of the device 110 when the chip scribe line 1703 is fabricated.

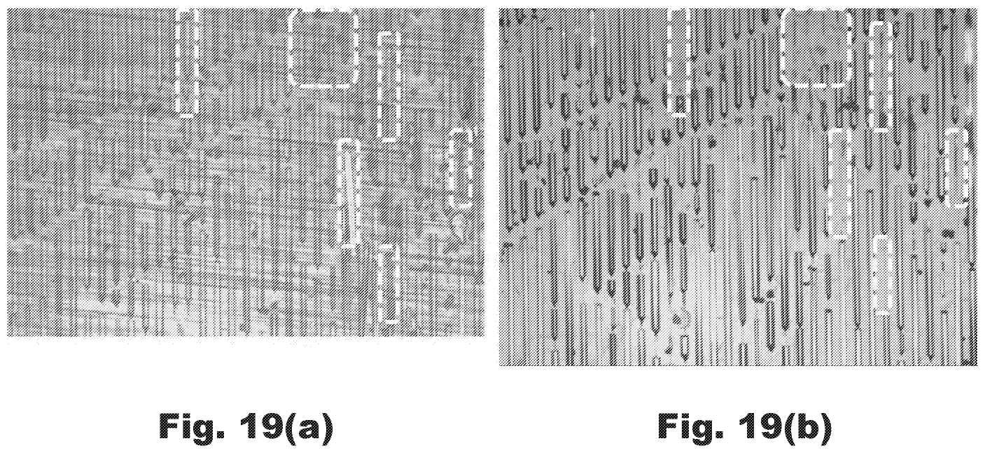

This technique may be used with or without temperature changes during the removal process. The results of without the temperature change are shown in FIGS. 19(a) and 19(b), which are reference images following removal of ELO III-nitride layers 105 from a c-plane III-nitride-based substrate 101 when no temperature changes are applied. However, is generally preferable to use this technique while changing the temperature during the removal process.

### Second Embodiment

The second embodiment is almost same as the first embodiment except for the plane of the substrate 101 . In this embodiment, the ELO III-nitride layers 105 are grown on an m-plane III-nitride substrate 101. The width and length of the opening areas 103 in the growth restrict mask 102 are respectively above 30 μm and 1200 μm; and the thickness of the ELO III-nitride layers 105 is about 15 μm.

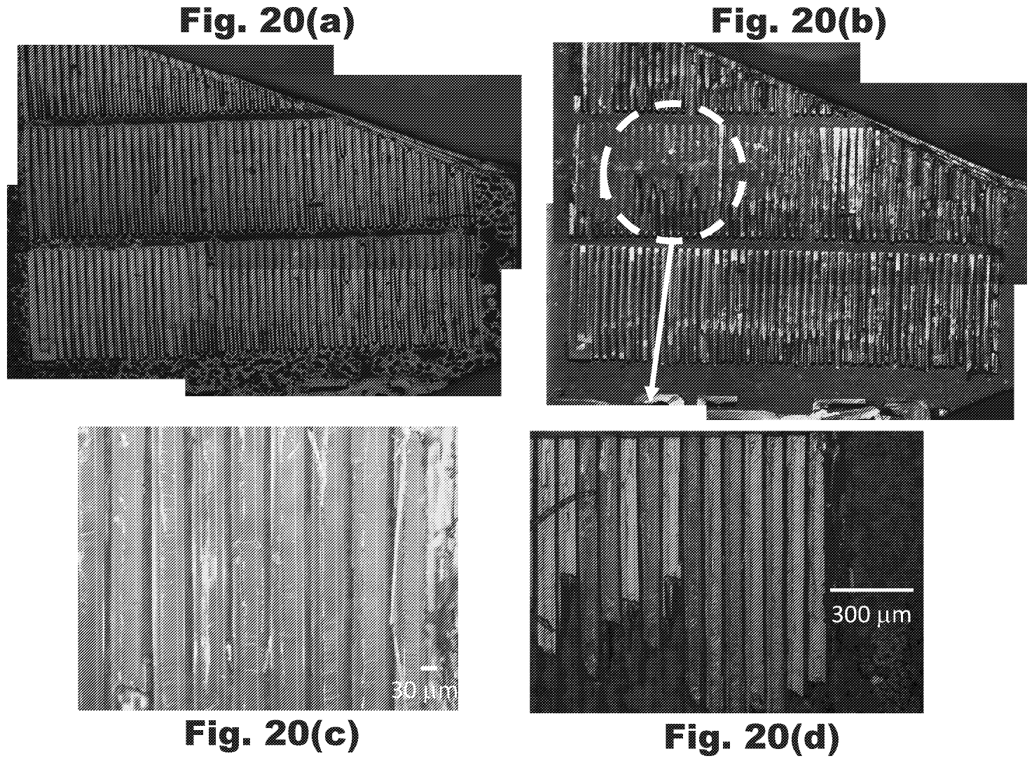

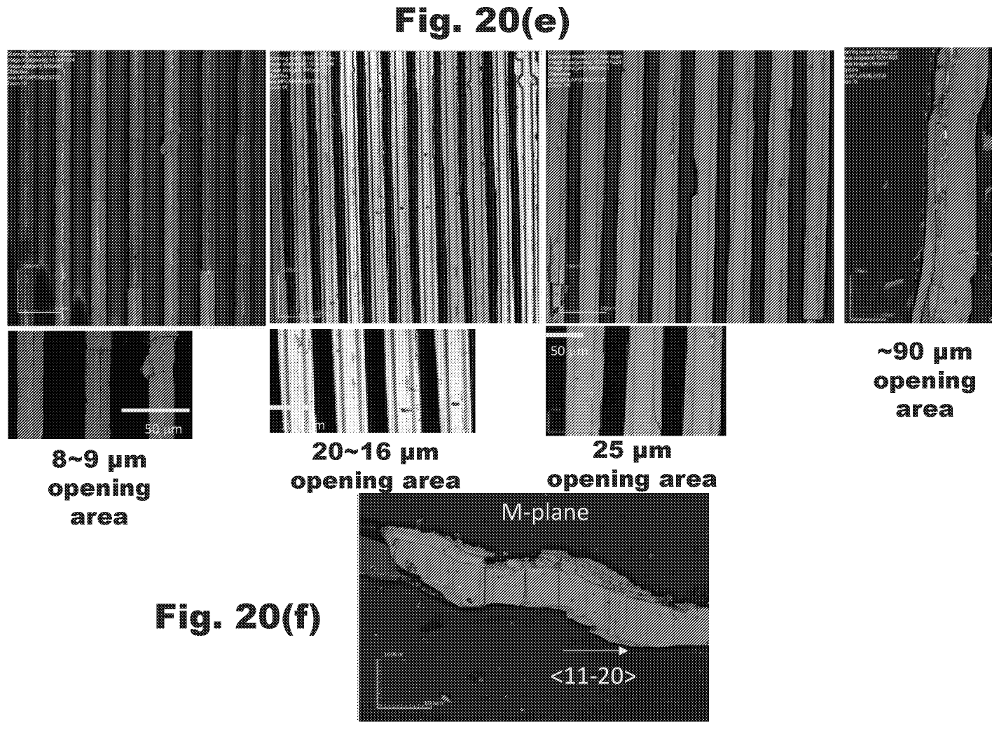

FIGS. 20(a), 20(b), 20(c) and 20(d) are optical microscope images before and after removing ELO III-nitride layers 105 from a (10-10) surface of the III-nitride-based substrate 101; FIG. 20(e) shows optical microscope images of the removed ELO nitride layers 105 on polymer/adhesive films 601 indicating the range of opening areas 103 that can be removed; and FIG. 20(f) is an optical microscope image of an irregular shape of the ELO III-nitride layers 105 removed using the polymer/adhesive film 601. in these images, the maximum length of the ELO III-nitride layers 105 transferred on to the polymer/adhesive film 601 is about 1 mm and the width is approximately 65 μm.

Generally, the narrower the width of the opening area 103, the easier it is to remove the ELO III-nitride layers 105. For example, it is not hard to remove the ELO III-nitride layers 105 when the opening area 103 has a width under 1 μm. On the other hand, it may be required to widen the ELO III-nitride layers 105 in order to form a device 110 on the flat surface region 107. For example, it takes a long growth time to obtain a width over 100 μm for the ELO III-nitride layers 105, which requires 50 μm of lateral growth on either side. Consequently, there is a trade-off relationship between the opening area 103 width and the width of the ELO III-nitride layers 105.

However, the trade-off relationship can be eliminated with this invention. As shown in FIGS. 20(a)-20(f), this invention can remove the ELO III-nitride layers 105 which contact the substrate 101 with a wide opening area 103 of 30 μm or more. If the width of the opening area 103 is 30 μm, then a lateral growth of the ELO III-nitride layers 105 of 30 μm on each side of the opening area 103 is all that is required to realize a commercial laser diode device 110, which leads to reduced growth time.

This technique can also be used to remove wider the ELO III-nitride layers 105. FIG. 20(d) shows images of the removed ELO III-nitride layers 105 on the polymer/adhesive film 601 having various opening areas 103 ranging from 8 μm to 80 μm. These results indicate that opening areas 103 up to at least about 80 μm can be used in this invention; however, it is likely that, commercial environments and equipment, one can obtain results with even larger values.

One more advantage of this invention is that the shape of the ELO layer doesn't matter. This technique can remove random ELO shapes from substrates. This is an added value for the flexibility of device design. FIG. 20(e) shows the shape of the ELO is layer is spread two dimensionally in between <11-20> and vertical to <11-20> on a III-nitride m-plane substrate.

### Third Embodiment

The third embodiment is almost same as the first embodiment except the type of the design. This embodiment exhibits the peeled ELO III-nitride layers 105 from a C-plane III-nitride-based substrate 101 having a Type 2 mask design.

In a Type 2 design, shown in FIG. 3(a), the growth restrict mask 102 has sub masks 301. The growth of the ELO III-nitride layers 105 in each sub mask 301 results in a patch 302 having length and width dimension varied from 50 μm to 300 μm. In each sub-mask 301, the growth restrict mask 102. has a plurality of opening areas 103 having a width of 3 μm to 7 μm and at an interval of 7 μm to 3 μm, such that to have a period of 10 μm pattern, are embedded as indicated in FIG. 3(a). However, these values are not limited.

In a Type 2 design, the ELO III-nitride layers 105 in the sub-mask 301 coalesce, although coalescence must be prevented for adjacent ELO III-nitride layers 105 from nearest sub-masks 301. As indicated in FIG. 7(b), the ELO III-nitride layers 105 are then removed using an polymer/adhesive film 601.

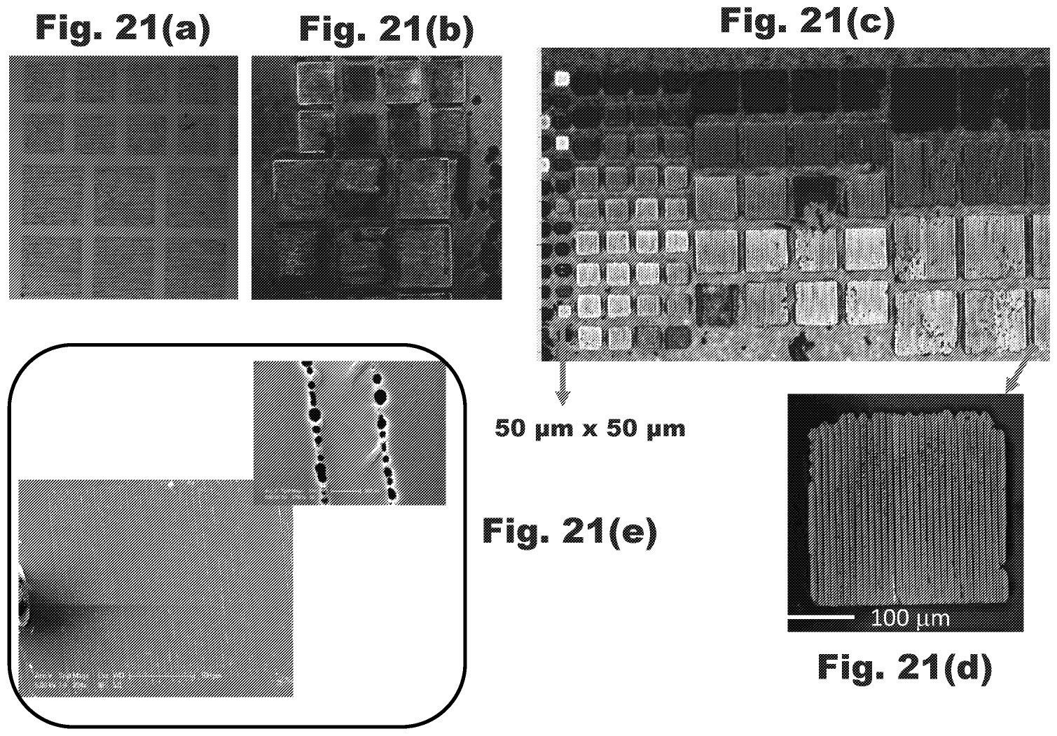

FIGS. 21(a) and 21(b) show the III-nitride-based substrate 101 and ELO III-nitride layers 105, respectively, after removing the ELO III-nitride layers 105 from the III-nitride-based substrate 101 using the polymer/adhesive film 601; FIG. 21(c) is a laser microscopic image of the peeled ELO III-nitride layers 105 on the polymer/adhesive film 601 wherein the patches have an area of 50 μm×50 μm, 100 μm×100 μm, 200 μm×200 μm, and 300 μm×300 μm. A magnified image of a patch on an polymer/adhesive film 601 within an area of 300 μm×300 μm is shown in FIG. 21(d). FIG. 21(e) shows a SEM image of the III-nitride-based substrate 101 after removing the ELO III-nitride layers 105, wherein the inset shows a magnified SEM image of the opening area 103 of the substrate 103.

### Fourth Embodiment

The fourth embodiment is almost same as the first embodiment except the type of the design. This embodiment exhibits the peeled ELO III-nitride layers 105 from the C-plane III-nitride-based substrate 101 having a Type 4 design.

In the Type 4 design, the length of the opening area 103 in the first direction is, for example, 30 to 100 μm; the width of the opening area 103 in the second direction is, for example, 30 to 100 μm, as shown in FIG. 4(a).

Like a Type 1 design, in the Type 4 design, the growth is stopped before the ELO III-nitride layers 105 reach or coalesce with their nearest neighbor ELO III-nitride layers 105, wherein the opening area 103 is restricted to a relatively small area, for example, a value 100 μm×100 μm for a pattern having the shape of a square,. The shape can be arbitrary, for example, a circle, triangle, square/rectangular, pentagonal, hexagonal, or simply a polygonal, as shown in FIGS. 4(e)-4(h). The opening areas 103 are designed such that each of the above-mentioned shapes have a value of approximately 0.01 mm². However, other values may be used, including much larger values, with a proper industrial setup and/or by inserting a weakly bonded interface layer between the III-nitride-based substrate 101 and the ELO III-nitride layers 105, as described in the following embodiments.

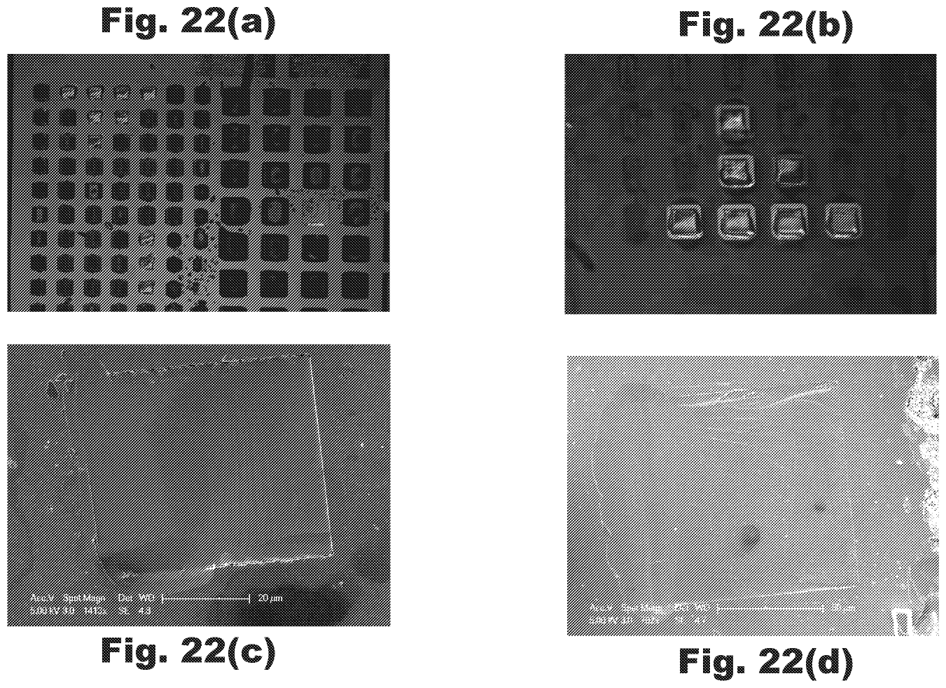

The ELO III-nitride layers 105 are removed by placing an polymer/adhesive film 601 on the sub-mask 301 patterns. FIGS. 22(a) and 22(b), respectively, show the III-nitride-based substrate 101 after removing the ELO III-nitride layers 105, and the polymer/adhesive film 601 with the removed ELO III-nitride layers 105. FIGS. 22(c) and 22(d) represent SEM images of the III-nitride-based substrate 101 with 50 μm×50 μm and 100 μm×100 μm patches, respectively, after removing the ELO III-nitride layers 105.

### Fifth Embodiment

The fifth embodiment is almost the same as the first embodiment except for the plane of the substrate 101. This embodiment is described in terms of using other planes, such as (20-21), (20-2-1), (1-100), etc. The island-like III-nitride semiconductor layers 109 comprise GaN layers with a thickness of about 12 μm grown by MOCVD on patterned semi-polar and non-polar substrates 101, for example, (20-21) or (20-2-1) or (1-100) substrates 101. Therefore, the island-like III-nitride semiconductor layers 109 are removed from the semi-polar and non-polar substrates 101 using the same method as the first embodiment.

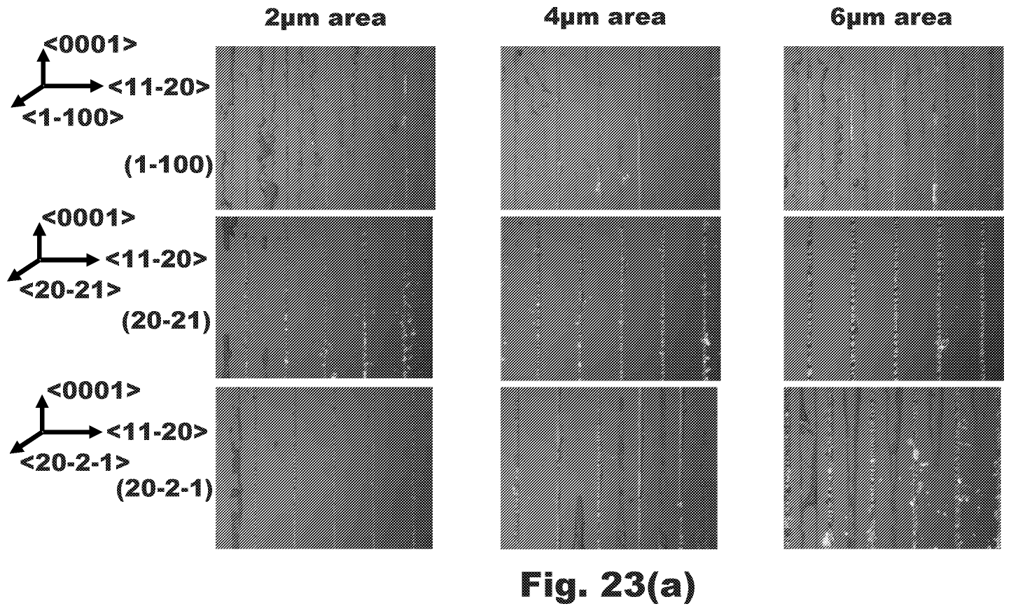

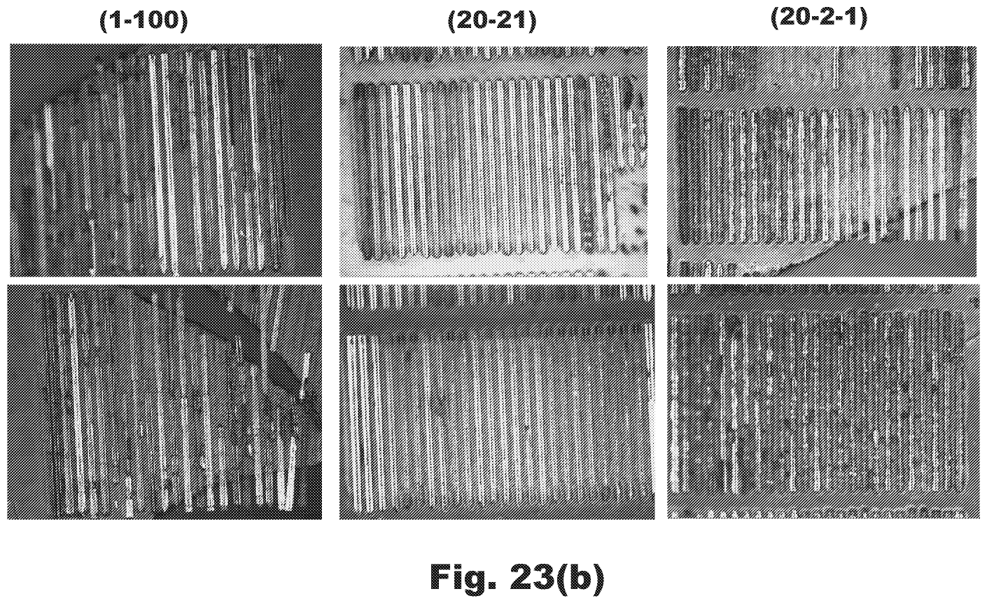

FIG. 23(a) shows optical microscope images of substrates 101 with (10-10), (20-21), (20-2-1) orientations after removing the ELO III-nitride layers 105 from opening areas 103 with widths of 2 μm, 4 μm and 6 μm; and FIG. 23(b) shows images of ELO III-nitride layers 105 on the polymer/adhesive film 601 after being removed from substrates 101 with the (10-10), (20-21), (20-2-1) orientations.

In other embodiments, other orientations, such as (30-31), (30-3-1), (10-11), (10-1-1), (11-22), (11-2-2), etc., can be used. In addition, various off-angle plane substrates 101 can be used as well.

This method also can be utilized when a hetero-substrate 201 is used instead of a III-nitride-based substrate 101. The hetero-substrate 201 may include, but is not limited to, sapphire, LiAlO₂ (LAO), SiC, Si, etc.

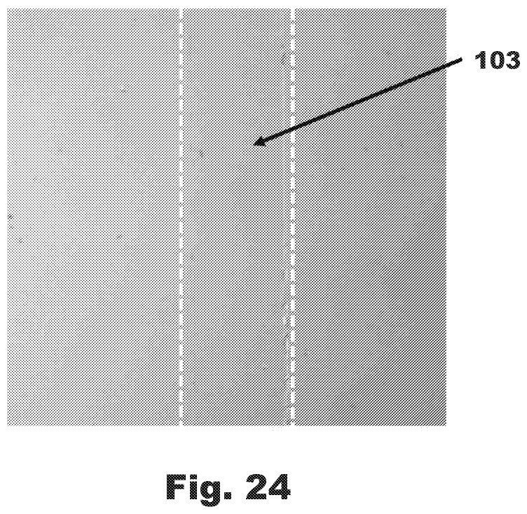

In the case of m-plane and c-plane III-nitride substrates 101, the cleavability of the m-plane and c-plane can be used for removing the ELO III-nitride layers 105. FIG. 24 is an image of a surface of an m-plane substrate 101 after the ELO III-nitride layers 105 have been removed, showing that the surface of the substrate 101 is extremely smooth following the removal.

### Sixth Embodiment

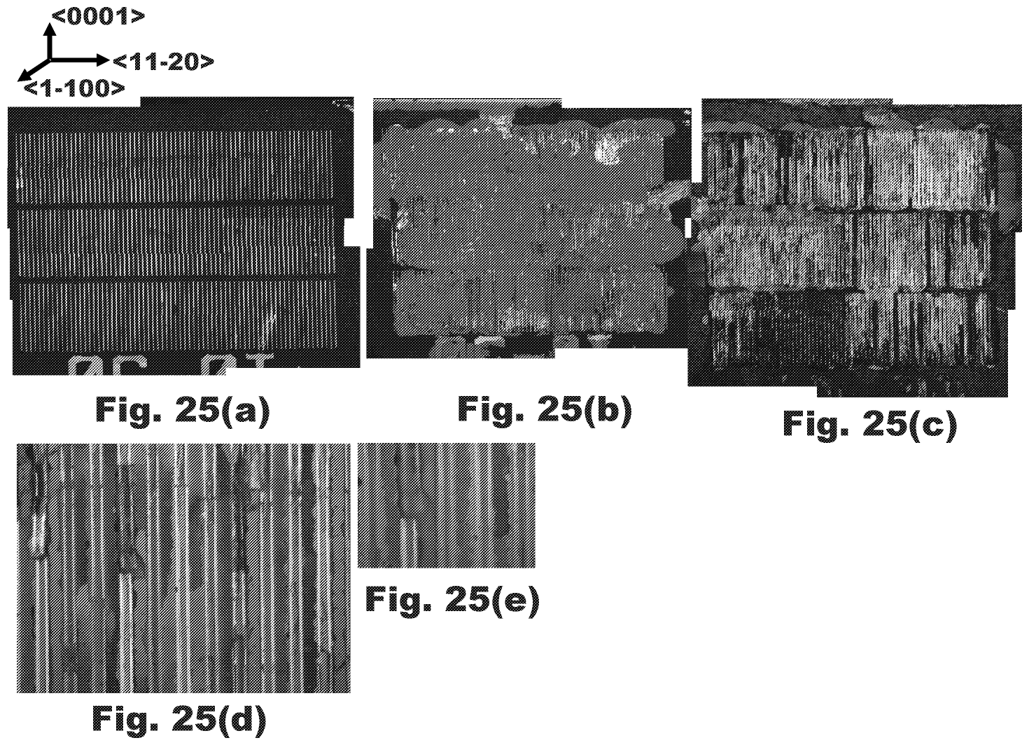

The sixth embodiment is almost the same as the first embodiment except for the use of the ELO III-nitride layers 105. Specifically, this embodiment uses AlGaN as an ELO III-nitride layer 105. FIGS. 25(a), 25(b), 25(c), 25(d) and 25(e) are optical microscope images of ELO III-nitride layers 105 comprised of AlGaN before and after being removed from a III-nitride-based substrate 101.

FIG. 25(a) comprises microscopic image of stripes on a nonpolar (1-100) plane of the III-nitride-based substrate 101. In this example, the ELO III-nitride layer 105 has a 2-3% Al composition, a thickness of about 25-30 μm, and no cracks after being grown.

FIG. 25(b) is a schematic illustration including an m-plane III-nitride-based substrate 101, growth restrict mask 102, and EU) III-nitride layers 105 comprising n-AlGaN.

FIG. 25(c) is a microscope image of the III-nitride-based substrate 101 after removing ELO III-nitride layers 105 comprising AlGaN.

FIGS. 25(d)-25(f) are microscopic images of ELO III-nitride layers 105 comprised of AlGaN removed using a polymer/adhesive film 601.

The present embodiment can utilize a high quality and low defect density GaN substrate 101 along with ELO III-nitride layers 105 comprised of AlGaN as a technique to obtain low defect density and high crystal quality semiconductor layers. It may possible to fabricate a near-UV device 110 on top of these high quality AlGaN ELO III-nitride layers 105 and then remove the AlGaN ELO III-nitride layers 105 and near-UV III-nitride semiconductor device layers 106 using the invention as described in first embodiment.

Near-UV and UV devices 110 cannot use GaN substrates 101 in their final device 110 structure because the GaN substrate 101 absorbs UV-light. So, this invention is useful in separating the AlGaN ELO III-nitride layers 105 and near-UV III-nitride semiconductor device layers 106 from the GaN substrate 101 for use as the near-UV or UV device 110.

Also, in this embodiment, the AlGaN ELO III-nitride layers 105 do not coalesce, strain which is applied from the difference in thermal expansion is efficiently released by the AlGaN ELO III-nitride layers 105. Because the island-like III-nitride semiconductor layers 109 including the AlGaN ELO III-nitride layers 105 can be removed at an interface of the AlGaN ELO III-nitride layers 105 with an AlGaN/GaN substrate 101.

The AlGaN ELO III-nitride layers 105 also would be useful for near-UV or deep- LEDs, However, a GaN substrate 101 would absorb light that is shorter than 365 nm, due to the band-gap of GaN, and thus would not be suitable for near-UV and deep-UV LEDs. Since this method can remove the GaN substrate 101, which absorbs UV light, this would be suitable for UV and near-UV LEDs. Further, this method can be utilized with an MN substrate 101, which would be suitable for a deep-UV LED.

As set a forth, it is much preferable that the composition of the ELO III-nitride layers 105 are different from the substrate 101.

### Seventh Embodiment

The seventh embodiment is almost the same as the first embodiment except for using a different growth restrict mask 102 material and a thicker growth restrict mask 102 than that used in the first embodiment. For example, the seventh embodiment may use a growth restrict mask 102 comprised of Silicon Nitride (SiN) as the interface layer between the III-nitride-based substrate 101 and the ELO III-nitride layers 105, wherein the growth restrict mask 102 comprises 1 μm SiO₂ followed by 50 nm SiN. This may be used, for example, with an m-plane (1-100) III-nitride-based substrate 101, or a III-nitride substrate 101 having another plane orientation, for example, (30-31), (30-3-1), (20-21), (20-2-1) (10-11), (10-1-1), (11-22), (11-2-2), etc.

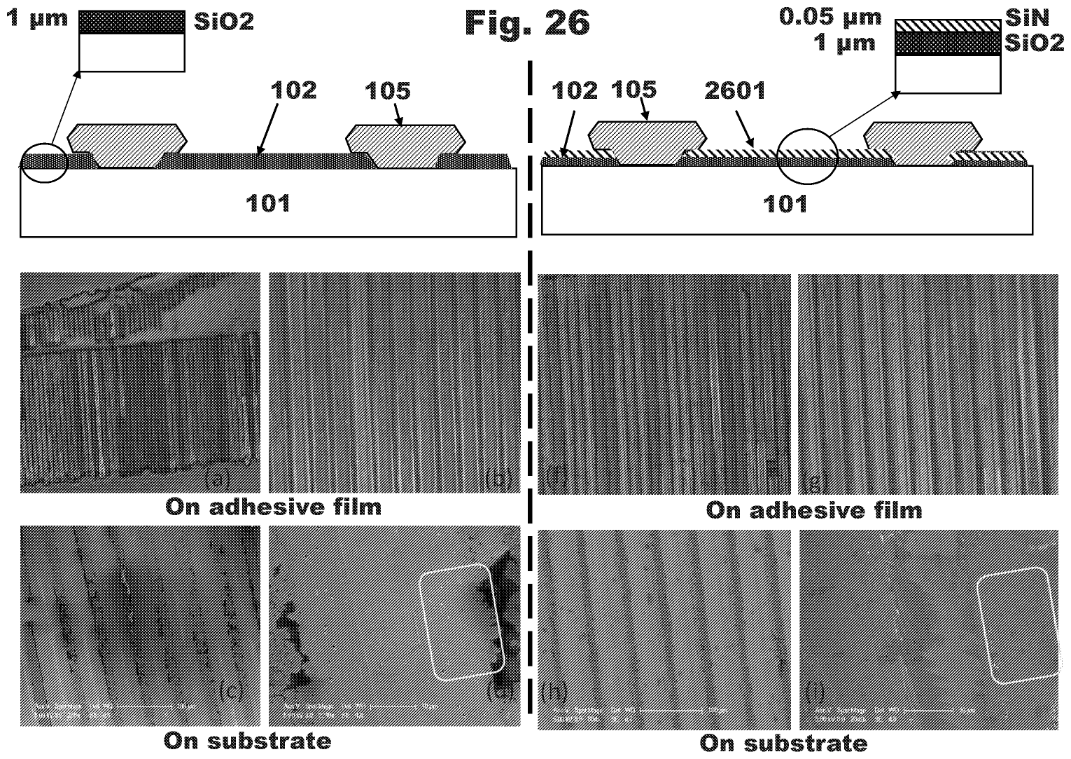

FIG. 26 includes both schematics and SEM images illustrating the effects of a growth restrict mask 102 comprised of SiO₂ or a growth restrict mask 102 comprised of SiO₂ and SiN 2601 on an interface with the ELO III-nitride layers 105 grown on a III-nitride-based substrate 101, wherein the images show the interface effects on a backside portion of the layers 105.

The SEM images indicate that the diffusion between the SiO₂ growth restrict mask 102 and the III-nitride-based substrate 101 is more when compared to the SiO₂ growth restrict mask 102 capped with SiN, which will benefit the recycling of the III-nitride-based substrate 101. In the latter case, the III-nitride-based substrate 101 will need to be polished less after removing the ELO III-nitride layers 105, when compared to the previous case, which may further reduce the cost of manufacturing semiconducting devices using this invention.

### Eighth Embodiment

The eighth embodiment is same as the first embodiment except in the alteration of directions of applied stress on the polymer/adhesive film 601 while lowering and/or raising the temperature invention.

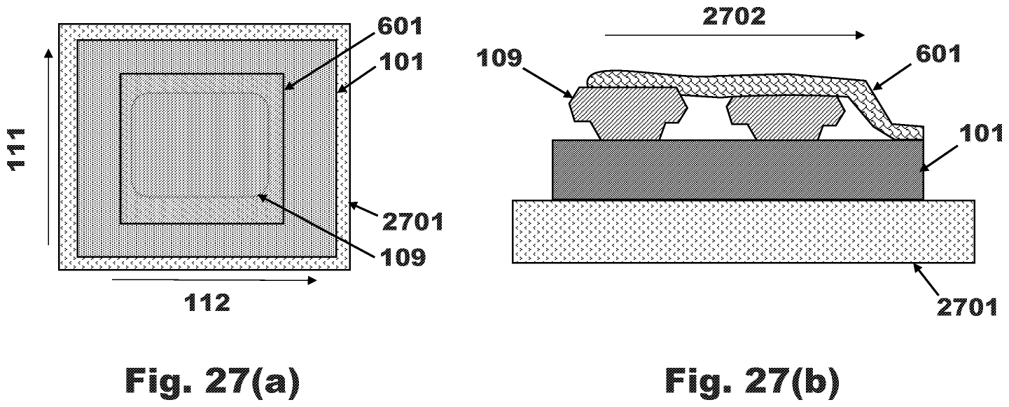

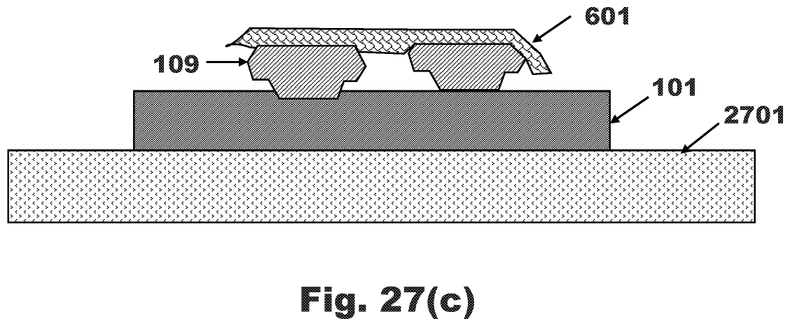

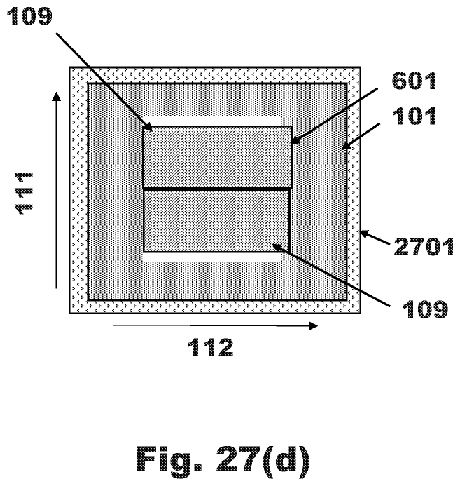

FIGS. 27(a), 7(b), 27(c) and 27(d) are schematic illustrations of alternative attachment methods of the polymer/adhesive film 601 to realize the invention, wherein these techniques modify the applied stress while lowering or raising temperature. In this embodiment, the substrate 101 resides on a supporting base 2701, such as a quartz plate.

In FIG. 27(a), the sides of the island-like III-nitride semiconductor layers 109 are aligned along the first and second directions 111, 112, and one part of the adhesive/polymer/adhesive film 601 contacts the substrate 101 on one side, as shown in FIG. 27(b). By doing this, the shrinking direction 2702 is controlled toward the one side. The movement of the film 601 during contraction and expansion while lowering or raising the temperature is not limited or stopped by the contact with the substrate 101. The shrinkage direction 2702 being in one direction, e.g., the second direction 112, has effectively worked to remove the island-like III-nitride semiconductor layers 109.

Alternatively, as shown in FIG. 27(c), the film 601 can only be attached to the island-like III-nitride semiconductor layers 109 without contacting the substrate 101.

As shown in FIG. 27(d), the adhesive/polymer/adhesive film 601 is attached to two (or more) separated island-like III-nitride semiconductor layers 109. Moreover, there may be two (or more) separated adhesive/polymer films 601, with one film 601 attached to one (or more) of the separated island-like III-nitride semiconductor layers 109. In this example, pressure applied in the second direction 112 can be reduced, which prevents the films 601 from twisting excessively. By doing this, the surface of the substrate 101 at the opening areas 103 is smooth, after the removal of the island-like III-nitride semiconductor layers 109.

In this embodiment, at least one of the edges of the island-like III-nitride semiconductor layers 109, along with a supporting base 2701, where the substrate 101 rests, are exposed to the ambient temperature. As the temperature is changed, there is a change in the shrinking direction 2701. Due to this controlled change in the shrinking direction 2701, or alternatively, the expansion direction, of the polymer/adhesive film 601, the quality and productivity of the transferred island-like III-nitride semiconductor layers 109 can be improved.

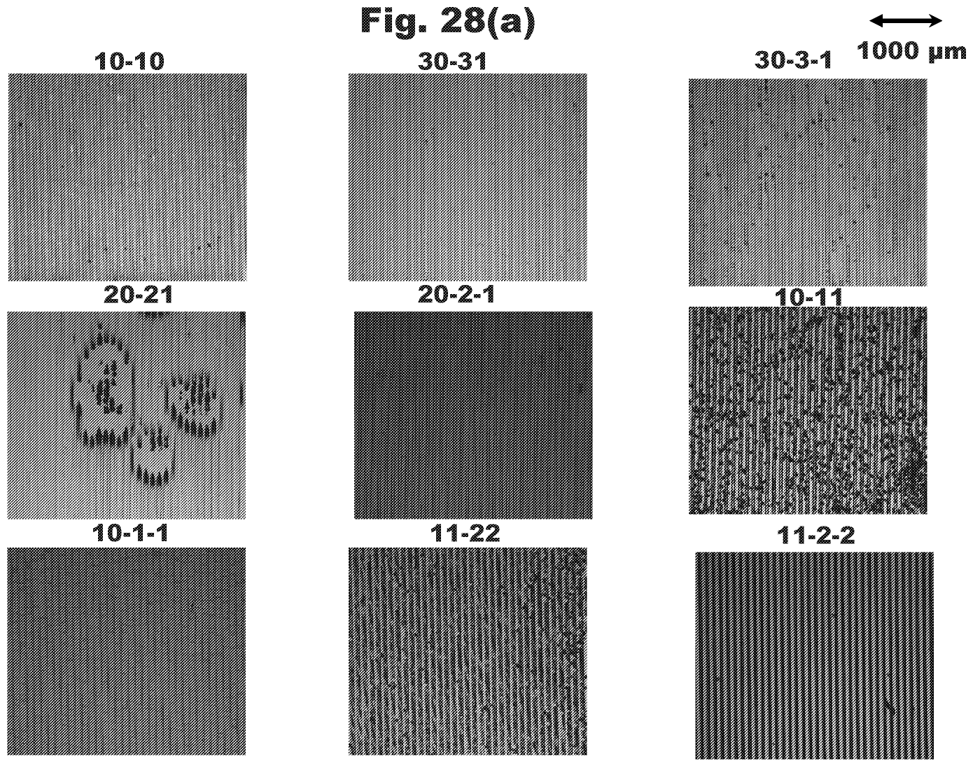

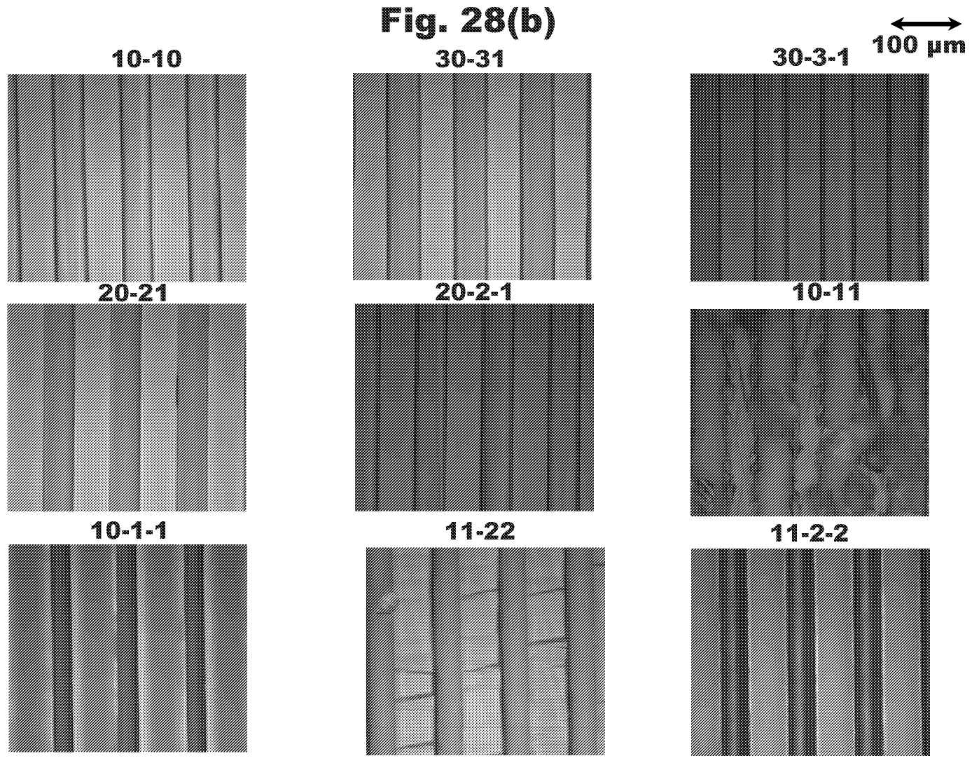

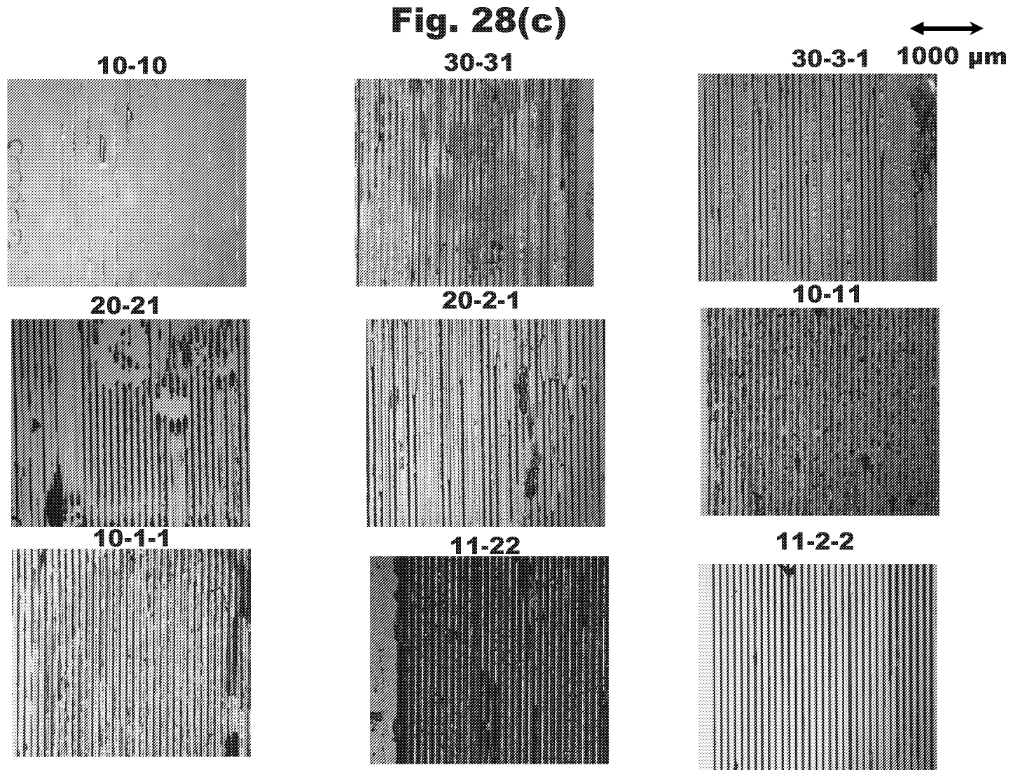

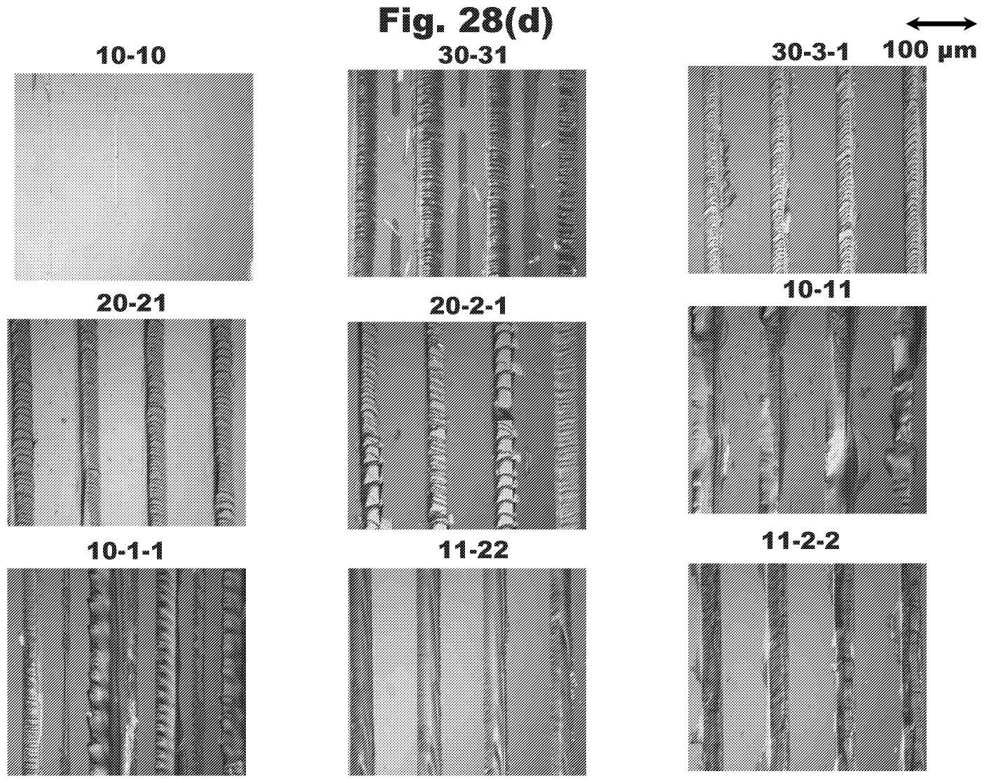

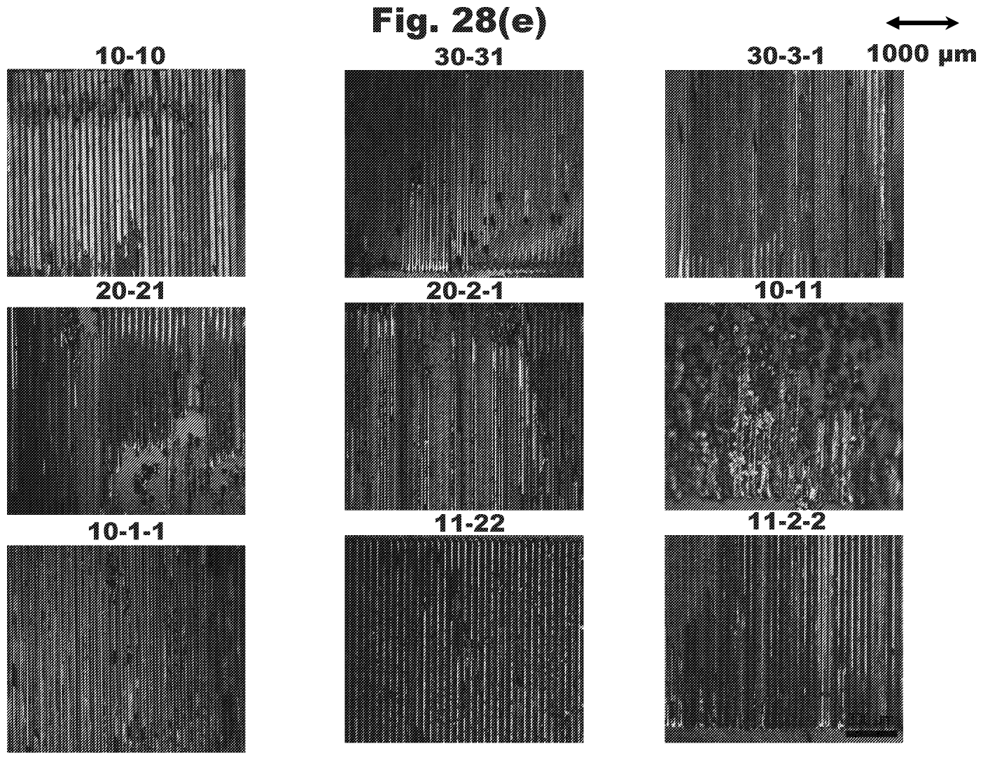

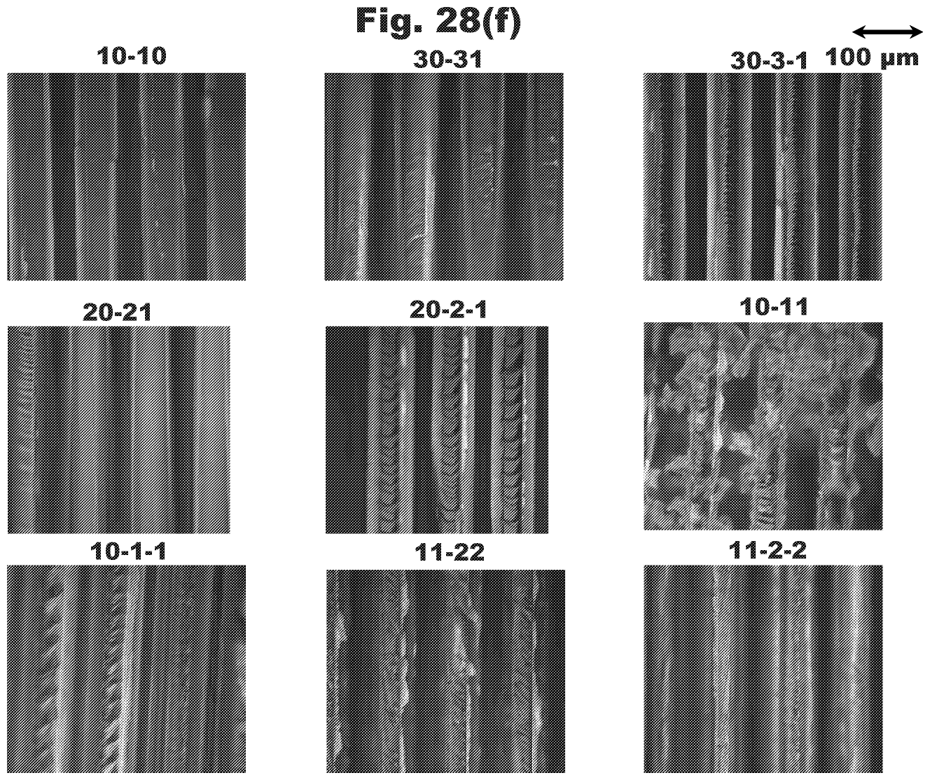

FIGS. 28(a), 28(b), 28(c), 28(d), 28(e) and 28(f) are optical microscopic images of the ELO III-nitride layers 105 grown using MOCVD on substrates 101 with orientations along various planes including the (10-10), (10-11), (20-21), (30-31), (11-22), (10-1-1), (20-2-1), (30-3-1), and (11-2-2) planes, after the ELO III-nitride layers 105 have been removed from the substrates 101 using the polymer/adhesive film 601.

Optical microscope images of the ELO In-nitride layers 105 grown on the various planes of the III-nitride substrate 101 are shown in FIG. 28(a) at a lower magnification, and the same images are shown in FIG. 28(b) at higher magnification.

Optical microscope images of the substrates 101 having the various planes after the ELO III-nitride layers 105 have been removed, are shown in FIG. 28(c) at lower magnification, and the same images are shown in FIG. 28(d) at higher magnification.

Optical microscope images of the ELO III-nitride layers 105 after they have been removed from the substrates 101 having various planes are shown in FIG. 28(e) at a lower magnification, and the same images are shown in FIG. 28(1) at higher magnification.

### Ninth Embodiment

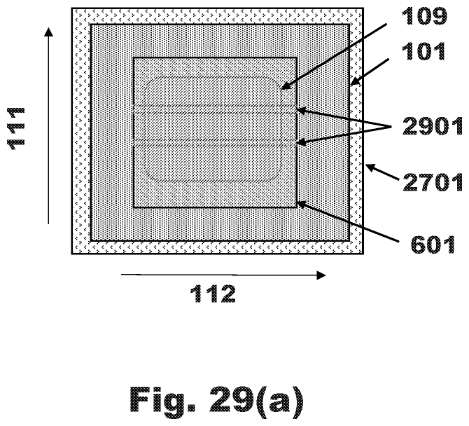

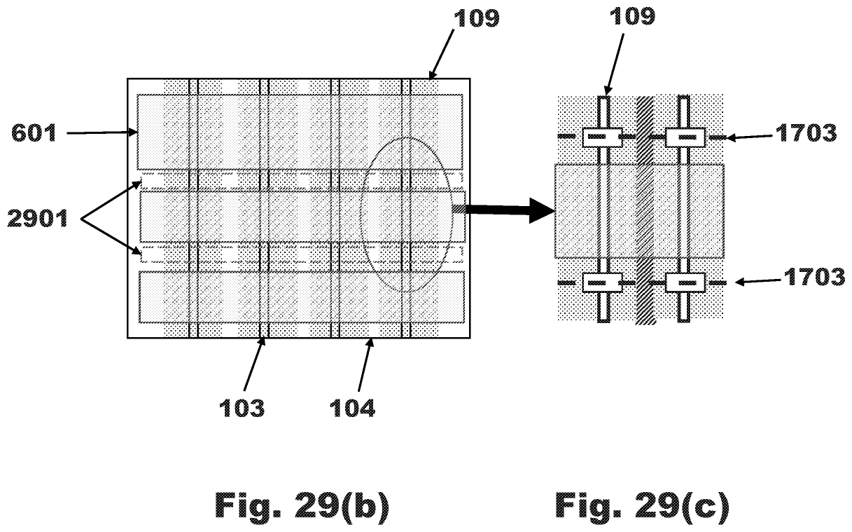

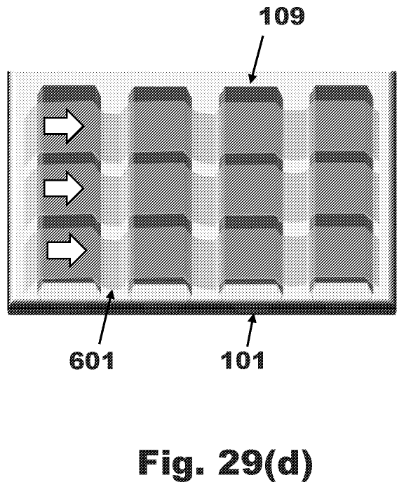

The ninth embodiment is same as the eighth embodiment except for adding an improved version of direction to the applied stress on the polymer/adhesive film 601 while lowering and/or raising the temperature to improve the quality and yield of the removed island-like III-nitride semiconductor layers 109, as shown in the schematic illustrations of FIGS. 29(a), 29(b), 29(c) and 29(d).

As shown in FIG. 29(a), instead of placing the polymer/adhesive film 601 to cover the entire island-like III-nitride semiconductor layers 109, the polymer/adhesive film 601 is designed to have narrow openings 2901 at specified intervals along the first direction 111.

As shown in FIGS. 29(b) and 29(c), the polymer/adhesive film 601 lies in-between two chip scribe lines 1703 of a ridge of one device 110.

As shown in FIG. 29(d), the polymer/adhesive film 601 can remove one or more of the island-like III-nitride semiconductor layers 109 when peeled from the substrate 101. This technique provides unique control over the strain applied to the island-like III-nitride semiconductor layers 109, which allows the island-like III-nitride semiconductor layers 109 to be removed at a much higher quality at an elevated throughput. Island-like III-nitride semiconductor layers 109 that are longer in the first direction 111 and wider in the second direction 112 can be peeled from the substrate 101 without cracking or twisting. For example, the typical length of the island-like III-nitride semiconductor layers 109 removed using this technique is about 4 mm with an opening area 103 width of about 25 μm.

### Tenth Embodiment

The tenth embodiment induces thermal stress between the polymer/adhesive film 601 and island-like III-nitride semiconductor layers 109 by either raising or lowering the temperature. As a result, a soft region of the polymer/adhesive film 601 is pushed uniformly onto and around the island-like III-nitride semiconductor layers 109. As a result, island-like III-nitride semiconductor layers 109 with a large aspect ratio or island-like III-nitride semiconductor layers 109 with a random shape can be removed from the substrate 101 very effectively. For example, the images shown in FIGS. 28(a), 28(b), 28(c) and 28(d) are of ELO III-nitride layers 105 having an aspect ratio of nearly 70, a length of about 4000 μm, and a width of about 55 μm.

Nonetheless, removing epi-layers from larger wafers (larger than 2-inch) will be challenging for the other alternatives to this techniques, such as spalling and PEC etching. Moreover, this technique has additional advantages.

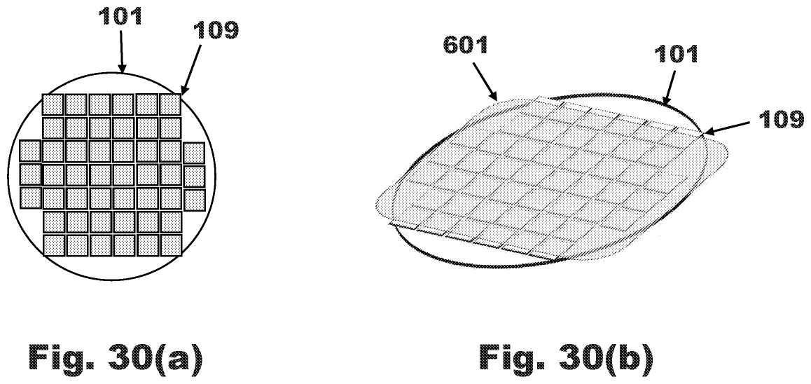

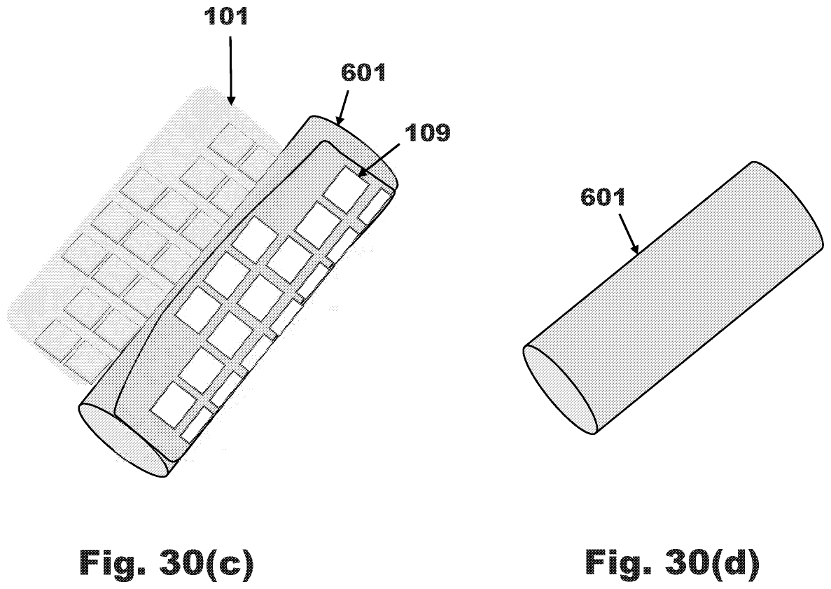

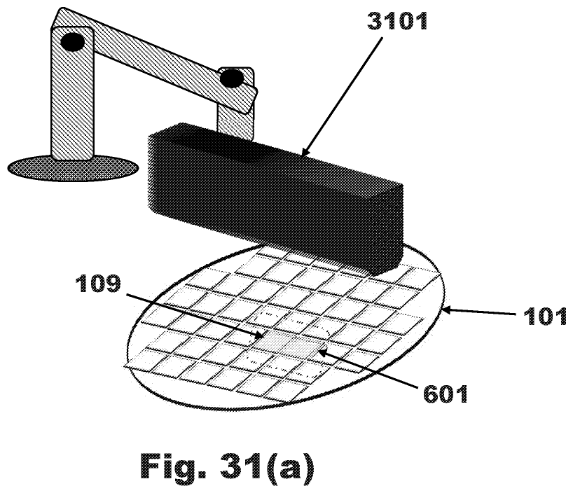

FIGS. 30(a), 30(b), 30(c) and 30(d) are schematic views showing how to peel the island-like III-nitride semiconductor layers 109 from substrates 101 comprising large-scale wafers using the polymer/adhesive film 601 and applying local thermal stress.

As shown in FIGS. 30(a) and 30(b), the wafer 101 contains a plurality of separated island-like III-nitride semiconductor layers 109, and the polymer/adhesive film 601 is applied to the surface of the wafer 101. As shown in FIG. 30(c), the polymer/adhesive film 601 is rolled up, which removes the island-like III-nitride semiconductor layers 109 from the wafer 101, with the island-like III-nitride semiconductor layers 109 attached to the polymer/adhesive film 601. As shown in FIG. 30(d), the polymer/adhesive film 601 is rolled into a tube.

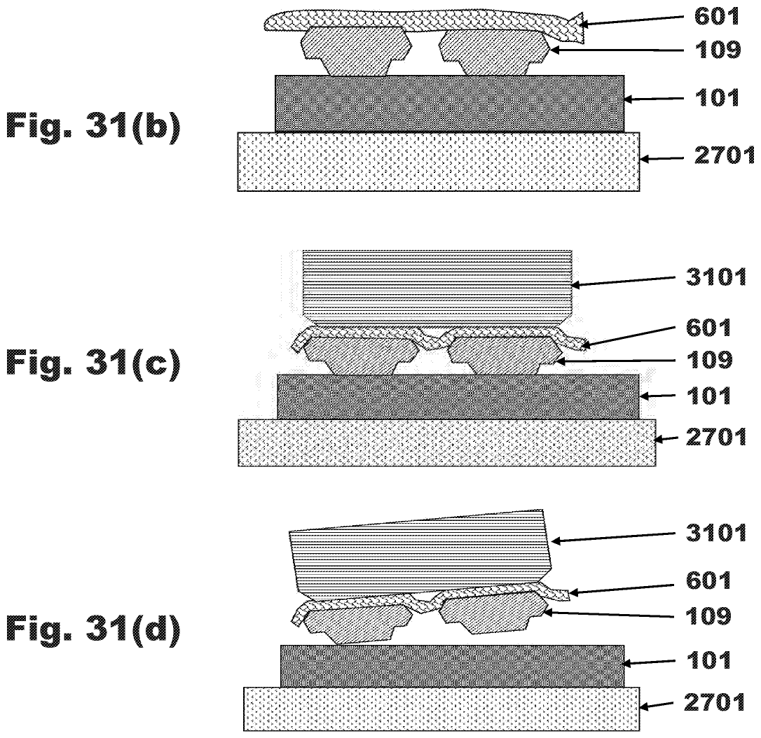

FIGS. 31(a), 31(b), 31(c) and 31(d) are schematic views showing how to peel off at least two island-like III-nitride semiconductor layers 109 at a selective region of the wafer 101. As shown in FIG. 31(a), after placing polymer/adhesive film 6101 on the selected island-like III-nitride semiconductor layers 109 on the wafer 101, a pressure is applied by a cylindrical roller 3101 onto the polymer/adhesive film 601 such that the polymer/adhesive film 601 reaches at least below the top surface of the selected island-like III-nitride semiconductor layers 109. The temperature of the wafer 101 including the polymer/adhesive film 601 is lowered or raised continuously using the cylindrical roller 3101. The role of the roller 3101 can be assumed as a pressure applier and as a local cooling and/or heating generator when it rolls across the wafer 101. By lowering and raising the temperature of the cylindrical roller 3101 at each region where it touches the wafer 101 and simultaneously peeling the polymer/adhesive film 601 by hooking one end of the polymer/adhesive film 601 to the cylindrical roller 3101, removing the island-like III-nitride semiconductor layers 109 from larger size wafers 101 is possible.

As this technique does not involve any chemicals to peel off the island-like III-nitride semiconductor layers 109, the same wafer 101 with little or no preparation after crossing the cylindrical roller 3101 to other end of the wafer 101 can be repeated several times even if some of the island-like III-nitride semiconductor layers 109 remain on the wafer 101 after the first attempt. As a result, this technique can obtain a 100% throughput with a less lead time in a cheaper way.

### Eleventh Embodiment

The eleventh embodiment is same as the tenth embodiment but adds one more advantages as compared to other peeling techniques. It is highly impossible to pick ELO III-nitride layers 105 from a selected portion of an entire wafer 101 using other mentioned removal techniques, like PEC etching, spalling and laser liftoff.

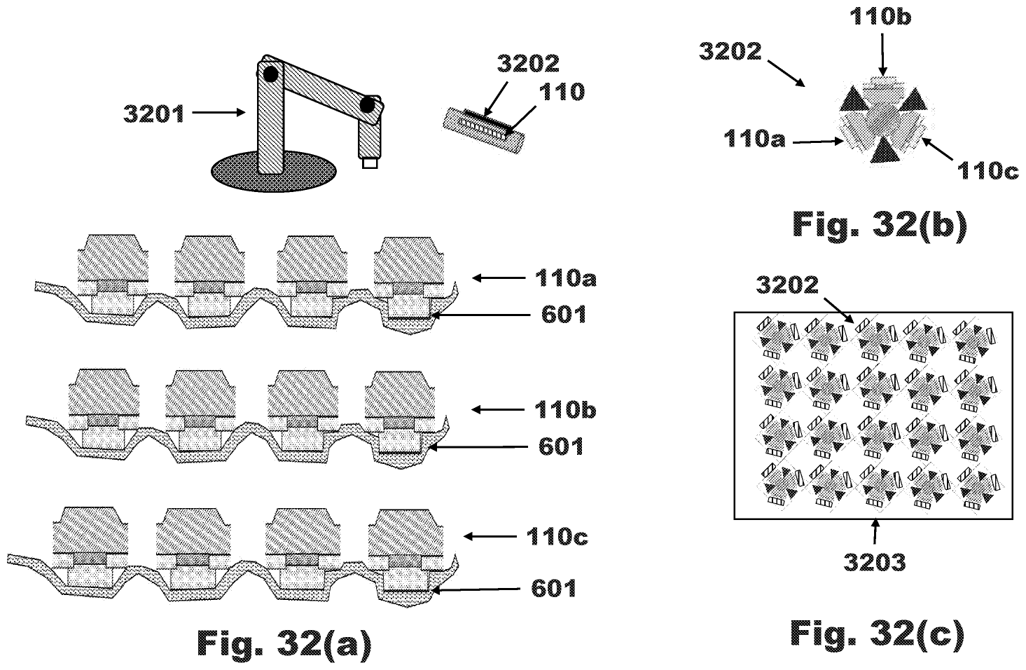

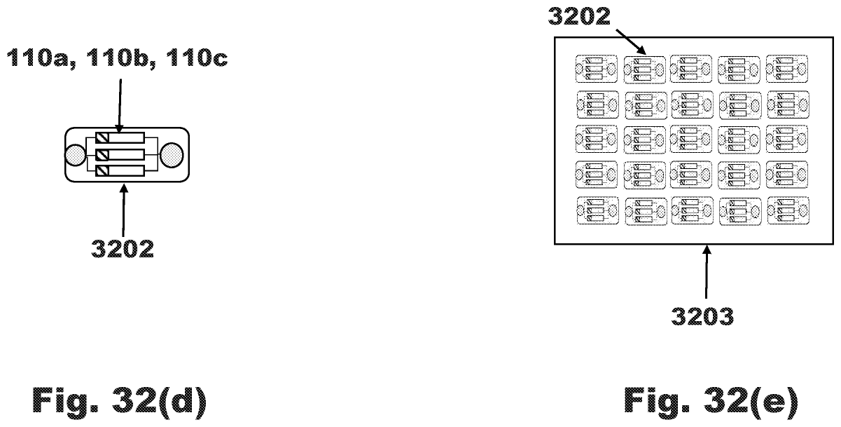

FIGS. 32(a), 32(b) and 32(c) are schematic views showing how to mass produce displays using laser diode devices 110 of this invention, while FIGS. 32(d) and 32(e) are schematic views showing how to mass produce displays using light emitting diode devices 110 of this invention.

FIG. 32(a) shows different types of devices 110, including red light emitting devices 110a, green light emitting devices 110b, and blue light emitting devices 110c, all of which have been transferred onto separate strips of the polymer/adhesive film 601. A robotic arm 3201 picks these different devices 110a, 110b, 100c and places them into a package 3202.

In the embodiment shown in FIG. 32(b), each of the packages 3202 includes a red light emitting laser diode device 110a, green light emitting laser diode device 110b, and blue light emitting laser diode device 110c. As shown in FIG. 32(c), multiple such packages 3202 may be assembled into a LD display 3203.

In the embodiment shown in FIG. 32(d), each of the packages 3202 includes a red light emitting diode device 110a, green light emitting diode device Hob, and blue light emitting diode device 110c. As shown in FIG. 32(e), multiple such packages 3202 may be assembled into an LED display 3203.

### Twelfth Embodiment

The twelfth embodiment is the same as the eleventh embodiment.

The present day display industry relies on wafer level testing to minimize the number of defective devices. This embodiment can select and pick individual island-like semiconductor layers 109 or devices 110 from a substrate 101 with less effort, and integrate them with other display elements. For example, this embodiment can select and pick a blue light emitting device for integration with green and red light emitting devices to create a pixel of display.

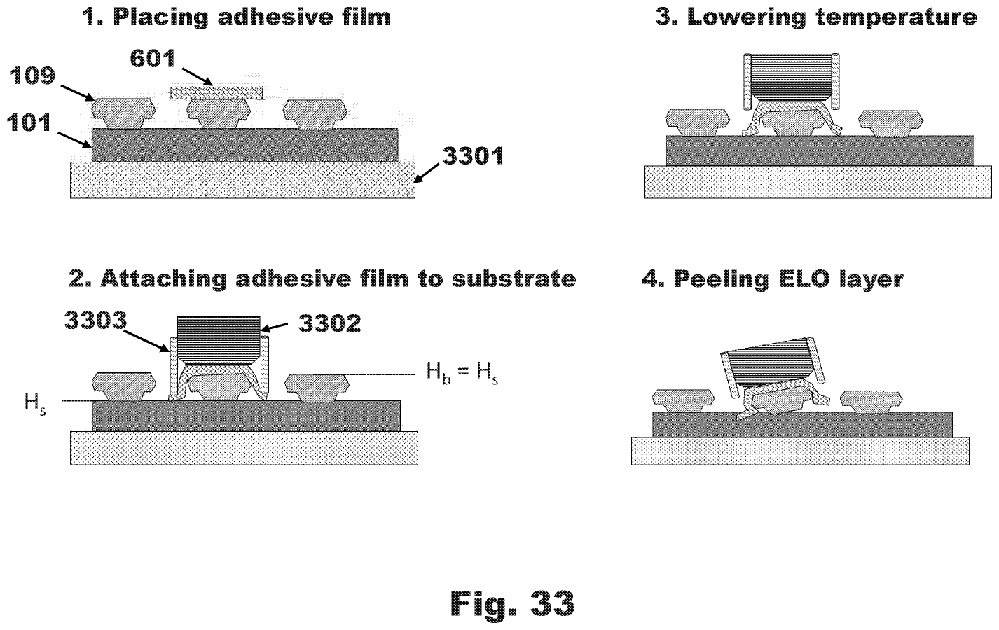

FIG. 33 is a schematic view and flowchart showing how to peel off at least one of the island-like III-nitride semiconductor layers 109 at a selective region from a substrate 101 mounted on a support 3301.

Step 1 involves placing the polymer/adhesive film 601 on the selected island-like III-nitride semiconductor layers 109.

Step 2 involves attaching the polymer/adhesive film 601 to the substrate 101. For example, a robotic head piece 3302 may include retractable pins 3303 on both sides of the robotic head piece that are pushed down until at least one side of the polymer/adhesive film 601 touches the surface of the substrate 101 in a recess region, such that H_{b} is equal to Hₛ. Once the polymer/adhesive film 601 reaches the surface of the substrate 101, the retractable pins 3303 are pulled back.

Step 3 involves lowering the temperature, which may use the same robotic head piece 3302 locally or through controlling an ambient over the entire substrate 101. As the temperature is lowered, a soft portion of the polymer/adhesive film 601 between surface of the substrate 101 and the top surface of the island-like III-nitride semiconductor layers 109 contracts and applies stress towards the island-like III-nitride semiconductor layers 109 from where it was held down onto the substrate 101, which results in a crack being initiated at the interface with the island-like III-nitride semiconductor layers 109.

Step 4 involves peeling the island-like III-nitride semiconductor layers 109 from the substrate 101. Peeling of the film 601 can be done either slightly by moving the robotic head piece 3302 along a shortest direction of the island-like III-nitride semiconductor layers 109 in order to avoid unwanted cracking in the island-like III-nitride semiconductor layers 109.

The result is the island-like III-nitride semiconductor layers 109 attached to the polymer/adhesive film 601, which may then be integrated with other elements of a functional display. Moreover, this technique is not limited only to displays, but can be applied to other applications that need to select and pick individual ones of the island-like III-nitride semiconductor layers 109.

### Thirteenth Embodiment

The thirteenth embodiment s same as the first embodiment except for the width of the opening area 103. In this embodiment, three samples were fabricated which have different widths for the opening areas 103, including 50, 100 or 200 μm.

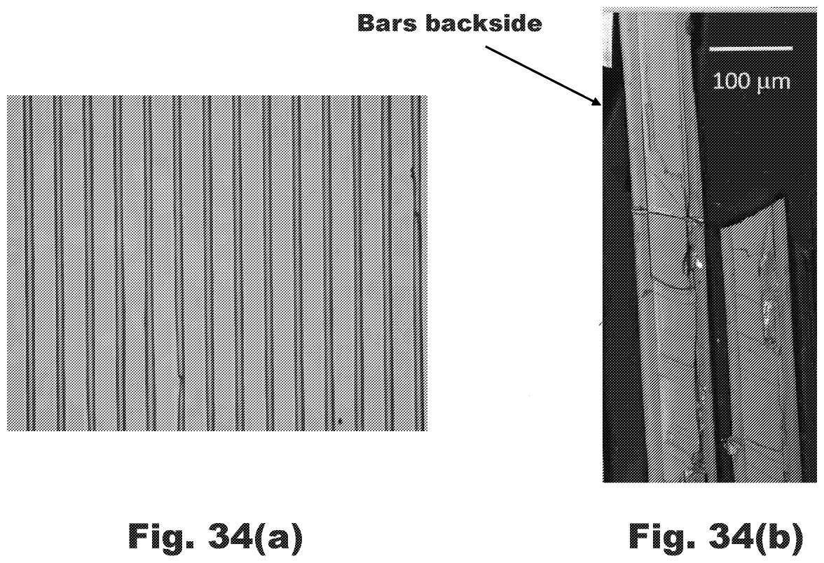

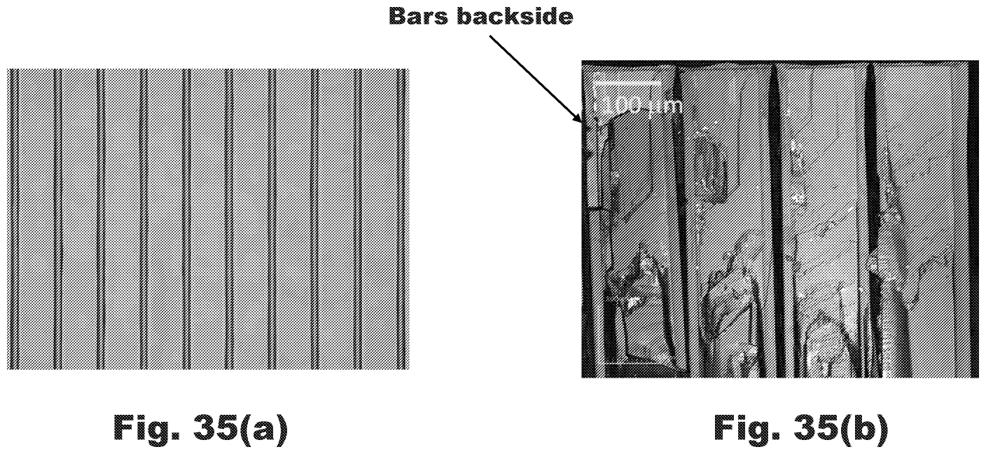

FIG. 34(a) is an image of the ELO III-nitride layers 105 grown on an m-plane substrate 101 using on a growth restrict mask 102 having opening areas 103 with a width of 50 μm and mask stripes with a width of 50 μm; and FIG. 34(b) is an image of the ELO III-nitride layers 105 transferred onto the polymer/adhesive film 601.

FIG. 35(a) is an image of the ELO III-nitride layers 105 grown on an m-plane substrate 101 using a growth restrict mask 102 having opening areas 103 with a width of 100 μm and mask stripes with a width of 50 μm; and FIG. 35(b) is an image of the ELO III-nitride layers 105 transferred onto the polymer/adhesive film 601.

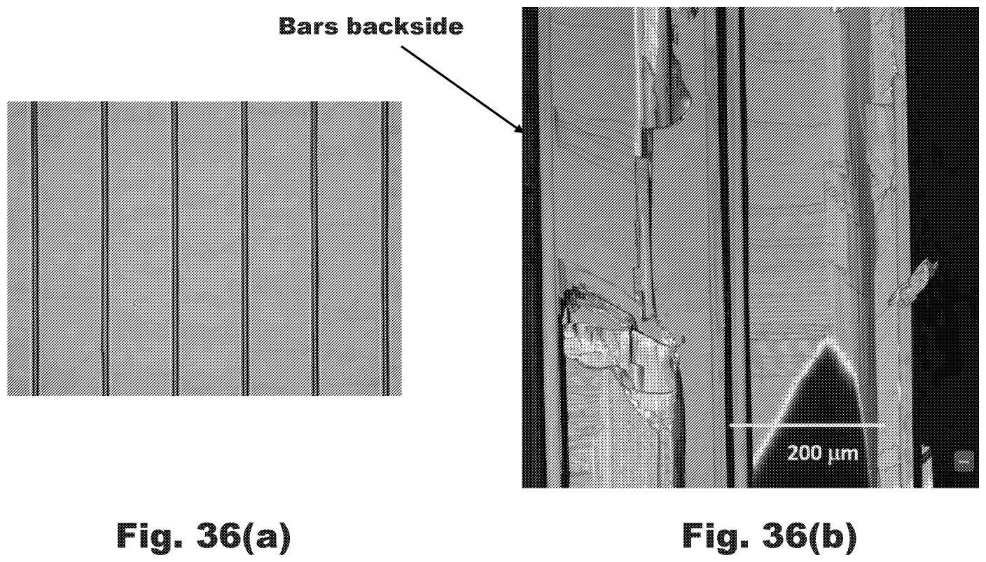

FIG. 36(a) is an image of the ELO III-nitride layers 105 grown on an m-plane substrate 101 using a growth restrict mask 102 having opening areas 103 with a width of 200 μm and mask stripes with a width of 50 μm; and FIG. 36(b) is an image of the ELO III-nitride layers 105 transferred onto the polymer/adhesive film 601.

### Fourteenth Embodiment

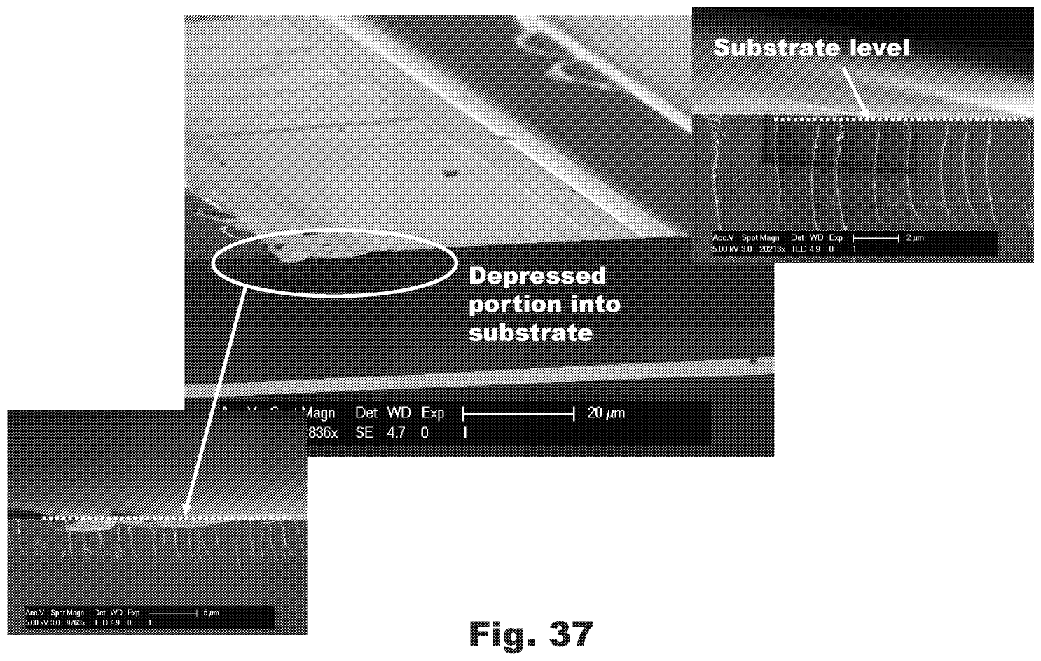

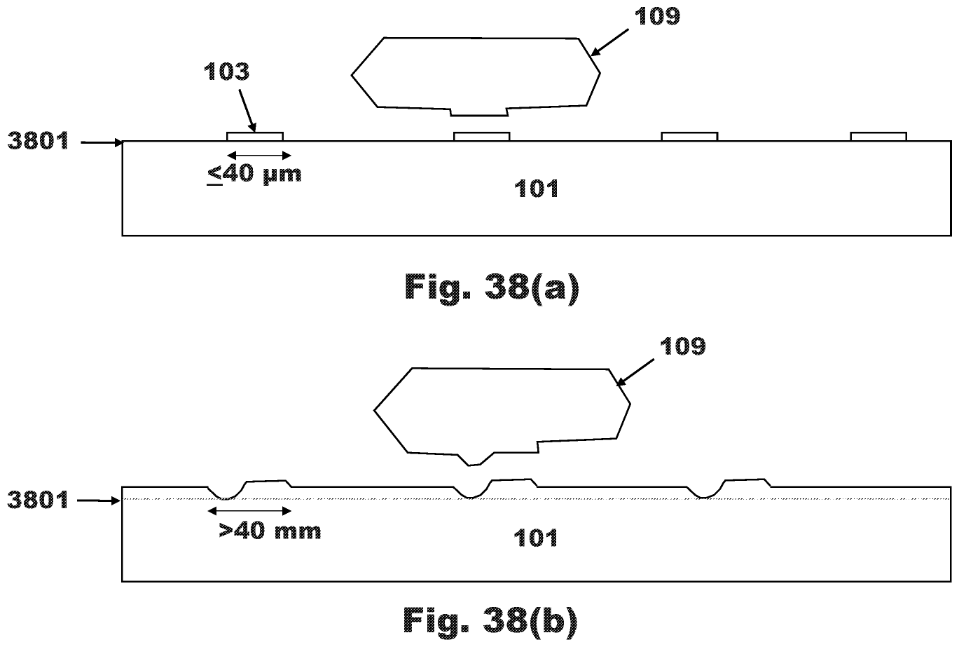

The fourteenth embodiment claims semiconductor layers made using this invention, which provide an advantage in recycling. Specifically, FIG. 37 includes images of the surface of the substrate 101 following removal of the island-like III-nitride semiconductor layers 109 at an opening area 103, and FIGS. 38(a) and 38(b) are schematics illustrating the surface of the substrate 101 following removal of the island-like III-nitride semiconductor layers 109 at an opening area 103.

In FIG. 38(a), the bottom surface of the island-like III-nitride semiconductor layers 109 at the opening area 103 does not contain material that originates from the substrate 101 when the opening area 103 has a width of 40 μm or less.

However, in FIG. 38(b), the island-like III-nitride semiconductor layers 109 with an opening area 103 having a width over 40 μm does contain material that originates from the substrate 101 between two sides at the bottom portion. This phenomenon sometimes happens when removing the island-like III-nitride semiconductor layers 109 from the substrate 101 mechanically. This is also reflected in the depressed portions of the substrate 101 shown in the images of FIG. 37.

Surface 3801 in both FIGS. 38(a) and 38(b) shows the depth of polishing required to recycle the substrate 101. In FIG. 38(a), the depth of polishing is minimal, while in FIG. 38(b), the depth of polishing is significant. In FIG. 38(a), unlike FIG. 38(b), polishing of the substrate 101 for reuse after removing the island-like III-nitride semiconductor layers 109 will not consume more portions of the substrate 101, thereby increasing the recycle life of the substrate 101.

Therefore, it is much better that the removed island-like III-nitride semiconductor layers 109 do not contain a portion of the substrate 101.

### Process Steps

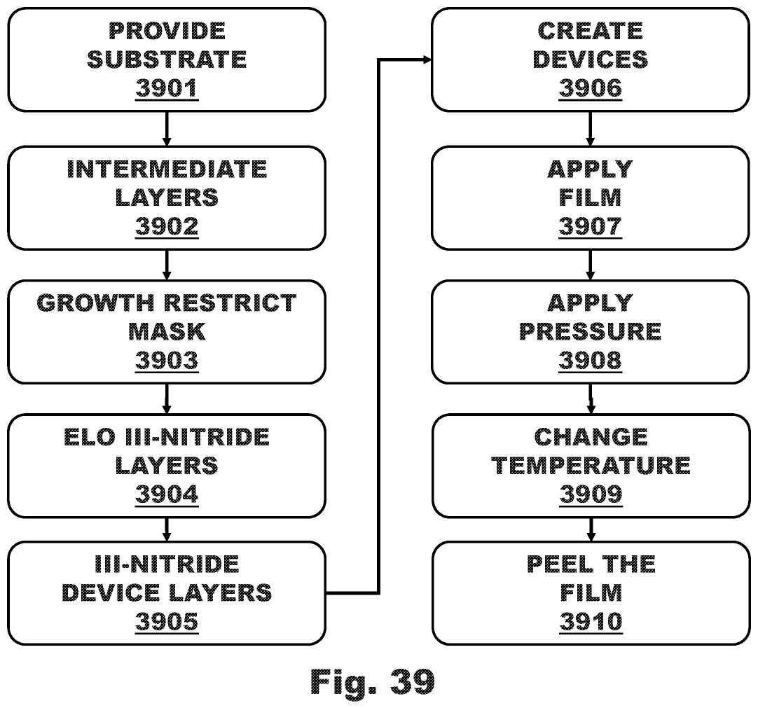

FIG. 39 is a flowchart that illustrates a method of removing semiconductor layers from a substrate 101, wherein the semiconductor layers are comprised of island-like III-nitride semiconductor layers 109 grown on a substrate 101 using a growth restrict mask 102 and epitaxial lateral overgrowth, and the epitaxial lateral overgrowth is stopped before the island-like III-nitride semiconductor layers 109 coalesce.

Block 3901 represents the step of providing a base substrate 101. In one embodiment, the base substrate 101 is a based substrate 101, such as a GaN-based substrate 101, or a foreign or hetero-substrate 201.

Block 3902 represents an optional step of depositing an intermediate layer on the substrate 101. In one embodiment, the intermediate layer is a III-nitride based layer, such as a GaN-based layer.

Block 3903 represents the step of forming a growth restrict mask 102 on or above the substrate 101, i.e., on the substrate 101 itself or on the intermediate layer. The growth restrict mask 102 is patterned to include a plurality of opening areas 103.

Block 3904 represents the step of growing one or more III-nitride based layers 105 on or above the growth restrict mask 102 using epitaxial lateral overgrowth, wherein the epitaxial lateral overgrowth of the III-nitride layers 105 extends in a direction parallel to the opening areas 103 of the growth restrict mask 102, and the epitaxial lateral overgrowth is stopped before the III-nitride layers 105 coalesce on the growth restrict mask 102. In one embodiment, the ELO III-nitride layers 105 are ELO GaN-based layers 105.

Block 3905 represents the step of growing one or more additional III-nitride semiconductor device layers 106 on the ELO III-nitride layers 105. These additional III-nitride semiconductor device layers 106, along with the ELO III-nitride layers 105, form one or more of the island-like III-nitride semiconductor layers 109, which may be randomly shaped. The island-like III-nitride semiconductor layers 109 may be patterned with a horizontal trench 501 extended inwards to a center of the island-like III-nitride semiconductor layers 109 with at least one side vertically below the island-like III-nitride semiconductor layers 109.

Block 3906 represents the step of fabricating devices 110 from the island-like III-nitride semiconductor layers 109, wherein the devices 110 may comprise laser diode devices 110 or light emitting diode devices 110.

Block 3907 represents the step of applying a polymer/adhesive film 601 to the island-like III-nitride semiconductor layers 109.

Block 3908 represents the step of applying a pressure on the film 601 from one or more sides. A compressible material 702 may be placed upon the film 601 to improve its attachment to the island-like III-nitride semiconductor layers 109; and the pressure is applied to the compressible material 702 for improved bonding of the film 601 to the island-like III-nitride semiconductor layers 109. In one embodiment, the film 601 has a top layer and a bottom layer, the bottom layer is pushed inward to a recess region between the island-like III-nitride semiconductor layers 109, and the top layer is harder than the bottom layer. Preferably, a bottom surface of the film 601 on or above the island-like III-nitride semiconductor layers 109 is pushed to a level at least below a top surface of the island-like III-nitride semiconductor layers 109, wherein the bottom surface of the film 601 reaches below a surface of a convexity region of the island-like III-nitride semiconductor layers 109. In addition, the film may be applied below a top surface of the island-like III-nitride semiconductor layers 109 and on to a surface of the substrate 101.

Block 3909 represents the step of changing a temperature of the film 601 and the substrate 101, such that a crack is induced into the island-like semiconductor layers 109, wherein the crack is induced into the island-like III-nitride semiconductor layers 109 at or above an interface between the island-like III-nitride semiconductor layers 109 and the substrate 101, for example, at the horizontal trench 501. In one embodiment, the temperature is changed to lower the temperature of the film 601 and the substrate 101; in other embodiments, the temperature is changed to raise the temperature of the film 601 and the substrate 101. Preferably, a thermal expansion coefficient of the film 601 is different from the island-like III-nitride semiconductor layers 109 and the substrate 101. Moreover, the pressure may be removed before the temperature is changed.

Block 3910 represents the step of peeling the film 601 with the island-like semiconductor layers 109 from the substrate 101, after the pressure is applied and the temperature is changed, wherein at least a portion of the island-like III-nitride semiconductor layers 109 may remain with the substrate 101 after the peeling. The film 601 with the island-like III-nitride semiconductor layers 109 may be peeled from the substrate 101 in any direction.

One or more of the above steps of applying the film 601 to the island-like III-nitride semiconductor layers 109; applying the pressure on the film 601; changing the temperature of the film 601 and the substrate 101; and peeling the film 601 with the island-like III-nitride semiconductor layers 109 from the substrate 101; may be performed by an automated apparatus.

Moreover, one or more of the above steps of applying the film 601 to the island-like III-nitride semiconductor layers 109; applying the pressure on the film 601; changing the temperature of the film 601 and the substrate 101; and peeling the film 601 with the island-like semiconductor layers 109 from the substrate 101; may be repeated to remove the island-like III-nitride semiconductor layers 109 from the substrate 101.

The resulting product of the method comprises one or more III-nitride based semiconductor devices 110 fabricated according to this method, as well as a substrate 101 that has been removed from the devices 110 and is available for recycling and reuse, as described and illustrated herein.

### Advantages and Benefits

The present invention provides many advantages and benefits:
This invention can be used with any plane of the III-nitride-based substrate and can peel off ELO III-nitride layers patterned on any direction on the respective III-nitride-based substrate.
The invention can be used with hetero-substrates and also with semiconductor devices other than III-nitride semiconductor devices.
Wider patterns having an opening area larger than 100 μm can also be removed, which will reduce MOCVD growth times and adds more flexibility to device designs, for example, power electronics can adopt this mechanism to realize high breakdown voltage devices by removing thicker ELO III-nitride layers having a wider opening area.
The process can be realized at a much cheaper price as the resources for peeling uses only a polymer/adhesive film.
The present invention has an inbuilt advantage to current display technologies, for example, laser diode or micro-LED displays, as these devices need to be handled one-by-one to integrate with other pixels to realize a functional display. The processed devices may stay attached to the polymer/adhesive film after removal from the substrate. The adhesiveness of the film can be lessened by UV or IR irradiation and then, using a tool, such as a robotic vacuum chuck, each device can be picked and integrated with other wavelength pixels to realize a functional display.
The process provides the best design to release stress in the island-like III-nitride semiconductor layers.
The device or chip size is reduced significantly when compared to the commercially available devices.
Thermal management of the device improves significantly due to the bonding.
This invention can also be adopted for micro-LEDs, power devices, VCSELs, etc.
This method also can be easily adopted for larger size wafers (>2 inch).
This method can be conducted repeatedly.
This method can be conducted on only part of the substrate.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto

What is claimed is:

1. A method of removing semiconductor layers from a substrate, comprising:
forming one or more island-like semiconductor layers on a substrate;
applying a film to the island-like semiconductor layers;
applying a pressure on the film from one or more sides;
changing a temperature of the film and the substrate; and
peeling the film with the island-like semiconductor layers from the substrate, after the pressure is applied and the temperature is changed.

2. The method of claim 1, wherein the film comprises a polymer or polymer/adhesive film.

3. The method of claim 1, wherein the film has a top layer and a bottom layer, and the bottom layer is pushed inwards to a recess region between the island-like semiconductor layers.

4. The method of claim 3, the top layer is harder than the bottom layer.

5. The method of claim 1, wherein a bottom surface of the film on or above the island-like semiconductor layers is pushed to a level at least below a top surface of the island-like semiconductor layers.

6. The method of claim 5, wherein the bottom surface of the film reaches below a surface of a convexity region of the island-like semiconductor layers.

7. The method of claim 1, wherein the film is applied below a top surface of the island-like semiconductor layers and on to a surface of the substrate.

8. The method of claim 1, wherein a compressible material is placed upon the film to improve its attachment to the island-like semiconductor layers; and the pressure is applied to the compressible material for improved bonding of the film to the island-like semiconductor layers.

9. The method of claim 1, the temperature is changed to lower the temperature of the film and the substrate.

10. The method of claim 1, wherein a thermal expansion coefficient of the film is different from the island-like semiconductor layers and the substrate.

11. The method of claim 1, wherein the pressure is removed before the temperature is changed.

12. The method of claim 1, wherein the island-like semiconductor layers are III-nitride-based semiconductor layers.

13. The method of claim 1, wherein the substrate is a III-nitride-based substrate or a foreign or hetero-substrate.

14. The method of claim 1, wherein one or more of the steps of applying the film to the island-like semiconductor layers; applying the pressure on the film; changing the temperature of the film and the substrate; and peeling the film with the island-like semiconductor layers from the substrate; is performed by an automated apparatus.

15. The method of claim 1, wherein the island-like semiconductor layers are randomly shaped.

16. The method of claim 1, wherein the film with the island-like semiconductor layers is peeled from the substrate in any direction.

17. The method of claim 1, wherein one or more of the steps of applying the film to the island-like semiconductor layers; applying the pressure on the film; changing the temperature of the film and the substrate; and peeling the film with the island-like semiconductor layers from the substrate; are repeated to remove the island-like semiconductor layers from the substrate.

18. The method of claim 1, wherein the island-like semiconductor layers are patterned with a horizontal trench extended inwards to a center of the island-like semiconductor layers with at least one side vertically below the island-like semiconductor layers.

19. The method of claim 1, wherein cracks are induced into the island-like semiconductor layers at or above an interface between the island-like semiconductor layers and the substrate.

20. The method of claim 1, wherein at least a portion of the island-like semiconductor layers remains with the substrate after the peeling.

21. The method of claim 1, wherein no portion of the substrate remains with the island-like semiconductor layers after the peeling.

22. The method of claim 1, wherein the island-like semiconductor layers are formed on the substrate using a growth restrict mask and epitaxial lateral overgrowth, and the epitaxial lateral overgrowth is stopped before the island-like semiconductor layers coalesce.

23. A device fabricated by the method of claim 1.
